(19) United States
(12) Patent Application Publication
(10) Pub. No.: US 2004/0169756 A1
(43) Pub. Date: Sep. 2, 2004

(54) Charge-coupled device of XY addressing type

(76) Inventors: Takahiko Murata, Osaka (JP); Takumi Yamaguti, Takatsuki (JP)

Correspondence Address: SNELL & WILMER LLP, 1920 MAIN STREET, SUITE 1200, IRVINE, CA, 92614-7230, US

(21) Appl. No.: 10/730,424

(22) Filed: Dec. 8, 2003

(30) Foreign Application Priority Data
Dec. 10, 2002 (JP) 2002-358658

(51) Int. Cl. H04N 5/335; H01L 27/00

(52) U.S. Cl. 348/308; 250/208.1

(57) ABSTRACT

A CCD of XY addressing type includes a light-receiving unit composed of an XY matrix of pixel units in each of which photoelectric transfer and charge accumulation are performed, and scans the light-receiving unit in the X-axis direction and the Y-axis direction to read accumulated charges. The CCD includes a parallel-in shift register that starts scanning from a first pixel unit that is included in the light-receiving unit, when voltage pulses applied thereto in parallel from a pulse generating circuit that generates voltage pulses are in a first combination, and starts scanning from a second pixel unit that is different from the first pixel unit and is included in the light-receiving unit, when the applied voltage pulses are in a second combination that is different from the first combination.

This application is based on application No. 2002-358658 filed in Japan, the content of which is hereby incorporated by reference.

### BACKGROUND OF THE INVENTION

(1) Field of the Invention

The present invention relates to a charge-coupled device of XY addressing type for use in digital cameras, etc., and in particular relates to a technique for shortening the scanning time depending on an area where an image is to be picked up.

(2) Related Art

Conventional charge-coupled devices (CCD) of XY addressing type are roughly composed of a light-receiving unit and a driving unit.

The light-receiving unit is composed of an XY matrix of pixel units in each of which photoelectric transfer and charge accumulation are performed.

The driving unit is composed of a horizontal scanning shift register and a vertical scanning shift register.

Here, the horizontal scanning shift register is a serial-in/parallel-out shift register that is placed to extend in the X-axis direction of the light-receiving unit, and scans the light-receiving unit in the X-axis direction. The vertical scanning shift register is a serial-in/parallel-out shift register that is placed to extend in the Y-axis direction of the light-receiving unit, and scans the light-receiving unit in the Y-axis direction.

To pick up an image formed in the light-receiving unit in the XY addressing type CCD, a pulse generating circuit therein applies voltage pulses to the two shift registers, causing the horizontal scanning shift register to scan from the left edge to the right edge in the X-axis direction and the vertical scanning shift register to scan from the top edge to the bottom edge in the Y-axis direction. By such scanning, signal charges accumulated in the pixel units are read.

In the XY addressing type CCD, the signal charges read by scanning the entire area of the light-receiving unit are stored into memory as image data.

Here, this XY addressing type CCD has a problem in that the entire area of the light-receiving unit is first scanned to store the read signal charges into memory as image data corresponding to the entire area, even when an image to be picked up is within a partial area of the light-receiving unit. The image data corresponding to the partial area is obtained by extracting such image data from the entire image data stored in the memory. Therefore, the problem is that an image pickup of a partial area requires as much scanning time as the scanning time required by an image pickup of the entire area of the light-receiving unit.

### SUMMARY OF THE INVENTION

In view of the above problem, the present invention aims to provide a CCD of XY addressing type that shortens the time required for scanning, depending on an area where an image is to be picked up.

The above aim of the present invention can be achieved by a charge-coupled device of XY addressing type, including: a light-receiving unit that includes an XY matrix of pixel units in each of which photoelectric transfer and charge accumulation are performed; a pulse generating circuit operable to generate two or more types of voltage pulses; and a shift register operable to (a) start scanning from a first pixel unit that is included in the light-receiving unit, when the two or more types of voltage pulses applied thereto in parallel from the pulse generating circuit are in a first combination, and (b) start scanning from a second pixel unit that is different from the first pixel unit and is included in the light-receiving unit, when the two or more types of the applied voltage pulses are in a second combination that is different from the first combination.

According to this configuration, a pixel unit from which the scanning is to be started can be changed depending on a combination of voltage pulses. Assume here that a pixel unit at the left edge of the light-receiving unit is a first pixel unit and the Nth pixel unit from the left edge is a second pixel unit, and that the light-receiving unit is to be scanned in the left to right direction. Here, when the scanning is started from the second pixel unit, the scanning time can be shortened compared with when the scanning is started from the first pixel unit, by the time conventionally required for scanning from the left edge pixel unit to the (N-1)th pixel unit.

Here, the pulse generating circuit may generate a first voltage pulse, a second voltage pulse, and a third voltage pulse, each having a voltage level set at HIGH level or LOW level, and applies the first voltage pulse, the second voltage pulse, and the third voltage pulse to the shift register, and the first combination may be a combination of the first voltage pulse and the second voltage pulse both being set at HIGH level and the third voltage pulse being set at LOW level at a first time point that is before scanning is started, and the second combination may be a combination of the second voltage pulse and the third voltage pulse both being set at HIGH level and the first voltage pulse being set at LOW level at the first time point.

According to this configuration, a pixel unit from which the scanning is to be started can be selected from the first pixel unit and the second pixel unit, by combining three voltage pulses (i.e., a first voltage pulse, a second voltage pulse, and a third voltage pulse), thereby enabling a scanning area to be changed.

Here, the shift register may include: a first pulse output unit operable to output a first selective pulse indicating to select the first pixel unit from the light-receiving unit; a second pulse output unit operable to output a second selective pulse indicating to select the second pixel unit from the light-receiving unit; a first scanning start unit operable to output, to the first pulse output unit, a first scanning start pulse indicating to start scanning from the first pixel unit, when the first voltage pulse and the second voltage pulse both being set at HIGH level are applied at the first time point; and a second scanning start unit operable to output, to the second pulse output unit, a second scanning start pulse indicating to start scanning from the second pixel unit, when the second voltage pulse and the third voltage pulse both being set at HIGH level are applied at the first time point, the first pulse output unit outputs the first selective pulse, when the first scanning start pulse is applied at the first time point and the third voltage pulse being set at HIGH level is applied at a second time point that follows the first time point, and the second pulse output unit outputs the second selective pulse, when the second scanning start pulse is applied at the first time point and the first voltage pulse being set at HIGH level is applied at the second time point.

According to this configuration, when pulses in the first combination (i.e., a HIGH level first voltage pulse and a HIGH level second voltage pulse) are applied to the first scanning start unit, the effect produced is that the scanning can be started from the first pixel unit. When pulses in the second combination (i.e., a HIGH level second voltage pulse and a HIGH level third voltage pulse) are applied to the second scanning start unit, the effect produced is that the scanning can be started from the second pixel unit.

Here, the pulse generating circuit may generate a fourth voltage pulse having a voltage level set at HIGH level or LOW level, and applies the fourth voltage pulse to the shift register, the first scanning start unit may include: a first MOSFET, to a drain of which the fourth voltage pulse is applied and to a gate of which the second voltage pulse is applied, where MOSFET stands for Metal Oxide Semiconductor Field Effect Transistor; and a second MOSFET, a drain of which is connected to a source of the first MOSFET and to a gate of which the first voltage pulse is applied, and the first scanning start unit may output, as the first scanning start pulse, a voltage pulse being set at HIGH level appearing at a source of the second MOSFET, when the fourth voltage pulse being set at HIGH level is applied at the first time point.

According to this configuration, two MOSFETs (i.e., a first MOSFET and a second MOSFET) used as switching elements enable the output of the first scanning start pulse to be controlled, thereby enabling the changing of a scanning area to be controlled.

The above aim of the present invention can also be achieved by a charge-coupled device of XY addressing type, including: a light-receiving unit that includes an XY matrix of pixel units in each of which photoelectric transfer and charge accumulation are performed; a pulse generating circuit operable to generate two or more types of voltage pulses; and a shift register operable to (a) end scanning at a last pixel unit that is positioned last in a scanning direction in the light-receiving unit, when the two or more types of voltage pulses applied thereto in parallel from the pulse generating circuit are in a combination other than a first combination, and (b) end scanning at a first pixel unit that is different from the last pixel unit and is included in the light-receiving unit, when the two or more types of the applied voltage pulses are in the first combination.

According to this configuration, a pixel unit at which the scanning is to be ended can be changed, depending on a combination of voltage pulses. Assume here that a pixel unit at the right edge of the light-receiving unit is a last pixel unit and the Mth pixel unit from the right edge is a first pixel unit, and that the light-receiving unit is to be scanned in the left to right direction. Here, when the scanning is ended at the first pixel unit, the scanning time cane shortened compared with when the scanning is ended at the last pixel unit, by the time conventionally required for scanning from the (M-1)th pixel unit to the right edge pixel unit.

### BRIEF DESCRIPTION OF THE DRAWINGS

These and other objects, advantages and features of the invention will become apparent from the following description thereof taken in conjunction with the accompanying drawings that illustrate a specific embodiment of the invention.

In the drawings:

FIG. 1 is a functional block diagram showing a configuration of a CCD relating to a first embodiment of the present invention;

FIG. 2 is a first functional block diagram showing a configuration of a horizontal scanning shift register relating to the first embodiment;

FIG. 3 is a second functional block diagram showing the configuration of the horizontal scanning shift register relating to the first embodiment;

FIG. 4 is a third functional block diagram showing the configuration of the horizontal scanning shift register relating to the first embodiment;

FIG. 5 is a first circuit diagram showing an example configuration of the horizontal scanning shift register relating to the first embodiment;

FIG. 6 is a second circuit diagram showing the example configuration of the horizontal scanning shift register relating to the first embodiment;

FIG. 7 is a third circuit diagram showing the example configuration of the horizontal scanning shift register relating to the first embodiment;

FIG. 8 is a fourth circuit diagram showing the example configuration of the horizontal scanning shift register relating to the first embodiment;

FIG. 9 is a first functional block diagram showing a configuration of a vertical scanning shift register relating to the first embodiment;

FIG. 10 is a second functional block diagram showing the configuration of the vertical scanning shift register relating to the first embodiment;

FIG. 11 is a third functional block diagram showing the configuration of the vertical scanning shift register relating to the first embodiment;

FIG. 12 is a first. circuit diagram showing an example configuration of the vertical scanning shift register relating to the first embodiment;

FIG. 13 is a second circuit diagram showing the example configuration of the vertical scanning shift register relating to the first embodiment;

FIG. 14 is a third circuit diagram showing the example configuration of the vertical scanning shift register relating to the first embodiment;

FIG. 15 is a fourth circuit diagram showing the example configuration of the vertical scanning shift register relating to the first embodiment;

FIGS. 16A and 16B show timing charts for voltage pulses applied from a pulse generating circuit to the horizontal scanning shift register and the vertical scanning shift register when scanning area A is scanned in the first embodiment;

FIG. 17 shows the state transition of the horizontal scanning shift register in the first embodiment, for operation example 1;

FIGS. 18A and 18B show timing charts for voltage pulses applied from the pulse generating circuit to the horizontal scanning shift register and the vertical scanning shift register when scanning area B is scanned in the first embodiment;

FIG. 19 shows the state transition of the horizontal scanning shift register in the first embodiment, for operation example 2;

FIGS. 20A and 20B show timing charts for voltage pulses applied from the pulse generating circuit to the horizontal scanning shift register and the vertical scanning shift register when scanning area C is scanned in the first embodiment;

FIG. 21 shows the state transition of the horizontal scanning shift register in the first embodiment, for operation example 3;

FIG. 22 is a functional block diagram showing a configuration of a CCD relating to a second embodiment of the present invention;

FIG. 23 is a first functional block diagram showing a configuration of a horizontal scanning shift register relating to the second embodiment;

FIG. 24 is a second functional block diagram showing the configuration of the horizontal scanning shift register relating to the second embodiment;

FIG. 25 is a third functional block diagram showing the configuration of the horizontal scanning shift register relating to the second embodiment;

FIG. 26 is a first circuit diagram showing an example configuration of the horizontal scanning shift register relating to the second embodiment;

FIG. 27 is a second circuit diagram showing the example configuration of the horizontal scanning shift register relating to the second embodiment;

FIG. 28 is a third circuit diagram showing the example configuration of the horizontal scanning shift register relating to the second embodiment;

FIG. 29 is a fourth circuit diagram showing the example configuration of the horizontal scanning shift register relating to the second embodiment;

FIG. 30 is a first functional block diagram showing a configuration of a vertical scanning shift register relating to the second embodiment;

FIG. 31 is a second functional block diagram showing the configuration of the vertical scanning shift register relating to the second embodiment;

FIG. 32 is a third functional block diagram showing the configuration of the vertical scanning shift register relating to the second embodiment;

FIG. 33 is a first circuit diagram showing an example configuration of the vertical scanning shift register relating to the second embodiment;

FIG. 34 is a second circuit diagram showing the example configuration of the vertical scanning shift register relating to the second embodiment;

FIG. 35 is a third circuit diagram showing the example configuration of the vertical scanning shift register relating to the second embodiment;

FIG. 36 is a fourth circuit diagram showing the example configuration of the vertical scanning shift register relating to the second embodiment;

FIGS. 37A and 37B show timing charts for voltage pulses applied from a pulse generating circuit to the horizontal scanning shift register and the vertical scanning shift register when scanning area A is scanned in the second embodiment;

FIG. 38 shows the state transition of the horizontal scanning shift register in the second embodiment, for operation example 1;

FIGS. 39A and 39B show timing charts for voltage pulses applied from the pulse generating circuit to the horizontal scanning shift register and the vertical scanning shift register when scanning area B is scanned in the second embodiment;

FIG. 40 shows the state transition of the horizontal scanning shift register in the second embodiment, for operation example 2;

FIGS. 41A and 41B show timing charts for voltage pulses applied from the pulse generating circuit to the horizontal scanning shift register and the vertical scanning shift register when scanning area C is scanned in the second embodiment; and

FIG. 42 shows the state transition of the horizontal scanning shift register in the second embodiment, for operation example 3.

### DESCRIPTION OF THE PREFERRED EMBODIMENTS

The following describes preferred embodiments of the present invention, with reference to the drawings.

<First Embodiment>

<Configuration of the CCD 100>

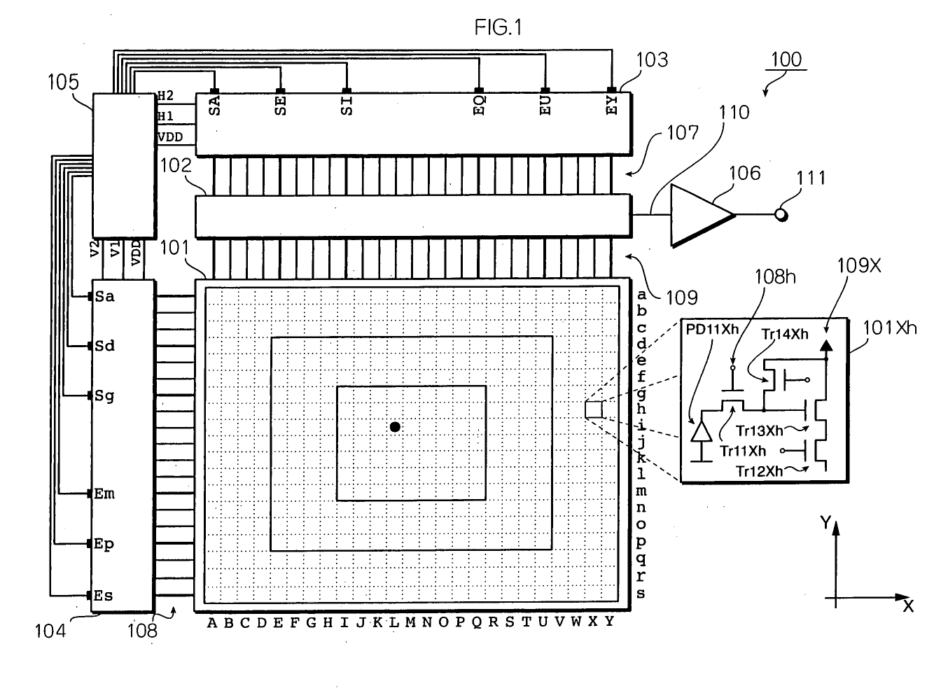

FIG. 1 is a functional block diagram showing a configuration of a CCD relating to a first embodiment of the present invention.

As shown in the figure, the CCD 100 includes a light-receiving unit 101, a switch unit 102, a horizontal scanning shift register 103, a vertical scanning shift register 104, a pulse generating circuit 105, and an amplifier unit 106. These components are mounted on a semiconductor substrate.

The horizontal scanning shift register 103 and the switch unit 102 are connected via a plurality of wiring lines 107 (hereafter referred to as a “horizontal selective line group”) arranged in parallel in the horizontal direction (X-axis direction in the figure). The vertical scanning shift register 104 and the light-receiving unit 101 are connected via a plurality of wiring lines 108 (hereafter referred to as a “vertical selective line group”) arranged in parallel in the vertical direction (Y-axis direction in the figure). The switch unit 102 and the light-receiving unit 101 are connected via a plurality of wiring lines 109 (hereafter referred to as a “vertical signal line group”) extending in the vertical direction. The switch unit 102 and the amplifier unit 106 are connected via a wiring line 110 (hereafter referred to as a “horizontal signal line”) extending in the horizontal direction.

The light-receiving unit 101 is composed of a matrix of pixel units.

As one example, the light-receiving unit 101 is hereafter assumed to be composed of a 25 by 19 matrix of pixel units, i.e., a matrix with 25 pixel units in a row (horizontal direction) by 19 pixel units in a column (vertical direction) Along with this assumption, the horizontal selective line group is assumed to include 25 horizontal selective lines, the vertical selective line group is assumed to include 19 vertical selective lines, and the vertical signal line group is assumed to include 25 vertical signal lines.

To specify one of a plurality of horizontal selective lines, vertical selective lines, vertical signal lines, and pixel units, symbols “A” to “Y” assigned in the horizontal direction of the light-receiving unit 101 and symbols “a” to “s” assigned in the vertical direction of the light-receiving unit 101 are used. As one example, a pixel unit positioned at column “X” and row “h” is specified as a pixel unit 101Xh.

The pixel unit 101Xh is composed of a photodiode PD11Xh, a MOS (Metal Oxide Semiconductor Structure) transistor (hereafter referred to as a “vertical MOS transistor”) Tr11Xh for switching purposes whose gate is connected to the vertical selective line 108h, and a plurality of MOS transistors Tr12Xh, Tr13Xh, and Tr14Xh for amplifying purposes. The MOS transistors Tr12Xh, Tr13Xh, and Tr14Xh constitute an amplifier circuit. A signal read from the photodiode PD11Xh is amplified by the amplifier circuit, and the amplified signal is output to the switch unit 102 via the vertical signal line 109X connected to a source of the MOS transistor Tr13Xh.

The switch unit 102 outputs signal charges read from the light-receiving unit 101 via the horizontal signal line group 109, to the amplifier unit 106 via the horizontal signal line 110.

The pulse generating circuit 105 is controlled by a control unit (not shown) that is provided external to the CCD 100. The pulse generating circuit 105 applies voltage pulses whose voltage level is set at HIGH or LOW, to the horizontal scanning shift register 103 and to the vertical scanning shift register 104.

Here, the control unit (not shown) is realized by a programmable logic device such as an FPGA (Field Programmable Gate Array) and a CPLD (Complex Programmable Logic Device), mounted with circuit data generated by logical synthesis using a program written in a hardware description language.

The amplifier unit 106 amplifies a signal charge output from the switch unit 102 via the horizontal signal line 110, and outputs the amplified signal charge as a video signal representing image data, to an output terminal 111.

The horizontal scanning shift register 103 is a parallel-in/parallel-out shift register, and outputs a voltage pulse that causes selective scanning in the horizontal direction of the light-receiving unit 101 (hereafter referred to as a “horizontal selective pulse”).

The vertical scanning shift register 104 is a parallel-in/parallel-out shift register, and outputs a voltage pulse that causes selective scanning in the vertical direction of the light-receiving unit 101 (hereafter referred to as a “vertical selective pulse”).

Assume here that voltage pulses are applied to the horizontal scanning shift register 103 and the vertical scanning shift register 104 from the pulse generating circuit 105, and the horizontal scanning shift register 103 outputs a horizontal selective pulse to the horizontal selective line 107L positioned at column “L”, and the vertical scanning shift register 104 outputs a vertical selective pulse to the vertical selective line 108i positioned at row “i”. In this case, a signal charge accumulated in the pixel unit 101Li positioned at column “L” and row “i” (indicated by a black point in the figure) is read.

<Configuration of the Horizontal Scanning Shift Register 103>

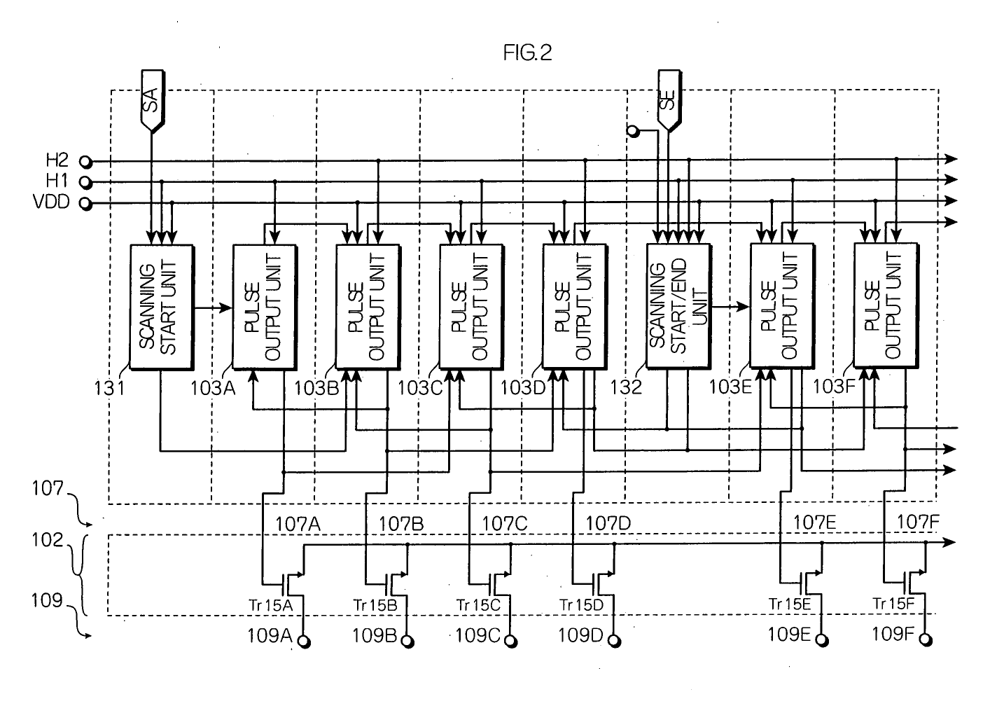

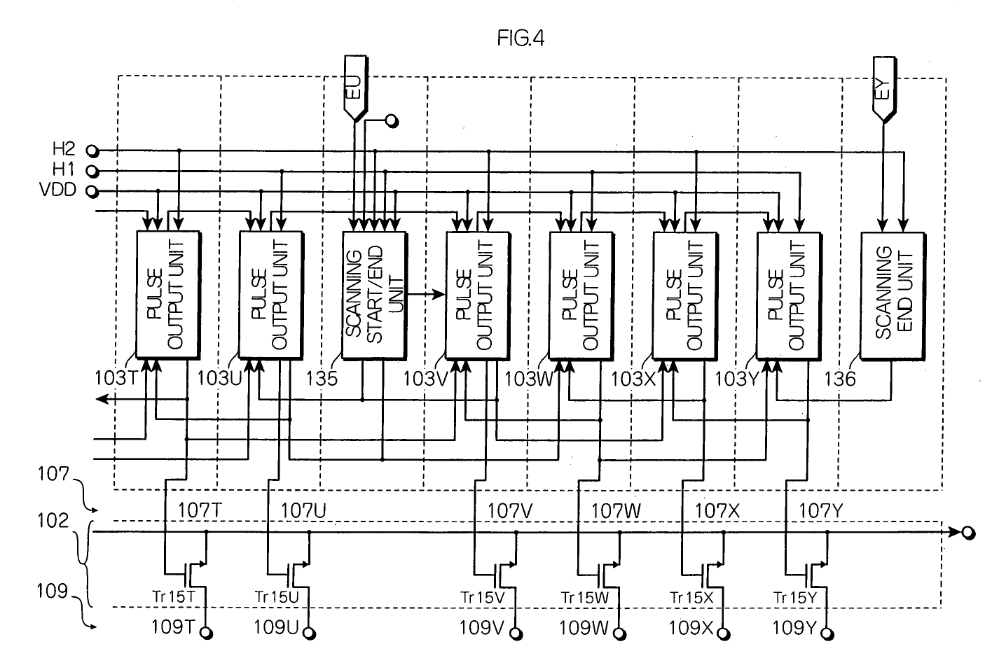

FIGS. 2 to 4 are functional block diagrams showing a configuration of the horizontal scanning shift register relating to the first embodiment.

As shown in FIGS. 2 to 4, the horizontal scanning shift register 103 includes pulse output units 103A to 103Y, a scanning start unit 131, scanning start/end units 132 to 135, and a scanning end unit 136. The horizontal scanning shift register 103 has terminals VDD, H1, and H2. The pulse generating unit 105 applies a source voltage to the terminal VDD, and applies a voltage pulse individually to each of the H1 and the H2. The horizontal scanning shift register 103 sequentially outputs, from its pulse output units, horizontal selective pulses to the switch unit 102 in such a manner that an active pulse output unit to output a horizontal selective pulse is sequentially shifted in the direction from where the scanning start unit 131 is positioned toward where the scanning end unit 136 is positioned.

Hereafter, a voltage pulse applied to the horizontal scanning shift register 103 via the terminal H1 is referred to as a first horizontal shift pulse, and a voltage pulse applied to the horizontal scanning shift register 103 via the terminal H2 is referred to as a second horizontal shift pulse. It is assumed that in the present embodiment when the first horizontal shift pulse is applied as being set at HIGH level, the second horizontal shift pulse is applied as being set at LOW level, and vice versa.

The switch unit 102 is composed of MOS transistors Tr15A to Tr15Y for switching purposes arranged in the horizontal direction (hereafter referred to as “horizontal MOS transistors”). The horizontal MOS transistor Tr15A (hereafter simply, “Tr15A”) has its drain connected to the horizontal signal line 109A, its gate connected to the horizontal selective line 107A, and its source connected to the horizontal signal line 110. The same applies to the horizontal MOS transistors Tr15B to Tr15Y (hereafter, simply “Tr15B” to “Tr15Y”).

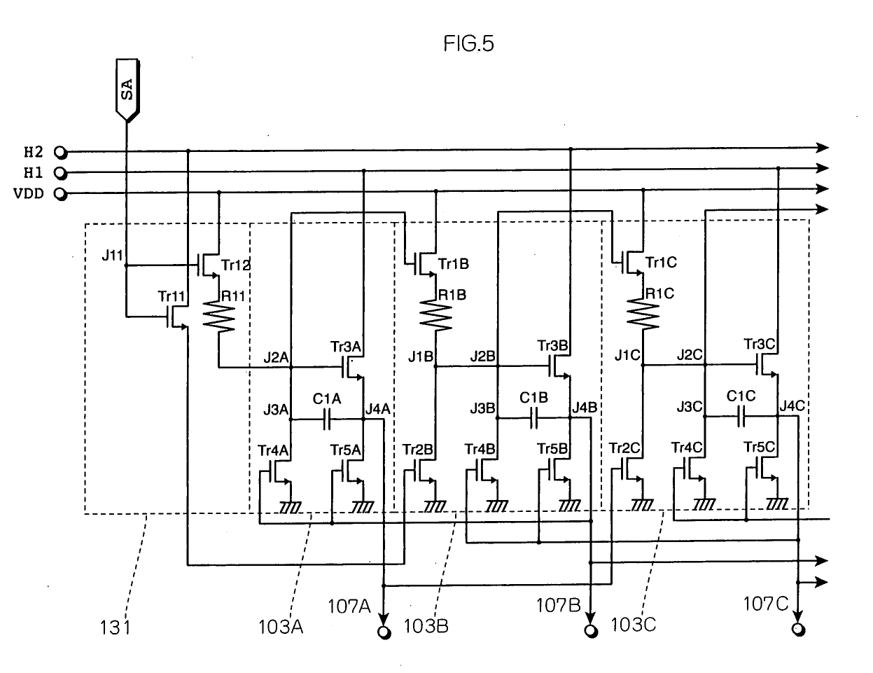

The pulse output unit 103A is composed of a capacitor for bootstrap purposes (shown in FIG. 5), and a plurality of MOS transistors for switching purposes (shown in FIG. 5). Further, the pulse output unit 103A is connected, via the horizontal selective line 107A, to a gate of its corresponding Tr15A, out of the Tr15A to Tr15Y corresponding in one-to-one to the pulse output units 103A to 103Y. The bootstrap capacitor included in the pulse output unit 103A is charged by a source voltage applied from the pulse generating circuit 105 via the terminal VDD. When a first horizontal shift pulse is applied from the pulse generating circuit 105 to the pulse output unit 103A via the terminal H1, with the capacitor having been charged, the pulse output unit 103A outputs a horizontal selective pulse. The horizontal selective pulse output from the pulse output unit 103A is applied to the gate of the Tr15A via the horizontal selective line 107A.

Hereafter, the same applies to the pulse output units 103B to 103Y. To the pulse output units positioned at even-numbered stages numbered from the stage of the pulse output unit 103A except the scanning start unit 131, the scanning start/end units 132 to 135, and the scanning end unit 136, a first horizontal shift pulse is applied from the pulse generating circuit 105 via the terminal H1. To the pulse output units positioned at odd-numbered stages numbered in the same way, a second horizontal shift pulse is applied from the pulse generating circuit 105 via the terminal H2. This is described in detail later, with reference to FIGS. 5 to 8.

Further, the horizontal scanning shift register 103 has terminals SA, SE, SI, EQ, EU, and EY, to each of which a voltage pulse is individually applied from the pulse generating circuit 105.

The terminal SA is connected to the scanning start unit 131, the terminal SE to the scanning start/end unit 132, and the terminal SI to the scanning start/end unit 133. The terminal EQ is connected to the scanning start/end unit 134, the terminal EU to the scanning start/end unit 135, and the terminal EY to the scanning end unit 136.

When a HIGH level voltage pulse is applied to the scanning start unit 131 via the terminal SA, the scanning start unit 131 outputs a HIGH level voltage pulse to the pulse output unit 103A, to charge the bootstrap capacitor included in the pulse output unit 103A. Hereafter, the same applies to the scanning start/end units 132 and 133, i.e., the scanning start/end units 132 and 133 respectively charge bootstrap capacitors included in the pulse output units 103E and 103I, which are positioned one stage after the scanning start/end units 132 and 133.

When a HIGH level voltage pulse is applied to the scanning end unit 136 via the terminal EY, the scanning end unit 136 outputs a HIGH level voltage pulse to the pulse output unit 103Y, to charge the bootstrap capacitor included in the pulse output unit 103Y. Hereafter, the same applies to the scanning start/end units 134 and 135, i.e., the scanning start/end units 134 and 135 respectively charge bootstrap capacitors included in the pulse output units 103Q and 103U, which are positioned one stage before the scanning start/end units 134 and 135.

The horizontal scanning shift register 103 starts outputting a horizontal selective pulse from a different pulse output unit, depending on a terminal to which a HIGH level voltage pulse is applied.

For example, when a HIGH level voltage pulse is applied to the scanning start unit 131 via the terminal SA, the horizontal scanning shift register 103 starts outputting a horizontal selective pulse from the pulse output unit 103A. In the same manner, when a HIGH level voltage pulse is applied to the scanning start/end unit 132 via the terminal SE, the horizontal scanning shift register 103 starts outputting a horizontal selective pulse from the pulse output unit 103E. Also, when a HIGH level voltage pulse is applied to the scanning start/end unit 133via the terminal SI, the horizontal scanning shift register 103 starts outputting a horizontal selective pulse from the pulse output unit 103I. After a horizontal selective pulse is output from one of the pulse output units 103A, 103E, and 103I, an active pulse output unit to output a horizontal selective pulse is sequentially shifted in the direction from where the scanning start unit 131 is positioned toward where the scanning end unit 136 is positioned.

Further, if (a) a HIGH level first horizontal shift pulse is applied to the pulse output unit 103Q when the pulse output unit 103Q outputs a horizontal selective pulse, and (b) a HIGH level voltage pulse is applied to the scanning start/end unit 134 via the terminal EQ, a horizontal selective pulse is output from pulse output units preceding the pulse output unit 103Q and from the pulse output unit 103Q, but is not output from the pulse output unit 103R and the following pulse output units. In the same manner, if (a) a HIGH level first horizontal shift pulse is applied to the pulse output unit 103U when the pulse output unit 103U outputs a horizontal selective pulse, and (b) a HIGH level voltage pulse is applied to the scanning start/end unit 135 via the terminal EU, a horizontal selective pulse is output from pulse output units preceding the pulse output unit 103U and from the pulse output unit 103U, but is not output from the pulse output unit 103V and the following pulse output units. In the other cases, a horizontal selective pulse is sequentially output from one pulse output unit after another, with the pulse output unit 103Y being the last unit to output a horizontal selective pulse.

It should be noted here that a HIGH level voltage pulse is not applied to the terminals SA, SE and SI while the active pulse output unit to output a horizontal selective pulse is being shifted.

As described above, the horizontal scanning shift register 103 scans the light-receiving unit 101 in the horizontal direction, from a pixel unit positioned at one of columns “A”, “E”, and “I” to a pixel unit positioned at one of columns “Q”, “U”, and “Y” shown in FIG. 1.

While the light-receiving unit 101 is being scanned, the pulse output units 103A to 103Y each make a state transition from an insulating-state, a charging-state, an outputting-state, and a discharging-state in the stated order.

The insulating-state is where a HIGH level voltage pulse is being applied to a target pulse output unit from a pulse output unit positioned two stages before the target pulse output unit, and a source voltage applied to a bootstrap capacitor included in the target pulse output unit is being insulated.

The charging-state is where a HIGH level voltage pulse is being applied to a target pulse output from a pulse output unit positioned one stage before the target pulse output unit, and a bootstrap capacitor included in the target pulse output unit is being charged by a source voltage applied from the pulse generating circuit 105.

The outputting-state is where a bootstrap capacitor included in a target pulse output unit is being charged. When the target pulse output unit is positioned at an even-numbered stage numbered from the pulse output unit 103A, a HIGH level first horizontal shift pulse is being applied to the target pulse output unit from the pulse generating circuit 105 in the outputting-state. When the target pulse output unit is positioned at an odd-numbered stage numbered from the pulse output unit 103A, a HIGH level second horizontal shift pulse is being applied to the target pulse output unit from the pulse generating circuit 105 in the outputting-state.

The discharging-state is where a HIGH level voltage pulse is being applied to a target pulse output unit from a pulse output unit positioned one stage after the target pulse output unit, and a bootstrap capacitor included in the target pulse output unit is being discharged.

<Circuit Configuration of the Horizontal Scanning Shift Register 103>

The following describes a circuit configuration of the horizontal scanning sift register 103 having the above-described configuration.

As one example, FIGS. 5 to 8 are circuit diagrams showing the configuration of the horizontal scanning shift register relating to the first embodiment.

The circuit configuration in FIG. 5 includes the scanning start unit 131 and the pulse output units 103A to 103C.

<Scanning Start Unit 131>

The scanning start unit 131 includes MOS transistors Tr11 and Tr12, a resistor R11, and wiring lines that connect these components.

To the MOS transistor Tr11 (hereafter simply, “Tr11”), a second horizontal shift pulse is applied to its drain via the terminal H2. When a HIGH level voltage pulse is applied to its gate via the terminal SA, the Tr11 enters in the conducting state. A voltage pulse according to a voltage level of the second horizontal shift pulse then appears at the source of the Tr11.

To the MOS transistor Tr12 (hereafter simply, “Tr12”), a source voltage is applied to its drain via the terminal VDD. When a HIGH level voltage pulse is applied to its gate via the terminal SA, the Tr12 enters in the conducting state. A HIGH level voltage pulse then appears at the source of the Tr12.

The register R11 (hereafter simply, “R11”) lowers a voltage of the HIGH level voltage pulse appearing at the source of the Tr12.

Here, when a HIGH level second horizontal shift pulse is applied and a HIGH level voltage pulse is applied via the terminal SA, a voltage of the HIGH level voltage pulse appearing at the source of the Tr12 is lowered by the R11, and the HIGH level voltage pulse whose voltage has been lowered is output from the scanning start unit 131 to the pulse output unit 103A. Due to this, a voltage level becomes HIGH at the junctions J2A and J3A of the pulse output unit 103A. Further, the output HIGH level voltage pulse is applied to the gate of the MOS transistor Tr3A constituting the pulse output unit 103A, so that the MOS transistor Tr3A enters in the conducting state.

Also, when a HIGH level voltage pulse appearing at the source of the Tr11 is applied to the gate of the MOS transistor Tr2B constituting the pulse output unit 103B, the MOS transistor Tr2B enters in the conducting state. Regardless of whether the MOS transistor Tr1B is in the conducting state or in the non-conducting state, a voltage level becomes LOW at the junctions J1B, J2B, and J3B, and the MOS transistor Tr3B enters in the non-conducting state (shifting starts)

<Pulse Output Unit 103A>

The pulse output unit 103A includes MOS transistors Tr3A to Tr5A, a register R1A, a capacitor C1A, and wiring lines that connect these components.

To the MOS transistor Tr3A (hereafter simply, “Tr3A”), a first horizontal shift pulse is applied to its drain via the terminal H1. When a HIGH level voltage pulse whose voltage has been lowered by the R1A, or a voltage generated by an electric charge charging the capacitor C1A is applied to its gate, the Tr3A enters in the conducting state. A voltage pulse according to a voltage level of the first horizontal shift pulse then appears at the source of the Tr3A.

The MOS transistors Tr4A and Tr5A (hereafter simply, “Tr4A” and “Tr5A”) have their sources grounded. When a HIGH level voltage pulse is applied from the pulse output unit 103B to their gates, the Tr4A and Tr5A enter in the conducting state. A voltage level then becomes LOW at the junctions J3A and J4A.

The capacitor C1A (hereafter simply, “C1A”) is a bootstrap capacitor, and is charged and discharged according to a voltage level at the junctions J3A and J4A.

As one example, when a LOW level horizontal shift pulse is applied, with the Tr4A and the Tr5A being in the non-conducting state and the Tr1A and the Tr3A being in the conducting state, a voltage level becomes HIGH at the junction J3A, and a voltage level becomes LOW at the junction J4A, so that an electric potential difference is generated between both terminals of the C1A, and the C1A is charged (the charging-state). If a LOW level horizontal shift pulse is applied, with the Tr4A and the Tr5A being in the conducting state, a voltage level becomes LOW at the junctions J3A and J4A, so that the terminals of the C1A are grounded, and the C1A is discharged (the discharging-state).

When a HIGH level first horizontal shift pulse is applied, with the C1A being charged, the Tr4A and the Tr5A being in the non-conducting state, and the Tr3A being in the conducting state, a voltage pulse obtained by adding a voltage generated by an electric charge charging the C1A to a HIGH level voltage pulse appearing at the source of the Tr3A is applied to the gate of the Tr3A and to the gate of the MOS transistor Tr1B constituting the pulse output unit 103B. Further, a HIGH level voltage pulse appearing at the source of the Tr3A is output from the pulse output unit 103A as a horizontal selective pulse. The output HIGH level voltage pulse is applied to the gate of the MOS transistor Tr2C constituting the pulse output unit 103C (the outputting-state).

<Pulse Output Unit 103B>

The pulse output unit 103B includes MOS transistors Tr1B to Tr5B, a register R1B, a capacitor C1B, and wiring lines that connect these components.

To the MOS transistor Tr1B (hereafter simply, “Tr1B”), a source voltage is applied to its drain via the terminal VDD. When a HIGH level voltage pulse is applied to its gate from the pulse output unit 103A, the Tr1B enters in the conducting state. A HIGH level voltage pulse then appears at the source of the Tr1B.

The resistor R1B (hereafter simply, “R1B”) lowers a voltage of the HIGH level voltage pulse appearing at the source of the Tr1B.

The MOS transistor Tr2B (hereafter simply, “Tr2B”) has its source grounded. When a HIGH level voltage pulse is applied to its gate from the scanning start unit 131, the Tr2B enters in the conducting state. A voltage level then becomes LOW at the junction J1B.

To the MOS transistor Tr3B (hereafter simply, “Tr3B”), a second horizontal shift pulse is applied to its drain via the terminal H2. When a HIGH level voltage pulse whose voltage has been lowered by the R1B or a voltage generated by an electric charge charging the capacitor C1B is applied to the gate of the Tr3B, the Tr3B enters in the conducting state. A voltage pulse according to a voltage level of the second horizontal shift pulse then appears at the source of the Tr3B.

The MOS transistors Tr4B and Tr5B (hereafter simply, “Tr4B” and “Tr5B”) have their sources grounded. When a HIGH level voltage pulse is applied to their gates from the pulse output unit 103C, the Tr4B and the Tr5B enter in the conducting state. A voltage level then becomes LOW at the junctions J3B and J4B.

The capacitor C1B (hereafter, “C1B”) is a bootstrap capacitor, and is charged and discharged according to a voltage level at the junctions J3B and J4B.

As one example, when a LOW level second horizontal shift pulse is applied, with the Tr2B, the Tr4B, and the Tr5B being in the non-conducting state and the Tr1B and the Tr3B being in the conducting state, a voltage level becomes HIGH at the junction J3B, a voltage level becomes LOW at the junction J4B, so that an electric potential difference is generated between both terminals of the C1B, and the C1B is charged (the charging-state). Also, when a LOW level second horizontal shift pulse is applied, with the Tr4B and the Tr5B being in the conducting state, a voltage level becomes LOW at the junctions J3B and J4B, so that the terminals of the C1B are grounded, and the C1B is discharged (the discharging-state).

Here, when a HIGH level second horizontal shift pulse is applied, with the C1B being charged, the Tr2B, Tr4B, and the Tr5A being in the non-conducting state, and the Tr3B being in the conducting state, a voltage pulse obtained by adding a voltage generated by an electric charge charging the C1B to a HIGH level voltage pulse appearing at the source of the Tr3B is applied to the gate of the Tr3B and to the gate of the MOS transistor Tr1C constituting the pulse output unit 103C. Further, the HIGH level voltage pulse appearing at the source of the Tr3B is output from the pulse output unit 103B as a horizontal selective pulse, and the output HIGH level voltage pulse is applied to the gates of the Tr4A and the Tr5A, and to the gate of the MOS transistor Tr2D constituting the pulse output unit 103D (the outputting-state).

Also, with the Tr2B being in the conducting state, a voltage level becomes LOW at the junctions J1B, J2B, and the J3B, and the Tr3B enters in the non-conducting state, regardless of whether the Tr1B is in the conducting state or in the non-conducting state (the insulating-state).

<Pulse Output Unit 103C>

The pulse output unit 103C includes MOS transistors Tr1C to Tr5C, a register R1C, a capacitor C1C, and wiring lines that connect these components.

To the MOS transistor Tr1C (hereafter simply, “Tr1C”), a source voltage is applied to its drain via the terminal VDD. When a HIGH level voltage pulse is applied to its gate from the pulse output unit 103B, the Tr1C enters in the conducting state. A HIGH level voltage pulse then appears at the source of the Tr1C.

The resistor R1C (hereafter simply, “R1C”) lowers a voltage of the HIGH level voltage pulse appearing at the source of the Tr1C.

The MOS transistor Tr2C (hereafter simply, “Tr2C”) has its source grounded. When a HIGH level voltage pulse is applied to its gate from the pulse output unit 103A, the Tr2C enters in the conducting state. A voltage level then becomes LOW at the junction J1C.

To the MOS transistor Tr3C (hereafter simply, “Tr3C”), a first horizontal shift pulse is applied to its drain via the terminal H1. When the HIGH level voltage pulse whose voltage has been lowered by the R1C or a voltage generated by an electric charge charging the capacitor C1C is applied to the gate of the Tr3C, the Tr3C enters in the conducting state. A voltage pulse according to a voltage level of the first horizontal shift pulse then appears at the source of the Tr3C.

The MOS transistors Tr4C and Tr5C (hereafter simply, “Tr4C” and “Tr5C”) have their sources grounded. When a HIGH level voltage pulse is applied to their gates from the pulse output unit 103C, the Tr4C and the Tr5C enter in the conducting state. A voltage level then becomes LOW at the junctions J3C and J4C.

The capacitor C1C (hereafter, “C1C”) is a bootstrap capacitor, and is charged and discharged according to a voltage level at the junctions J3C and J4C.

As one example, when a LOW level first horizontal shift pulse is applied, with the Tr2C, the Tr4C, and the Tr5C being in the non-conducting state and the Tr1C and the Tr3C being in the conducting state, a voltage level becomes HIGH at the junction J3C, and a voltage level becomes LOW at the junction J4C, so that an electric potential difference is generated between both terminals of the C1C, and the C1C is charged (the charging-state). Also, when a LOW level first horizontal shift pulse is applied, with the Tr4C and the Tr5C being in the conducting state, a voltage level becomes LOW at the junctions J3C and J4C, so that the terminals of the C1C are grounded, and the C1C is discharged (the discharging-state).

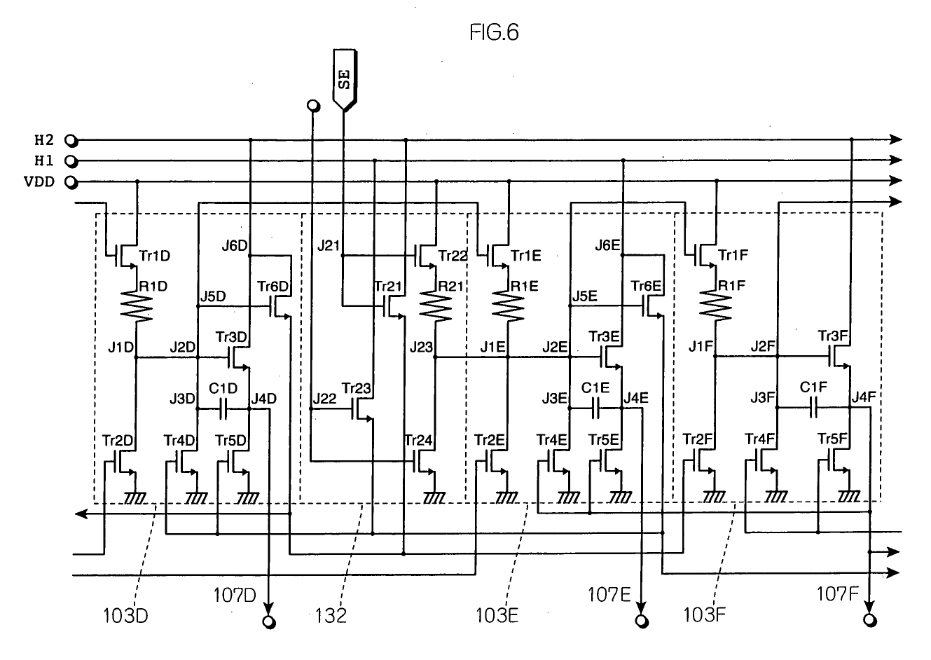

Here, when a HIGH level first horizontal shift pulse is applied, with the C1C being charged, the Tr2C, Tr4C, and the Tr5C being in the non-conducting state, and the Tr3C being in the conducting state, a voltage pulse obtained by adding a voltage generated by an electric charge charging the C1C to a HIGH level voltage pulse appearing at the source of the Tr3C is applied to the gate of the Tr3C and to the gate of the MOS transistor Tr1D constituting the pulse output unit 103D. Further, the HIGH level voltage pulse appearing at the source of the Tr3C is output from the pulse output unit 103C as a horizontal selective pulse, and the output HIGH level voltage pulse is applied to the gates of the Tr4B and the Tr5B, and to the gate of the MOS transistor Tr2E (shown in FIG. 6) constituting the pulse output unit 103E (shown in FIG. 6) (the outputting-state).

When the Tr2C is in the conducting state, a voltage level becomes LOW at the junctions J1C, J2C, and the J3C, and the Tr3C enters in the non-conducting state, regardless of whether the Tr1C is in the conducting state or in the non-conducting state (the insulating-state).

The circuit configuration in FIG. 6 includes the scanning start/end unit 132 and the pulse output units 103D to 103F.

<Pulse Output Unit 103D>

The pulse output unit 103D includes MOS transistors Tr1D to Tr6D, a register R1D, a capacitor C1D, and wiring lines that connect these components.

To the MOS transistor Tr1D (hereafter simply, “Tr1D”), a source voltage is applied to its drain via the terminal VDD. When a HIGH level voltage pulse is applied to its gate from the pulse output unit 103C, the Tr1D enters in the conducting state. A HIGH level voltage pulse then appears at the source of the Tr1D.

The register R1D (hereafter simply, “R1D”) lowers a voltage of the HIGH level voltage pulse appearing at the source of the Tr1D.

The MOS transistor Tr2D (hereafter simply, “Tr2D”) has its source grounded. When a HIGH level voltage pulse is applied to its gate from the pulse output unit 103B, the Tr2D enters in the conducting state. A voltage level then becomes LOW at the junction J1D.

To the MOS transistors Tr3D and Tr6D (hereafter simply, “Tr3D” and “Tr6D”), a second horizontal shift pulse is applied to their drains via the terminal H2. A HIGH level voltage pulse whose voltage has been lowered by the R1D or a voltage generated by an electric charge charging the capacitor C1D is applied to the gates of the Tr3D and the Tr6D, so that the Tr3D and the Tr6D enter in the conducting state. A voltage pulse according to a voltage level of the second horizontal shift pulse appears at the sources of the Tr3D and the Tr6D.

The MOS transistors Tr4D and Tr5D (hereafter simply, “Tr4D” and “Tr5D”) have their sources grounded. When a HIGH level voltage pulse is applied to their gates from the pulse output unit 103E, the Tr4D and the Tr5D enter in the conducting state. A voltage level then becomes LOW at the junctions J3D and J4D.

The capacitor C1D (hereafter simply, “C1D”) is a bootstrap capacitor, and is charged and discharged according to a voltage level at the junctions J3D and J4D.

As one example, when a LOW level second horizontal shift pulse is applied, with the Tr2D, the Tr4D, and the Tr5D being in the non-conducting state, and the Tr1D, the Tr3D, and the Tr6D being in the conducting state, a voltage level becomes HIGH at the junction J3D and a voltage level becomes LOW at the junction J4D, so that an electric potential difference is generated between both terminals of the C1D, and the C1D is charged (the charging-state). Also, when a LOW level second horizontal shift pulse is applied, with the Tr4D and the Tr5D being in the conducting state, a voltage level becomes LOW at the junctions J3D and J4D, so that the terminals of the C1D are grounded, and the C1D is discharged (the discharging-state).

Here, when a HIGH level second horizontal shift pulse is applied, with the C1D being charged, the Tr2D, the Tr4D, and the Tr5D being in the non-conducting state, and the Tr3D and the Tr6D being in the conducting state, a voltage pulse obtained by adding a voltage generated by an electric charge charging the C1D to a HIGH level voltage pulse appearing at the source of the Tr3D is applied to the gates of the Tr3D and the Tr6D, and to the gate of the MOS transistor Tr1E constituting the pulse output unit 103E. Further, the HIGH level voltage pulse appearing at the source of the Tr3D is output from the pulse output unit 103D as a horizontal selective pulse, and the output HIGH level voltage pulse is applied to the gates of the Tr4C and the Tr5C, and to the gate of the MOS transistor Tr2F constituting the pulse output unit 103F (the outputting-state).

Also, with the Tr2D being in the conducting state, a voltage level becomes LOW at the junctions J1D, J2D, J3D, and J5D, and the Tr3D and the Tr6D enter in the non-conducting state, regardless of whether the Tr1D is in the conducting state or in the non-conducting state (the insulating-state)

<Scanning Start/End Unit 132>

The scanning start/end unit 132 includes MOS transistors Tr21 to Tr24, a register R21, and wiring lines that connect these components.

To the MOS transistor Tr21 (hereafter simply, “Tr21”), a second horizontal shift pulse is applied to its drain via the terminal H2. When a HIGH level voltage pulse is applied to its gate via the terminal SE, the Tr21 enters in the conducting state. A voltage pulse according to a voltage level of the second horizontal shift pulse then appears at the source of the Tr21.

To the MOS transistor Tr22 (hereafter simply, “Tr22”), a source voltage is applied to its drain via the terminal VDD. When a HIGH level voltage pulse is applied to its gate via the terminal SE, the Tr22 enters in the conducting state. A HIGH level voltage pulse then appears at the source of the Tr22.

The register R21 (hereafter simply, “R21”) lowers a voltage of the HIGH level voltage pulse appearing at the source of the Tr22.

Here, when. a HIGH level second horizontal shift pulse is applied and a HIGH level voltage pulse is applied via the terminal SE, the HIGH level voltage pulse appearing at the source of the Tr22 is lowered by the R21, and the HIGH level voltage pulse whose voltage has been lowered is output from the scanning start/end unit 132 to the pulse output unit 103E via the junction J23. Due to this, a voltage level becomes HIGH at the junctions J1E, J2E, J3E, and J5E of the pulse output unit 103E. Further, the output HIGH level voltage pulse is applied to the gates of the MOS transistors Tr3E and Tr6E, so that the Tr3E and the Tr6E enter in the conducting state.

Also, the HIGH level voltage pulse appearing at the source of the Tr21 is applied to the gate of the MOS transistor Tr2F constituting the pulse output unit 103F, so that the MOS transistor Tr2F enters in the conducting state. A voltage level then becomes LOW at the junctions J1F, J2F, and J3F, and the MOS transistor Tr3F enters in the non-conducting state, regardless of whether the MOS transistor Tr1F is in the conducting state or in the non-conducting state (shifting starts).

To the MOS transistor Tr23 (hereafter simply, “Tr23”), a first horizontal shift pulse is applied to its drain via the terminal H1. When a HIGH level voltage pulse is applied to its gate via a free terminal, the Tr23 enters in the conducting state. A voltage pulse according to a voltage level of the first horizontal shift pulse then appears at the source of the Tr23.

The MOS transistor Tr24 (hereafter simply, “Tr24”) has its source grounded. When a HIGH level voltage pulse is applied to the gate of the Tr24 via a free terminal, the Tr24 enters in the conducting state. A voltage level then becomes LOW at the junction J23.

When a HIGH level first horizontal shift pulse is applied and a HIGH level voltage pulse is applied via the free terminal, a voltage level becomes LOW at the junction J23, and a LOW level voltage pulse is output from the scanning start/end unit 132 to the pulse output unit 103E via the junction J23. Due to this, a voltage level becomes LOW at the junctions J1E, J2E, J3E, and J5E, regardless of whether the MOS transistor Tr1E is in the conducting state or in the non-conducting state. Further, the output LOW level voltage pulse is applied to the gates of the MOS transistors Tr3E and Tr6E, so that the MOS transistors Tr3E and Tr6E enter in the non-conducting state.

Further, when a HIGH level first horizontal shift pulse is applied and a HIGH level voltage pulse is applied via a free terminal, the HIGH level voltage pulse appearing at the source of the Tr23 is applied to the gates of the Tr4D and the Tr5D, so that the Tr4D and the Tr5D enter in the conducting state. A voltage level becomes LOW at the junctions J3D and J4D, so that both terminals of the C1D are grounded, and the C1D is discharged (shifting ends).

<Pulse Output Unit 103E>

The pulse output unit 103E includes MOS transistors Tr1E to Tr6E, a register R1E, a capacitor C1E, and wiring lines that connect these components.

To the MOS transistor Tr1E (hereafter simply, “Tr1E”), a source voltage is applied to its drain via the terminal VDD. When a HIGH level voltage pulse is applied to its gate from the pulse output unit 103D, the Tr1E enters in the conducting state. A HIGH level voltage pulse then appears at the source of the Tr1E.

The register R1E (hereafter simply, “R1E”) lowers a voltage of the HIGH level voltage pulse appearing at the source of the Tr1E.

The MOS transistor Tr2E (hereafter simply, “Tr2E”) has its source grounded. When a HIGH level voltage pulse is applied to its gate from the pulse output unit 103D, the Tr2E enters in the conducting state. A voltage level then becomes LOW at the junction J1E.

To the MOS transistors Tr3E and Tr6E (hereafter simply, “Tr3E” and “Tr6E”), a first horizontal shift pulse is applied to their drains via the terminal H1. When a HIGH level voltage pulse whose voltage has been lowered by the R1E or a voltage generated by an electric charge charging the capacitor C1E is applied to the gates of the Tr3E and the Tr6E, the Tr3E and the Tr6E enter in the conducting state. A voltage pulse according to a voltage level of the first horizontal shift pulse appears at the sources of the Tr3E and the Tr6E.

The MOS transistors Tr4E and Tr5E (hereafter simply, “Tr4E” and “Tr5E”) have their sources grounded. When a HIGH level voltage pulse is applied to their gates from the pulse output unit 103F, the Tr4E and the Tr5E enter in the conducting state. A voltage level becomes LOW at the junctions J3E and J4E.

The capacitor C1E (hereafter simply, “C1E”) is a bootstrap capacitor, and is charged and discharged according to a voltage level at the junctions J3E and J4E.

As one example, when a LOW level first horizontal shift pulse is applied, with the Tr2E, the Tr4E, and the Tr5E being in the non-conducting state, and the Tr1E, the Tr3E, and the Tr6E being in the conducting state, a voltage level becomes HIGH at the junction J3E, and a voltage level becomes LOW at the junction J4E, so that an electric potential difference is generated between both terminals of the C1E, and the C1E is charged (the charging-state). Also, when a LOW level first horizontal shift pulse is applied, with the Tr4E and the Tr5E being in the conducting state, a voltage level becomes LOW at the junctions J3E and J4E, so that the terminals of the C1E are grounded, and the C1E is discharged (the discharging-state).

When a HIGH level first horizontal shift pulse is applied, with the Tr2E, the Tr4E, and the Tr5E being in the non-conducting state, and the Tr3E and the Tr6E being in the conducting state, a voltage pulse obtained by adding a voltage generated by an electric charge charging the C1E to a HIGH level voltage pulse appearing at the source of the Tr3E is applied to the gates of the Tr3E and the Tr6E, and to the gate of the MOS transistor Tr1F constituting the pulse output unit 103F. Further, the HIGH level voltage pulse appearing at the source of the Tr3E is output from the pulse output unit 103E as a horizontal selective pulse. Further, the HIGH level voltage pulse appearing at the source of the Tr6E is applied to the gates of the Tr4E and the Tr5D and to the gate of the MOS transistor Tr2G (not shown) constituting the pulse output unit 103G (not shown) (the outputting-state).

Here, with the Tr2E being in the conducting state, a voltage level becomes LOW at the junctions J1E, J2E, J3E, and J5E, and the Tr3E and the Tr6E enter in the non-conducting state, regardless of whether the Tr1E is in the conducting state or in the non-conducting state (the insulating-state).

<Pulse Output Unit 103F>

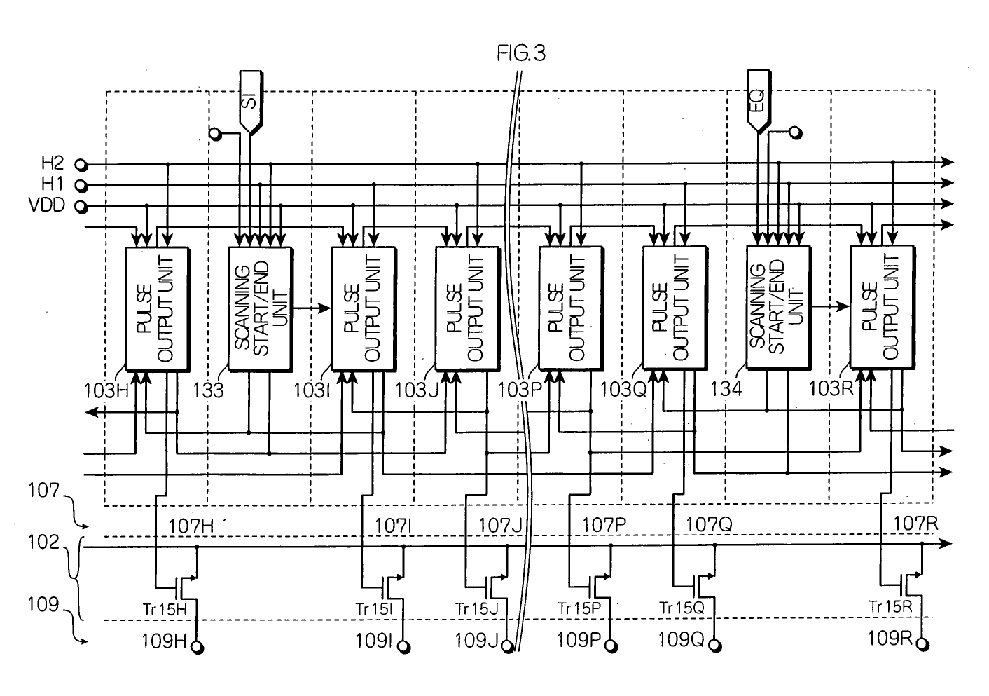

The pulse output unit 103F has the same configuration as the pulse output unit 103B except that the scanning start/end unit 132, the pulse output unit 103E, the pulse output unit 103G, and the pulse output unit 103H are provided respectively instead of the scanning start unit 131, the pulse output unit 103A, the pulse output unit 103C, and the pulse output unit 103D as shown in FIGS. 2 and 3. The pulse output unit 103F is therefore not described here.

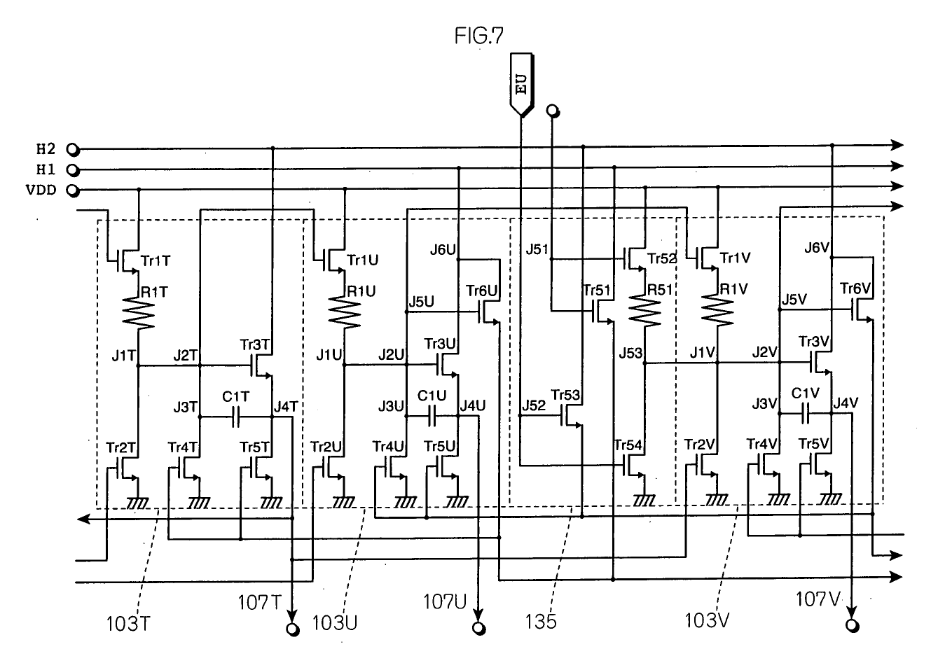

The circuit configuration in FIG. 7 includes the scanning start/end unit 135, and the pulse output units 103T to 103V.

<Pulse Output Unit 103T>

The pulse output unit 103T has the same configuration as the pulse output unit 103B except that the pulse output unit 103R, the pulse output unit 103S, the pulse output unit 103U, and the pulse output unit 103V are provided respectively instead of the scanning start unit 131, the pulse output unit 103A, the pulse output unit 103C, and the pulse output unit 103D as shown in FIGS. 2 to 4. The pulse output unit 103T is therefore not described here.

<Pulse Output Unit 103U>

The pulse output unit 103U includes MOS transistors Tr1U to Tr6U, a resistor R1U, a capacitor C1U, and wiring lines that connect these components.

To the MOS transistor Tr1U (hereafter simply, “Tr1U”), a source voltage is applied to its drain via the terminal VDD. When a HIGH level voltage pulse is applied to its gate from the pulse output unit 103T, the Tr1U enters in the conducting state. A HIGH level voltage pulse then appears at the source of the Tr1U.

The register R1U (hereafter simply, “R1U”) lowers a voltage of the HIGH level voltage pulse appearing at the source of the Tr1U.

The MOS transistor Tr2U (hereafter simply, “Tr2U”) has its source grounded. When a HIGH level voltage pulse is applied to its gate from the pulse output unit 103S, the Tr2U enters in the conducting-state. A voltage level then becomes LOW at the junction J1U.

To the MOS transistors Tr3U and Tr6U (hereafter simply, “Tr3U” and “Tr6U”), a first horizontal shift pulse is applied to their drains via the terminal H1. When the HIGH level voltage pulse whose voltage has been lowered by the R1U or a voltage generated by an electric charge charging the capacitor C1U is applied to the gates of the Tr3U and the Tr6U, the Tr3U and the Tr6U enter in the conducting-state. A voltage pulse according to a voltage level of the first horizontal shift pulse then appears at the sources of the Tr3U and the Tr6U.

The MOS transistors Tr4U and Tr5U (hereafter simply, “Tr4U” and “Tr5U”) have their sources grounded. When a HIGH level voltage pulse is applied to their gates from the pulse output unit 103V, the Tr4U and the Tr5U enter in the conducting-state. A voltage level then becomes LOW at the junctions J3E and J4E.

The capacitor C1U (hereafter simply, “C1U”) is a bootstrap capacitor, and is charged and discharged according to a voltage level at the junctions J3U and J4U.

As one example, when a LOW level first horizontal shift pulse is applied, with the Tr2U, Tr4U and Tr5U being in the non-conducting state and the Tr1U, Tr3U, and Tr6U being in the conducting-state, a voltage level becomes HIGH at the junction J3U and a voltage level becomes LOW at the junction J4U, so that an electric potential difference is generated between both terminals of the C1U, and the C1U is charged (the charging-state). Further, when a LOW level first horizontal shift pulse is applied, with the Tr4U and the Tr5U being in the conducting-state, a voltage level becomes LOW at the junctions J3U and J4U, so that the terminals of the C1U are grounded, and the C1U is discharged (the discharging-state).

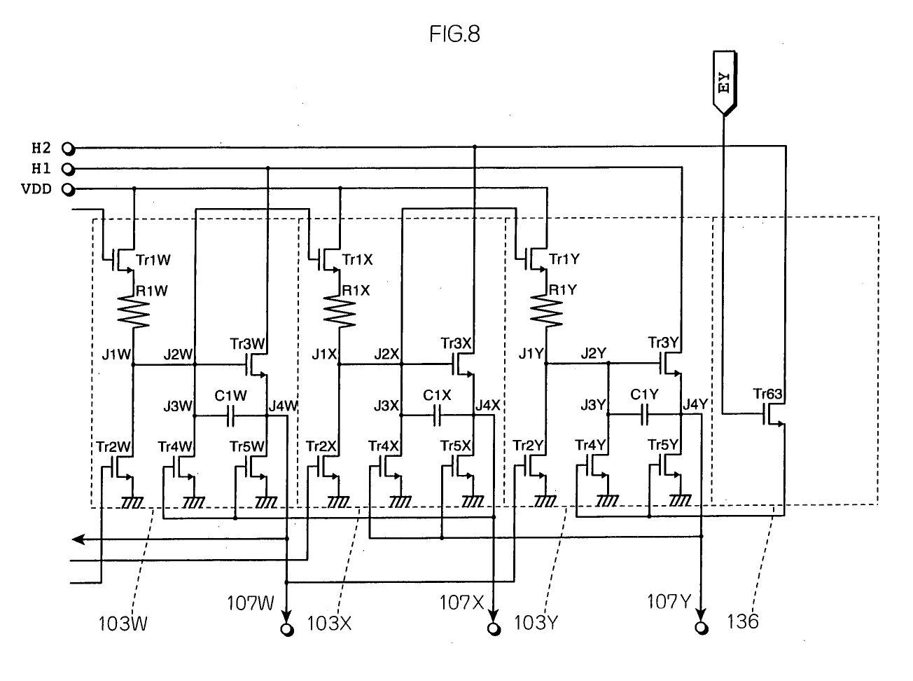

Here, when a HIGH level second horizontal shift pulse is applied, with the Tr2U, Tr4U and Tr5U being in the non-conducting state and the Tr3U and Tr6U being in the conducting-state, a voltage pulse obtained by adding a voltage generated by an electric charge charging the C1U to a HIGH level voltage pulse appearing at the source of the Tr3U is applied to the gates of the Tr3U and the Tr6U, and to the gate of the MOS transistor Tr1V constituting the pulse output unit 103V. Further, the HIGH level voltage pulse appearing at the source of the Tr3U is output from the pulse output unit 103U as a horizontal selective pulse. Further, the HIGH level voltage pulse appearing at the source of the pulse output unit Tr6U is applied to the gates of the Tr4T and the Tr5T and to the gate of the MOS transistor Tr2W constituting the pulse output unit 103W (shown in FIG. 8) (the outputting-state).

Also, with the Tr2U being in the conducting state, a voltage level becomes LOW at the junctions J1U, J2U, J3U, and J5U, and the Tr3U and the Tr6U enter in the non-conducting state, regardless of whether the Tr1U is in the conducting state or in the non-conducting state (the insulating-state).

<Scanning start/End Unit 135>

The scanning start/end unit 135 includes MOS transistors Tr51 to Tr54, a resistor R51, and wiring lines that connect these components.

To the MOS transistor Tr51 (hereafter simply, “Tr51”), a first horizontal shift pulse is applied to its drain via the terminal H1. When a HIGH level voltage pulse is applied to its gate via a free terminal, the Tr51 enters in the conducting state. A voltage pulse according to a voltage level of the first horizontal shift pulse then appears at the source of the Tr51.

To the MOS transistor Tr52 (hereafter simply, “Tr52”), a source voltage is applied to its drain via the terminal VDD. When a HIGH level voltage pulse is applied to its gate via a free terminal, the Tr52 enters in the conducting state. A HIGH level voltage pulse then appears at the source of the Tr52.

The resistor R51 lowers a voltage of the HIGH level voltage pulse appearing at the source of the MOS transistor Tr52.

Here, when a HIGH level first horizontal shift pulse is applied and a HIGH level voltage pulse is applied via the free terminal, a voltage of the HIGH level voltage pulse appearing at the source of the Tr52 is lowered by the R51, and the HIGH level voltage pulse whose voltage has been lowered is output from the scanning start/end unit 135 to the pulse output unit 103V via the junction J53. Due to this, a voltage level becomes HIGH at the junctions J1V, J2V, J3V, and J5V of the pulse output unit 103V. Further, the output HIGH level voltage pulse is applied to the gates of the MOS transistors Tr3V and Tr6V, so that the MOS transistors Tr3V and Tr6V enter in the conducting state.

Also, a HIGH level voltage pulse appearing at the source of the Tr51 is applied to the gate of the MOS transistor Tr2W constituting the pulse output unit 103W, so that the MOS transistor Tr2W enters in the conducting state. Regardless of whether the MOS transistor Tr1W is in the conducting state or in the non-conducting state, a voltage level becomes LOW at the junctions J1W, J2W, and J3W, and the MOT transistor Tr3W enters in the non-conducting state (shifting starts).

To the MOS transistor Tr53 (hereafter simply, “Tr53”), a second horizontal shift pulse is applied to its drain via the terminal H2. When a HIGH level voltage pulse is applied to its gate via the terminal EU, the Tr53 enters in the conducting state. A voltage pulse according to a voltage level of the second horizontal shift pulse then appears at the source of the Tr53.

The MOS transistor Tr54 (hereafter simply, “Tr54”) has its source grounded. When a HIGH level voltage pulse is applied to its gate via the terminal EU, the Tr54 enters in the conducting state. A voltage level then becomes LOW at the junction J53.

Here, when a LOW level second horizontal shift pulse is applied and a HIGH level voltage pulse is applied via the terminal EU, a voltage level becomes LOW at the junction J53, and also, a LOW level voltage pulse is output from the scanning start/end unit 135 to the pulse output unit 103V via the junction J53. Due to this, a voltage level becomes LOW at the junctions J1V, J2V, J3V, and J5V of the pulse output unit 103V, regardless of whether the MOS transistor Tr1V is in the conducting state or in the non-conducting state. Further, the output LOW level voltage pulse is applied to the gates of the MOS transistors Tr3V and Tr6V, so that the MOS transistors Tr3V and Tr6V enter in the non-conducting state.

Also, when a HIGH level second horizontal shift pulse is applied and a HIGH level voltage pulse is applied via the terminal EU, a HIGH level voltage pulse appearing at the source of the Tr53 is applied to the gates of the MOS transistors Tr4U and Tr5U constituting the pulse output unit 103U, so that the MOS transistors Tr4U and Tr5U enter in the conducting state. A voltage level then becomes LOW at the junctions J3U and J4U, so that both terminals of the capacitor C1U are grounded, and the C1U is discharged (shifting ends).

<Pulse Output Unit 103V>

The pulse output unit 103V includes MOS transistors Tr1V to Tr6V, a resistor R1V, a capacitor C1V, and wiring lines that connect these components.

To the MOS transistor Tr1V (hereafter simply, “Tr1V”), a source voltage is applied to its drain via the terminal VDD. When a HIGH level voltage pulse is applied to its gate from the pulse output unit 103U, the Tr1V enters in the conducting state. A HIGH level voltage pulse then appears at the source of the Tr1V.

The register R1V (hereafter simply, “R1V”) lowers a voltage of the HIGH level voltage pulse appearing at the source of the Tr1V.

The MOS transistor Tr2V (hereafter simply, “Tr2V”) has its source grounded. When a HIGH level voltage pulse is applied to its gate from the pulse output unit 103U, the Tr2V enters in the conducting state. A voltage level then becomes LOW at the junction J1V.

To the MOS transistors Tr3V and Tr6V (hereafter simply, “Tr3V” and “Tr6V”), a second horizontal shift pulse is applied to their drains via the terminal H2. When a HIGH level voltage pulse whose voltage has been lowered by the R1V or a voltage generated by an electric charge charging the capacitor C1V is applied to the gates of the Tr3V and the Tr6V, the Tr3V and the Tr6V enter in the conducting state. A voltage pulse according to a voltage level of the second horizontal shift pulse then appears at the sources of the Tr3V and the Tr6V.

The MOS transistors Tr4V and Tr5V (hereafter simply, “Tr4V” and “Tr5V”) have their sources grounded. When a HIGH level voltage pulse is applied to their gates from the pulse output unit 103W, the Tr4V and the Tr5V enter in the conducting state. A voltage pulse then becomes LOW at the junctions J3V and J4V.

The capacitor C1V (hereafter simply, “C1V”) is a bootstrap capacitor, and is charged and discharged according to a voltage level at the junctions J3V and J4V.

As one example, when a LOW level second horizontal shift pulse is applied, with the Tr2V, Tr4V and Tr5V being in the non-conducting state and the Tr1V, Tr3V, and Tr6V being in the conducting-state, a voltage level becomes HIGH at the junction J3V, and a voltage level becomes LOW at the junction J4V, so that an electric potential difference is generated between both terminals of the C1V, and the C1V is charged (the charging-state). Further, when a LOW level second horizontal shift pulse is applied, with the Tr4V and the Tr5V being in the conducting state, a voltage level becomes LOW at the junctions J3V and J4V, so that the terminals of the C1V are grounded, and the C1V is discharged (the discharging-state).

Here, when a HIGH level second horizontal shift pulse is applied, with the Tr2V, Tr4V and Tr5V being in the non-conducting state and the Tr3V and Tr6V being in the conducting-state, a voltage pulse obtained by adding a voltage generated by an electric charge charging the C1V to a voltage pulse appearing at the source of the Tr3V is applied to the gates of the Tr3V and the Tr6V, and to the gate of the MOS transistor Tr1W constituting the pulse output unit 103W (shown in FIG. 8).

Further, the HIGH level voltage pulse appearing at the source of the Tr3V is output from the pulse output unit 103V as a horizontal selective pulse. Further, the HIGH level voltage pulse appearing at the source of the Tr6V sis applied to the gates of the Tr4U and the Tr5U and to the gate of the MOS transistor Tr2X (shown in FIG. 8) constituting the pulse output unit 103X (shown in FIG. 8)(the outputting-state).

Also, with the Tr2V being in the conducting state, a voltage level becomes LOW at the junctions J1V, J2V, J3V, and J5V, and the Tr3V and the Tr6V enter in the non-conducting state, regardless of whether the Tr1V is in the conducting state or in the non-conducting state (the insulating-state).

The circuit configuration in FIG. 8 includes the scanning end unit 136, and the pulse output units 103W to 103Y.

<Pulse Output Unit 103W>

The pulse output unit 103W has the same configuration as the pulse output unit 103C except that the pulse output unit 103U, the pulse output unit 103V, the pulse output unit 103X, and the pulse output unit 103Y are provided respectively instead of the pulse output unit 103A, the pulse output unit 103B, the pulse output unit 103D, and the pulse output unit 103E as shown in FIGS. 2 to 4. The pulse output unit 103W is therefore not described here.

<Pulse Output Unit 103X>

The pulse output unit 103X has the same configuration as the pulse output unit 103B except that the pulse output unit 103V, the pulse output unit 103W, the pulse output unit 103Y are provided respectively instead of the scanning start unit 131, the pulse output unit 103A and the pulse output unit 103C, and that the pulse output unit 103E is not provided, as shown in FIGS. 2 to 4. The pulse output unit 103X is therefore not described here.

<Pulse Output Unit 103Y>

The pulse output unit 103Y has the same configuration as the pulse output unit 103C except that the pulse output unit 103W and the pulse output unit 103X are provided respectively instead of the pulse output unit 103A and the pulse output unit 103B, and that the pulse output units 103D and 103E are not provided, as shown in FIGS. 2 to 4. The pulse output unit 103Y is therefore not described here.

<Scanning End Unit 136>

The scanning end unit 136 includes a MOS transistor Tr63.

To the MOS transistor Tr63 (hereafter simply, “Tr63”), a second horizontal shift pulse is applied to its drain via the terminal H2. When a HIGH level voltage pulse is applied to its gate via the terminal EY, the Tr63 enters in the conducting state. A voltage pulse according to a voltage level of the second horizontal shift pulse then appears at the source of the Tr63.

Here, when a HIGH level second horizontal shift pulse is applied and a HIGH level voltage pulse is applied via the terminal EY, a HIGH level voltage pulse appearing at the source of the Tr63 is applied to the gates of the MOS transistors Tr4Y and Tr5Y constituting the pulse output unit 103Y, so that the MOS transistors Tr4Y and Tr5Y enter in the conducting state. A voltage level becomes LOW at the junctions J3Y and J4Y, so that both terminals of the capacitor C1Y are grounded, and the C1Y is discharged (shifting ends).

<Configuration of the Vertical Scanning Shift Register 104>

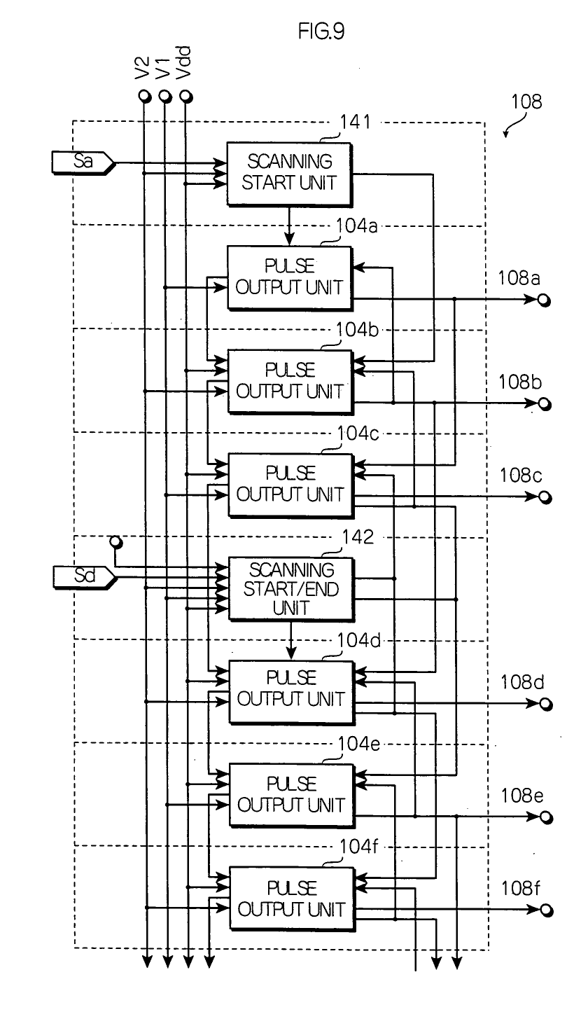

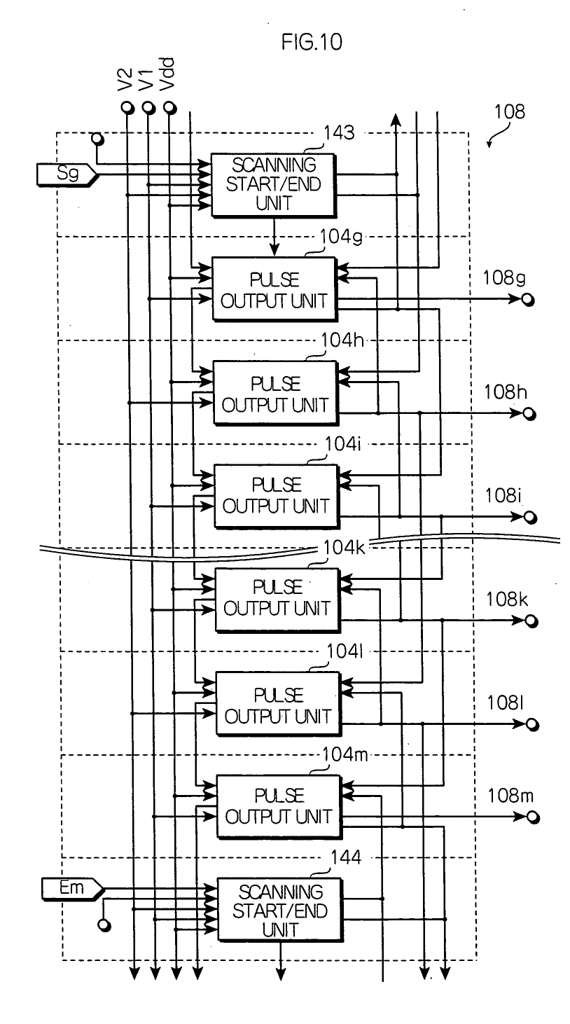

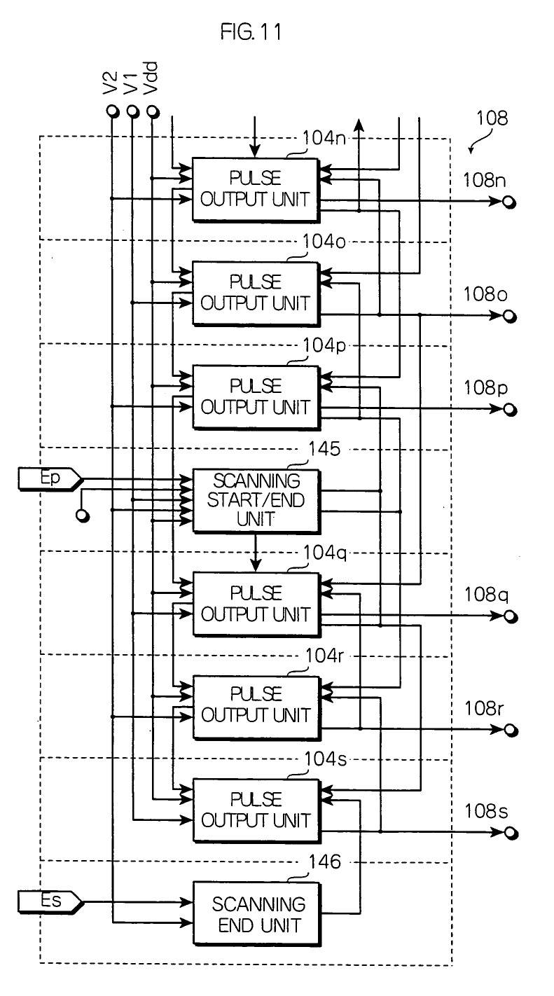

FIGS. 9 to 11 are functional block diagrams showing the configuration of the vertical scanning shift register relating to the first embodiment.

As shown in FIGS. 9 to 11, the vertical scanning shift register 104 includes pulse output unit 104a to 104s, a scanning start unit 141, scanning start/end units 142 to 145, and a scanning end unit 146. The vertical scanning shift register 104 has terminals Vdd, V1, and V2. The pulse generating unit 105 applies a source voltage to the terminal Vdd, and applies a voltage pulse individually to each of the V1 and the V2. The vertical scanning shift register 104 sequentially outputs, from its pulse output units, vertical selective pulses to the light-receiving unit 101 in such a manner that an active pulse output unit to output a vertical selective pulse is sequentially shifted in the direction from where the scanning start unit 141 is positioned toward where the scanning end unit 146 is positioned.

Hereafter, a voltage pulse applied to the vertical scanning shift register 104 via the terminal V1 is referred to as a first vertical shift pulse, and a voltage pulse applied to the vertical scanning shift register 104 via the terminal V2 is referred to as a second vertical shift pulse. It is assumed that in the present embodiment when the first vertical shift pulse is applied as being set at HIGH level, the second vertical shift pulse is applied as being set at LOW level, and vice versa.

Further, the vertical scanning shift register 104 has terminals Sa, Sd, Sg, Em, Ep, and Es. The pulse generating circuit 105 applies a voltage pulse individually to each of the terminals Sa, Sd, Sg, Em, Ep, and Es.

The terminal Sa is connected to the scanning start unit 141, the terminal Sd to the scanning start/end unit 142, and the terminal Sg to the scanning start/end unit 143. The terminal Em is connected to the scanning start/end unit 144, the terminal Ep to the scanning start/end unit 145, and the terminal Es to the scanning end unit 146.

<Circuit Configuration of the Vertical Scanning Shift Register 104>

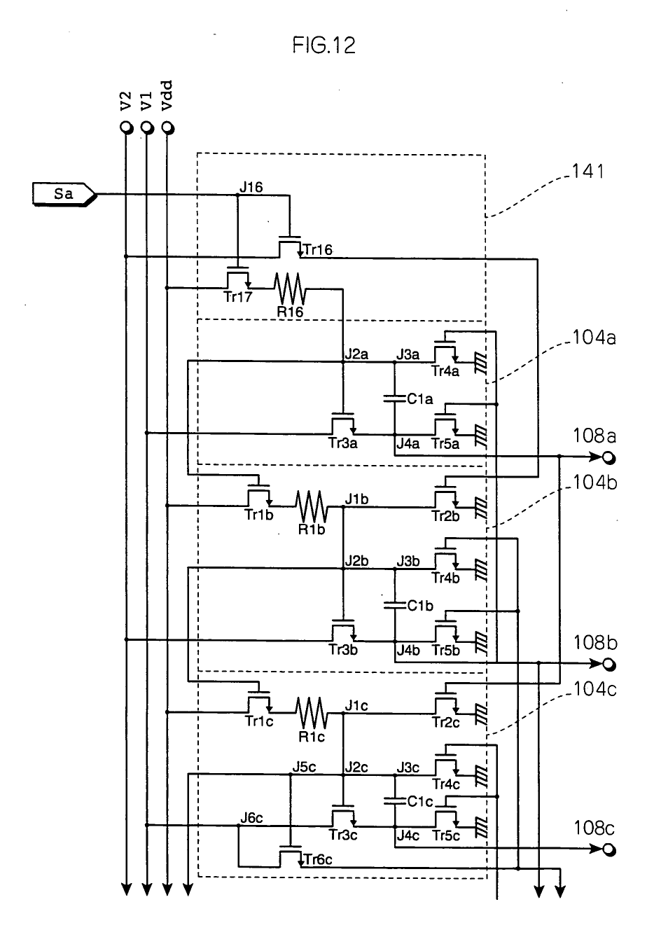

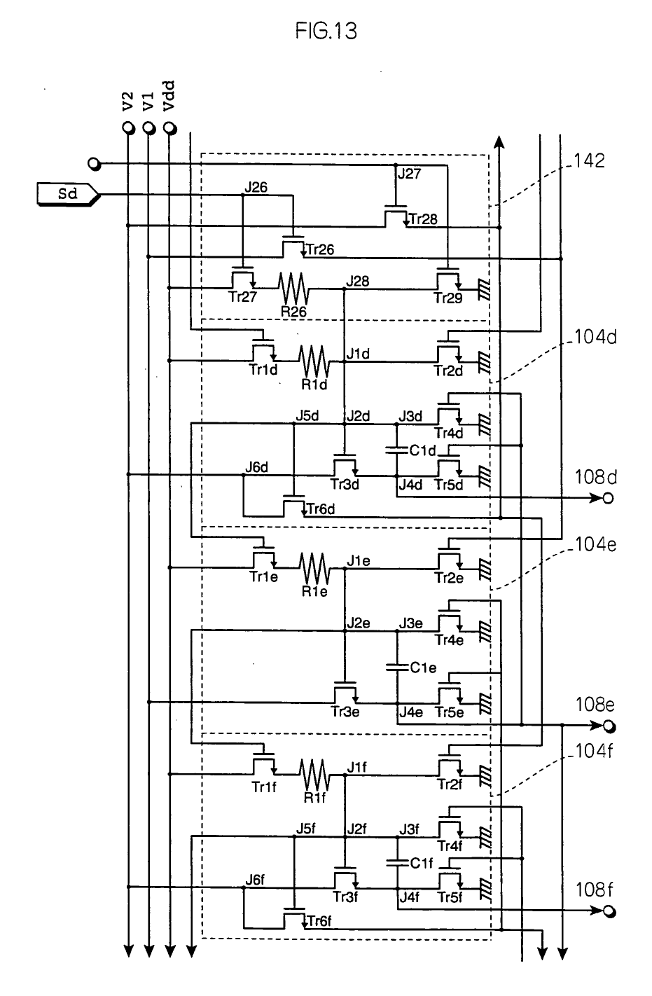

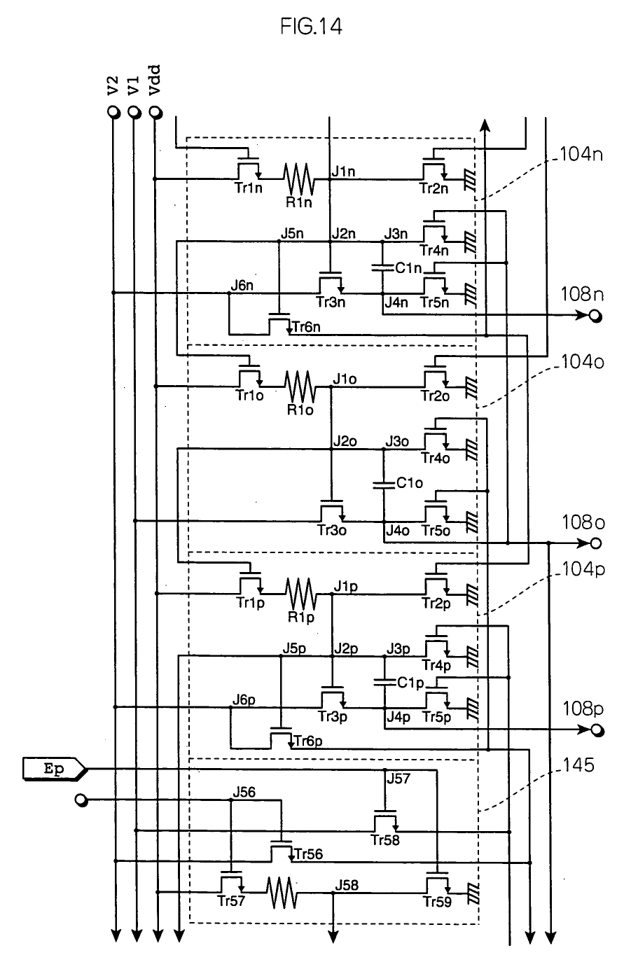

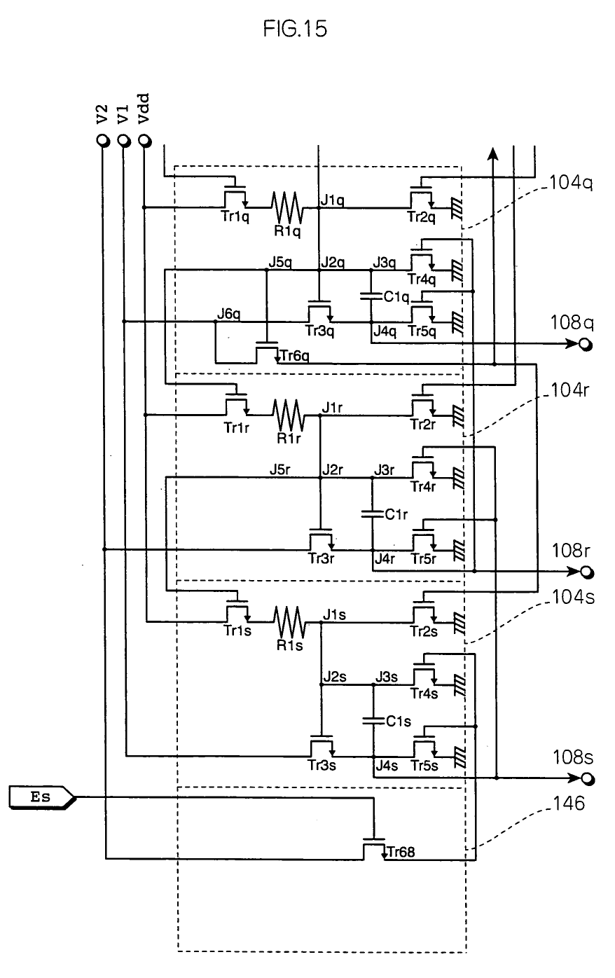

As one example, FIGS. 12 to 15 are circuit diagrams showing the configuration of the vertical scanning shift register relating to the first embodiment.

As shown in FIGS. 12 to 15, the vertical scanning shift register 104 includes the same components as the components of the horizontal scanning shift register 103, and therefore is not described here.

<Operation of the CCD 100>

The following describes the operation of the CCD 100 including the horizontal scanning shift register 103 and the vertical scanning shift register 104 having the above-described configurations. The following description exemplifies the case where one of scanning areas A, B, and C described below is selectively scanned, according to a voltage pulse applied from the pulse generating circuit 105 to the horizontal scanning shift register 103 and the vertical scanning shift register 104.

(Scanning Area A) An area composed of pixel units positioned at columns from “A” to “Y” in the horizontal direction and rows from “a” to “s” in the vertical direction.

(Scanning Area B) An area composed of pixel units positioned at columns from “E” to “U” in the horizontal direction and rows from “d” to “p” in the vertical direction.

(Scanning Area C) An area composed of pixel units positioned at columns from “I” to “Q” in the horizontal direction and rows from “g” to “m” in the vertical direction.

The following describes each of the operation example 1 where the scanning area A is scanned, the operation example 2 where the scanning area B is scanned, and the operation example 3 where the scanning area C is scanned.

<Operation Example 1 in the First Embodiment>

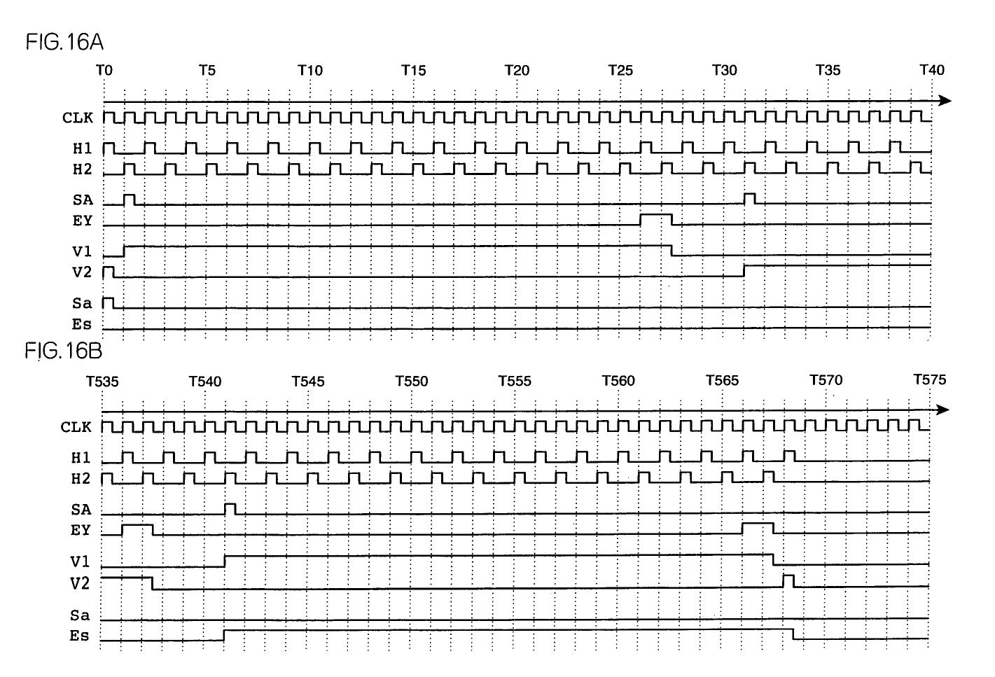

FIGS. 16A and 16B show timing charts for voltage pulses applied from the pulse generating circuit to the horizontal scanning shift register and the vertical scanning shift register when the scanning area A is scanned in the first embodiment. FIG. 16A shows a timing chart when the scanning starts, whereas FIG. 16B shows a timing chart when the scanning ends.

As shown in FIGS. 16A and 16B, voltage pulses are applied from the pulse generating circuit 105 to the components of the horizontal scanning shift register 103 and the vertical scanning shift register 104 via the clock, terminals H1, H2, SA, EY, V1, V2, Sa, and Es in the stated order shown from top down.

To be more specific, to the components of the horizontal scanning shift register 103, a HIGH level first horizontal shift pulse is applied via the terminal H1 for one clock from “T0” with a two-clock cycle, and a HIGH level second horizontal shift pulse is applied via the terminal H2 for one clock from “T1” with a two-clock cycle. Further, to the scanning start unit 131, a HIGH level voltage pulse is applied via the terminal SA for one clock from “T1” with a 30-clock cycle. To the scanning end unit 136, a HIGH level voltage pulse is applied via the terminal EY for two clocks from “T26” with a 30-clock cycle.

In the same manner, to the components of the vertical scanning shift register 104, a HIGH level first vertical shift pulse is applied via the terminal V1 for 27 clocks from “T1” with a 60-clock cycle. A HIGH level second vertical shift pulse is applied via the terminal V2 for one clock from “T0” and for 27 clocks from “T31” with a 60-clock cycle, and for one clock from “T568”. Further, to the scanning start unit 141, a HIGH level voltage pulse is applied via the terminal Sa for one clock from “T0”. To the scanning end unit 146, a HIGH level voltage pulse is applied via the terminal Es for 28 clocks from “T541”.

Here, the following describes one example case where one row is scanned in the horizontal direction during the time from “T0” to “T28”, based on the timing charts shown in FIGS. 16A and 16B.

Here, to the vertical scanning shift register 104, a LOW level first vertical shift pulse is applied, and a HIGH level second vertical shift pulse is applied, and a HIGH level voltage pulse is applied to the scanning start unit 141 via the terminal Sa, from the pulse generating circuit 105, so that the pulse output unit 104a makes a state transition to the charging state, and the pulse output unit 104b makes a state transition to the insulating state (“T0”). Further, a HIGH level first vertical shift pulse is applied, a LOW level second vertical shift pulse is applied, and a HIGH level voltage pulse is applied to the scanning start unit 141 via the terminal Sa, so that the pulse output unit 104a makes a state transition to the outputting-state, the pulse output unit 104b makes a state transition to the charging-state, and the pulse output unit 104c makes a state transition to the insulating-state (“T1”).

Hereafter, it is assumed that a vertical selective pulse is being output from the output unit 104a until “T28”, and a LOW level voltage pulse is being applied to the scanning end unit 146 via the terminal Es until “T541”.

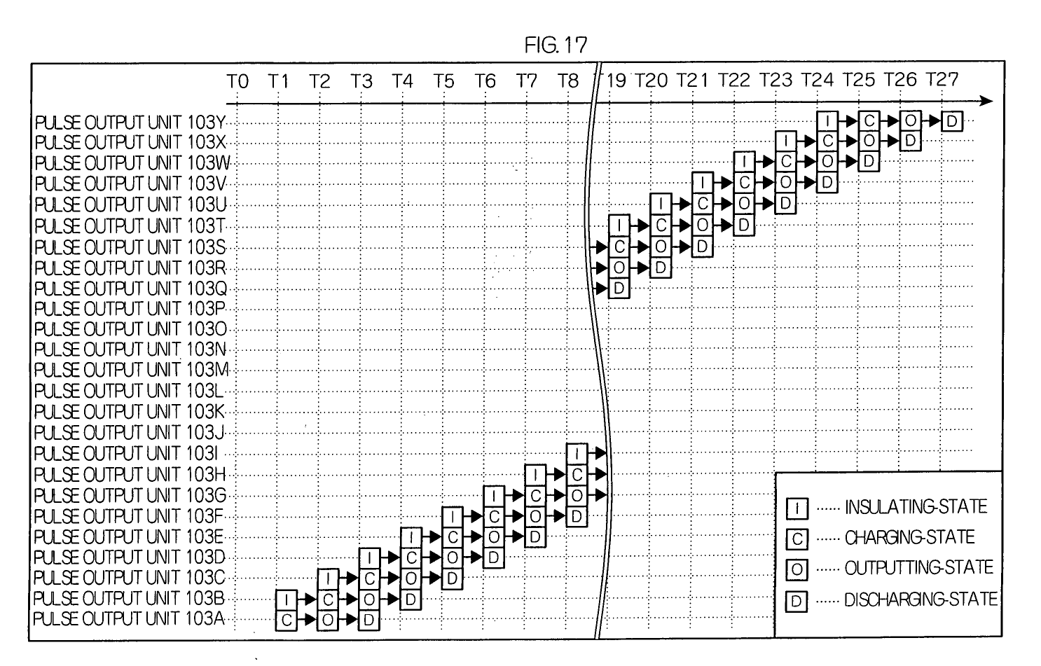

FIG. 17 shows the state transition of the horizontal scanning shift register relating to the first embodiment for the operation example 1. The state transition during the time from “T4” to “T24” is not described.

As shown in the figure, to the horizontal scanning shift register 103, a LOW level first horizontal shift pulse is applied, a HIGH level second horizontal shift pulse is applied, and a HIGH level voltage pulse is applied to the scanning start unit 131 via the terminal SA, from the pulse generating circuit 105, so that the pulse output unit 103A makes a state transition to the charging-state, and the pulse output unit 103B makes a state transition to the insulating-state (“T1”). Further, a HIGH level first horizontal shift pulse is applied, a LOW level second horizontal shift pulse is applied, and a HIGH level voltage pulse is applied to the scanning start unit 131 via the terminal SA, so that the pulse output unit 103A makes a state transition to the outputting-state, the pulse output unit 103B makes a state transition to the charging-state, and the pulse output unit 103C makes a state transition to the insulating-state (“T2”). Further, a LOW level first horizontal shift pulse is applied, a HIGH level second horizontal shift pulse is applied, and a LOW level voltage pulse is applied to the scanning start unit 131 via the terminal SA, so that the pulse output unit 103A makes a state transition to the discharging-state, the pulse output unit 103B makes a state transition to the outputting-state, the pulse output unit 103C makes a state transition to the charging-state, and the pulse output unit 103D makes a state transition to the insulating-state (“T3”).

After that, to the horizontal scanning shift register 103, a LOW level first horizontal shift pulse is applied, a HIGH level second horizontal shift pulse is applied, and a LOW level voltage pulse is applied to the scanning end unit 136 via the terminal EY, from the pulse generating circuit 105, so that the pulse output unit 103W makes a state transition to the discharging-state, the pulse output unit 103X makes a state transition to the outputting-state, and the pulse output unit 103Y makes a state transition to the charging-state (“T25”). Further, a HIGH level first horizontal shift pulse is applied, a LOW level second horizontal shift pulse is applied, and a HIGH level voltage pulse is applied to the scanning end unit 136 via the terminal EY, so that the pulse output unit 103X makes a state transition to the discharging-state, and the pulse output unit 103Y makes a state transition to the outputting-state (“T26”). Then, a LOW level first horizontal shift pulse is applied, a HIGH level second horizontal shift pulse is applied, and a HIGH level voltage pulse is applied to the scanning end unit 136 via the terminal EY, so that the pulse output unit 103Y makes a state transition to the discharging-state (“T27”).

As described above, a horizontal selective pulse is output from each of the pulse output units 103A to 103Y, resulting in the pixel units 101Aa to 101Ya being scanned. In the same manner, to each of the active pulse output units 104b to 104s in the vertical scanning shift register 104, a horizontal selective pulse is output from each of the pulse output units 103A to 103Y, resulting in the scanning area A being scanned.

<Operation Example 2 in the First Embodiment>

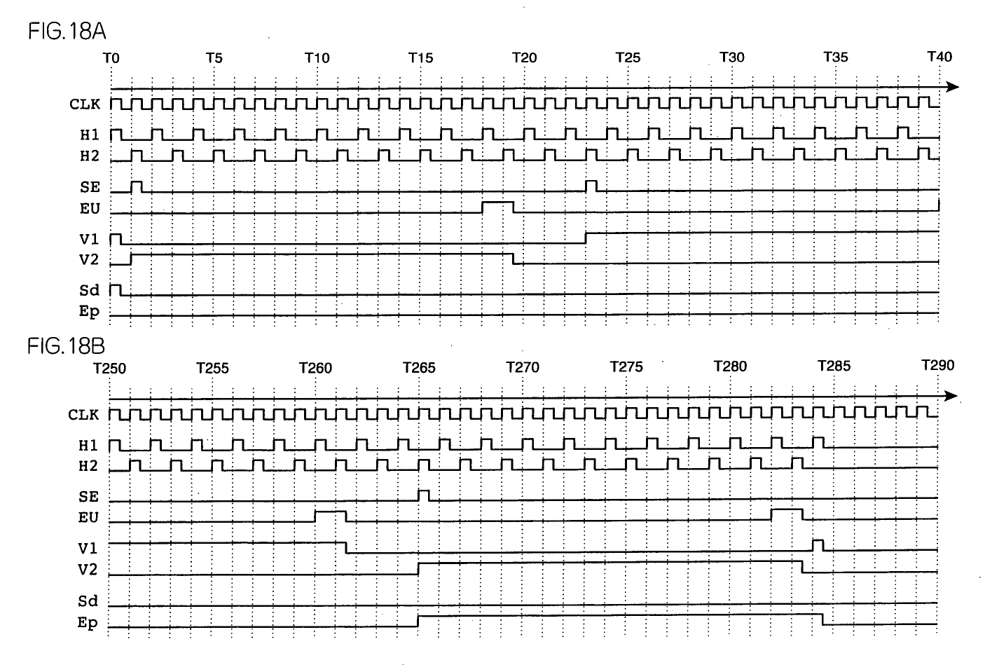

FIGS. 18A and 18B show timing charts for voltage pulses applied from the pulse generating circuit to the horizontal scanning shift register and the vertical scanning shift register when the scanning area B is scanned in the first embodiment. FIG. 18A shows a timing chart when the scanning starts, whereas FIG. 18B shows a timing chart when the scanning ends.

As shown in FIGS. 18A and 18B, voltage pulses are applied from the pulse generating circuit 105 to the components of the horizontal scanning shift register 103 and the vertical scanning shift register 104 via the clock, terminals H1, H2, SE, EU, V1, V2, Sd, and Ep in the stated order shown from top down.

To be more specific, to the components of the horizontal scanning shift register 103, a HIGH level first horizontal shift pulse is applied via the terminal H1 for one clock from “T0” with a two-clock cycle, and a HIGH level second horizontal shift pulse is applied via the terminal H2 for one clock from “T1” with a two-clock cycle. Further, to the scanning start/end unit 132, a HIGH level voltage pulse is applied via the terminal SE for one clock from “T1” with a 22-clock cycle. To the scanning start/end unit 135, a HIGH level voltage pulse is applied via the terminal EU for two clocks from “T18” with a 22-clock cycle.

In the same manner, to the components of the vertical scanning shift register 104, a HIGH level first vertical shift pulse is applied via the terminal V1 for one clock from “T0”, for 19 clocks from “T23” with a 44-clock cycle, and for one clock from “T284”, and a HIGH level second vertical shift pulse is applied via the terminal V2 for 19 clocks from “T1” with a 44-clock cycle. Further, to the scanning start/end unit 142, a HIGH level voltage pulse is applied via the terminal Sd for one clock from “T0”. To the scanning start/end unit 145, a HIGH level voltage pulse is applied via the terminal Ep for 20 clocks from “T265”.

Here, the following describes one example case where one row is scanned in the horizontal direction during the time from “T0” to “T20”, based on the timing charts shown in FIGS. 18A and 18B.

Here, to the vertical scanning shift register 104, a HIGH level first vertical shift pulse is applied, and a LOW level second vertical shift pulse is applied, and a HIGH level voltage pulse is applied to the scanning start/end unit 142 via the terminal Sd, from the pulse generating circuit 105, so that the pulse output unit 104d makes a state transition to the charging-state, and the pulse output unit 104e makes a state transition to the insulating-state (“T0”). Further, a LOW level first vertical shift pulse is applied, a HIGH level second vertical shift pulse is applied, and a HIGH level voltage pulse is applied to the scanning start/end unit 142 via the terminal Sd, so that the pulse output unit 104d makes a state transition to the.outputting-state, the pulse output unit 104e makes a state transition to the charging-state, and the pulse output unit 104f makes a state transition to the insulating-state (“T1”).

Hereafter, it is assumed that a vertical selective pulse is being output from the pulse output unit 104d until “T20”, and a LOW level voltage pulse is being applied to the scanning start/end unit 145 via the terminal Ep until “T265”.

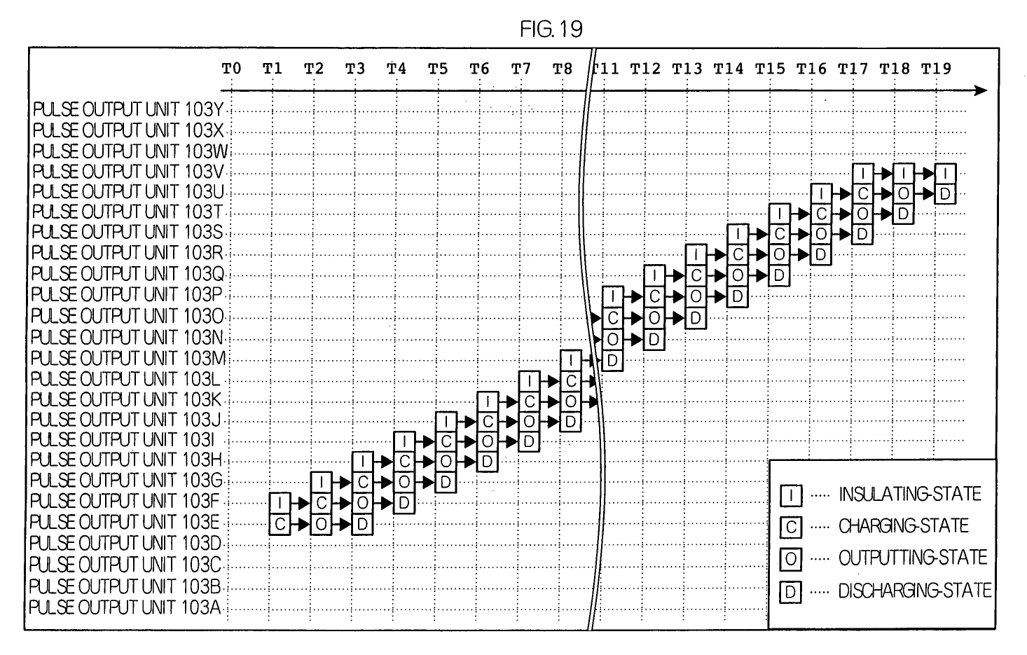

FIG. 19 shows the state transition of the horizontal scanning shift register relating to the first embodiment for the operation example 2. The state transition during the time from “T4” to “T16” is not described.

As shown in the figure, to the horizontal scanning shift register 103, a LOW level first horizontal shift pulse is applied, a HIGH level second horizontal shift pulse is applied, and a HIGH level voltage pulse is applied to the scanning start/end unit 132 via the terminal SE, from the pulse generating circuit 105, so that the pulse output unit 103E makes a state transition to the charging-state, and the pulse output unit 103F makes a state transition to the insulating-state (“T1”). Further, a HIGH level first horizontal shift pulse is applied, a LOW level second horizontal shift pulse is applied, and a HIGH level voltage pulse is applied to the scanning start/end unit 132 via the terminal SE, so that the pulse output unit 103E makes a state transition to the outputting-state, the pulse output unit 103F makes a state transition to the charging-state, and the pulse output unit 103G makes a state transition to the insulating-state (“T2”). Further, a LOW level first horizontal shift pulse is applied, a HIGH level second horizontal shift pulse is applied, and a LOW level voltage pulse is applied to the scanning start/end unit 132 via the terminal SE, so that the pulse output unit 103E makes a state transition to the discharging-state, the pulse output unit 103F makes a state transition to the outputting-state, the pulse output unit 103G makes a state transition to the charging-state, and the pulse output unit 103H makes a state transition to the insulating-state (“T3”).

After that, to the horizontal scanning shift register 103, a LOW level first horizontal shift pulse is applied, a HIGH level second horizontal shift pulse is applied, and a LOW level voltage pulse is applied to the scanning start/end unit 135 via the terminal EU from the pulse generating circuit 105, so that the pulse output unit 103S makes a state transition to the discharging-state, the pulse output unit 103T makes a state transition to the outputting-state, the pulse output unit 103U makes a state transition to the charging-state, and the pulse output unit 103V makes a state transition to the insulating-state (“T17”). Further, a HIGH level first horizontal shift pulse is applied, a LOW level second horizontal shift pulse is applied, and a HIGH level voltage pulse is applied to the scanning start/end unit 135 via the terminal EU, so that the pulse output unit 103T makes a state transition to the discharging-state, the pulse output unit 103U makes a state transition to the outputting-state, and the pulse output unit 103V makes a state transition to the insulating-state (“T18”). Then, a LOW level first horizontal shift pulse is applied, a HIGH level second horizontal shift pulse is applied, and a HIGH level voltage pulse is applied to the scanning start/end unit 135 via the terminal EU, so that the pulse output unit 103U makes a state transition to the discharging-state, and the pulse output unit 103V makes a state transition to the insulating-state (“T19”).

As described above, a horizontal selective pulse is output from each of the pulse output units 103E to 103U, resulting in the pixel units 101Ed to 101Ud being scanned. In the same manner, to each of the active pulse output units 104e to 104p in the vertical scanning shift register 104, a horizontal selective pulse is output from each of the pulse output units 103E to 103U, resulting in the scanning area B being scanned.

<Operation Example 3 in the First Embodiment>

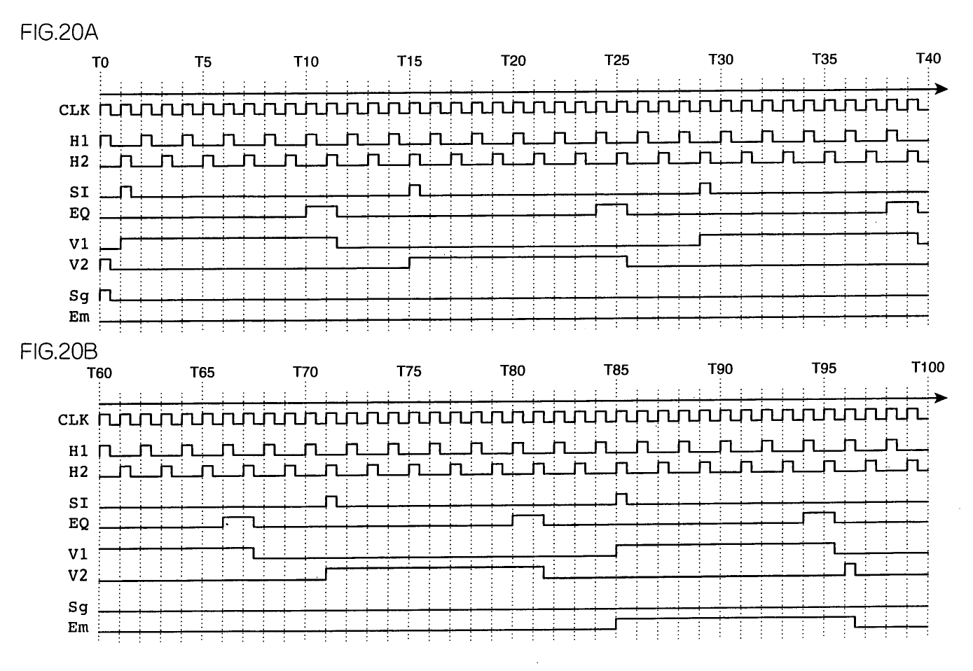

FIGS. 20A and 20B show timing charts for voltage pulses applied from the pulse generating circuit to the horizontal scanning shift register and the vertical scanning shift register when the scanning area C is scanned in the first embodiment. FIG. 20A shows a timing chart when the scanning starts, whereas FIG. 20B shows a timing chart when the scanning ends.

As shown in FIGS. 20A and 20B, voltage pulses are applied from the pulse generating circuit 105 to the components of the horizontal scanning shift register 103 and the vertical scanning shift register 104 via the clock, terminals H1, H2, SI, EQ, V1, V2, Sg, and Em in the stated order shown from top down.

To be more specific, to the components of the horizontal scanning shift register 103, a HIGH level first horizontal shift pulse is applied via the terminal H1 for one clock from “T0” with a two-clock cycle, and a HIGH level second horizontal shift pulse is applied via the terminal H2 for one clock from “T1” with a two-clock cycle. Further, to the scanning start/end unit 133, a HIGH level voltage pulse is applied via the terminal SI for one clock from “T1” with a 14-clock cycle. To the scanning start/end unit 134, a HIGH level voltage pulse is applied via the terminal EQ for two clocks from “T10” with a 14-clock cycle.

In the same manner, to the components of the vertical scanning shift register 104, a HIGH level first vertical shift pulse is applied via the terminal V1 for 11 clocks from “T1” with a 28-clock cycle, a HIGH level second vertical shift pulse is applied via the terminal V2 for one clock from “T0”, for one clock from “T15” with a 28-clock cycle, and for one clock from “T96”. Further, to the scanning start/end unit 143, a HIGH level voltage pulse is applied via the terminal Sg for one clock from “T0”. To the scanning start/end unit 144, a HIGH level voltage pulse is applied via the terminal Em for 12 clocks from “T85”.

Here, the following describes one example case where one row is scanned in the horizontal direction during the time from “T0” to “T12”, based on the timing charts shown in FIGS. 20A and 20B.

Here, to the vertical scanning shift register 104, a LOW level first vertical shift pulse is applied, and a HIGH level second vertical shift pulse is applied, and a HIGH level voltage pulse is applied to the scanning start/end unit 143 via the terminal Sg, from the pulse generating circuit 105, so that the pulse output unit 104g makes a state transition to the charging-state, and the pulse output unit 104h makes a state transition to the insulating-state (“T0”). A HIGH level first vertical shift pulse is applied, a LOW level second vertical shift pulse is applied, and a HIGH level voltage pulse is applied to the scanning start/end unit 143 via the terminal Sg, so that the pulse output unit 104g makes a state transition to the outputting-state, the pulse output unit 104h makes a state transition to the charging-state, and the pulse output unit 104i makes a state transition to the insulating-state (“T1”).

Hereafter, it is assumed that a vertical selective pulse is being output from the pulse output unit 104g until “T12”, and a LOW level voltage pulse is being applied to the scanning start/end unit 144 via the terminal Em until “T84”.

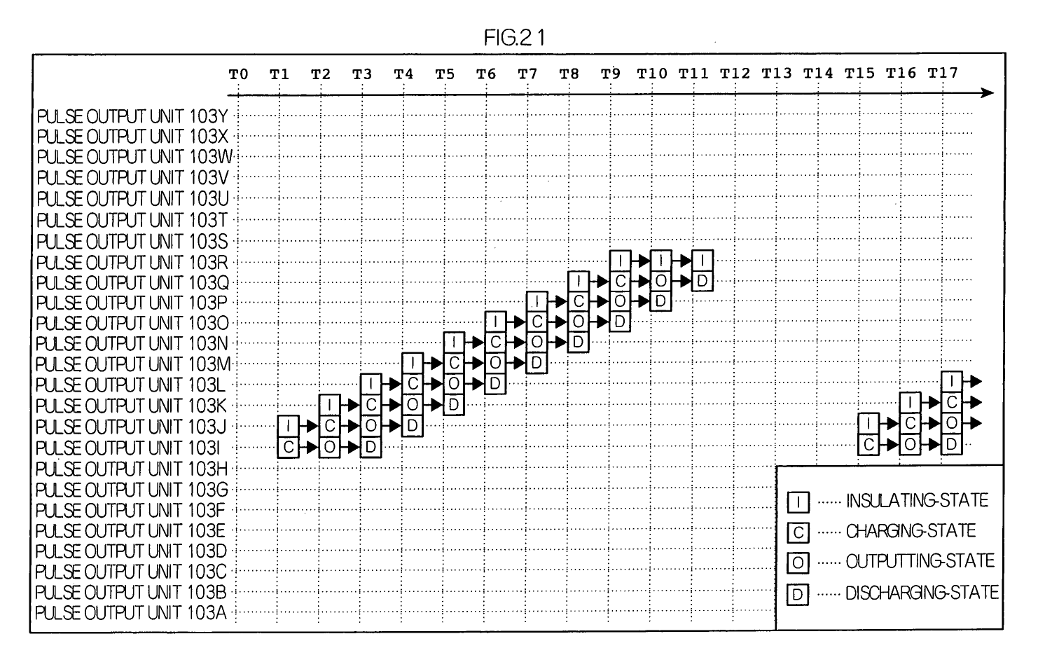

FIG. 21 shows the state transition of the horizontal scanning shift register relating to the first embodiment for the operation example 3. The state transition during the time from “T4” to “T8” is not described.

As shown in the figure, to the horizontal scanning shift register 103, a LOW level first horizontal shift pulse is applied, a HIGH level second horizontal shift pulse is applied, and a HIGH level voltage pulse is applied to the scanning start/end unit 133 via the terminal SI, from the pulse generating circuit 105, so that the pulse output unit 103I makes a state transition to the charging-state, and the pulse output unit 103J makes a state transition to the insulating-state (“T1”). Further, a HIGH level first horizontal shift pulse is applied, a LOW level second horizontal shift pulse is applied, and a HIGH level voltage pulse is applied to the scanning start/end unit 133 via the terminal SI, so that the pulse output unit 103I makes a state transition to the outputting-state, the pulse output unit 103J makes a state transition to the charging-state, and the pulse output unit 103K makes a state transition to the insulating-state (“T2”). Further, a LOW level first horizontal shift pulse is applied, a HIGH level second horizontal shift pulse is applied, and a LOW level voltage pulse is applied to the scanning start/end unit 132 via the terminal SI, so that the pulse output unit 103I makes a state transition to the discharging-state, the pulse output unit 103J makes a state transition to the outputting-state, the pulse output unit 103K makes a state transition to the charging-state, and the pulse output unit 103L makes a state transition to the insulating-state (“T3”).

After that, to the horizontal scanning shift register 103, a LOW level first horizontal shift pulse is applied, a HIGH level second horizontal shift pulse is applied, and a LOW level voltage pulse is applied to the scanning start/end unit 134 via the terminal EQ, from the pulse generating circuit 105, so that the pulse output unit 1030 makes a state transition to the discharging-state, the pulse output unit 103P makes a state transition to the outputting-state, the pulse output unit 103Q makes a state transition to the charging-state, and the pulse output unit 103R makes a state transition to the insulating state (“T9”). Further, a HIGH level first horizontal shift pulse is applied, a LOW level second horizontal shift pulse is applied, and a HIGH level voltage pulse is applied to the scanning start/end unit 134 via the terminal EQ, so that the pulse output unit 103P makes a state transition to the discharging-state, the pulse output unit 103Q makes a state transition to the outputting-state, and the pulse output unit 103R makes a state transition to the insulating-state (“T10”). Then, a LOW level first horizontal shift pulse is applied, a HIGH level second horizontal shift pulse is applied, and a HIGH level voltage pulse is applied to the scanning start/end unit 134 via the terminal EQ, so that the pulse output unit 103Q makes a state transition to the discharging-state, and the pulse output unit 103R makes a state transition to the insulating-state (“T1”).

As described above, a horizontal selective pulse is output from each of the pulse output units 103I to 103Q, resulting in the pixel units 101Ig to 101Qg being scanned. In the same manner, to each of the active pulse output units 104h to 104m in the vertical scanning shift register 104, a horizontal selective pulse is output from each of the pulse output units 103I to 103Q, resulting in the scanning area C being scanned.

<Summary of the First Embodiment>

As described above, the horizontal scanning shift register 103 and the vertical scanning shift register 104 respectively output a horizontal selective pulse and a vertical selective pulse, and apply the horizontal selective pulse to the gates of the horizontal MOS transistors Tr15A to Tr15Y constituting the switch unit 102, and apply the vertical selective pulse to the gates of the vertical MOS transistors Tr11Aa to Tr11Ys constituting the light-receiving unit 101, to select one pixel unit after another for reading a signal charge from the selected pixel unit. In this way, a signal charge accumulated in a photodiode of the selected pixel unit is read and output to the switch unit 102 via the vertical signal lines 109A to 109Y.

Here, according to a voltage pulse applied from the pulse generating circuit 105, a horizontal MOS transistor to which a horizontal selective pulse is applied, and a vertical MOS transistor to which a vertical selective pulse is applied are controlled.

<Second Embodiment>

The following describes a second embodiment of the present invention, with reference to the drawings. It should be noted here that components and operations in the second embodiment that are the same as the components and the operations described in the first embodiment are given the same reference numerals as used in the first embodiment, and are not described in the second embodiment.

<Configuration of the CCD 200>

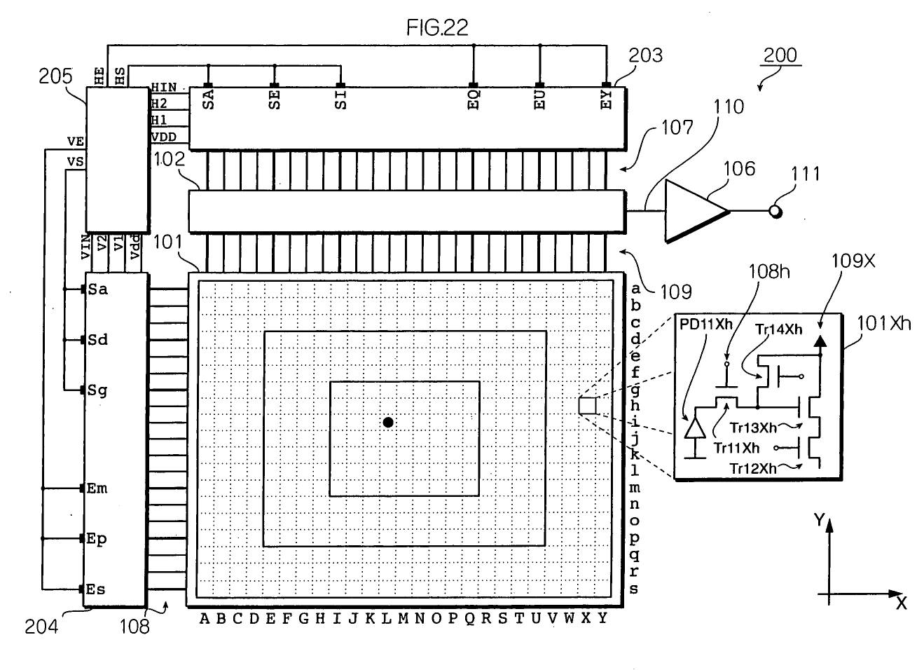

FIG. 22 is a functional block diagram showing a configuration of a CCD relating to the second embodiment.

As shown in the figure, the CCD 200 differs from the CCD 100 in that it includes a horizontal scanning shift register 203, a vertical scanning shift register 204, and a pulse generating circuit 205 instead of the horizontal scanning shift register 103, the vertical scanning shift register 104, and the pulse generating circuit 105.

<Configuration of the Horizontal Scanning Shift Register 203>

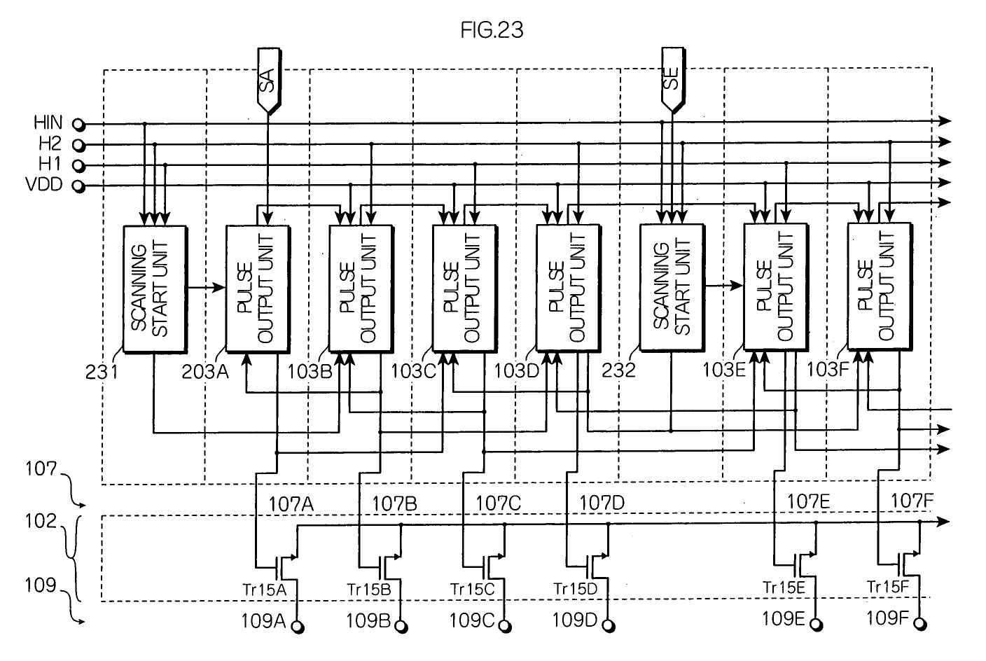

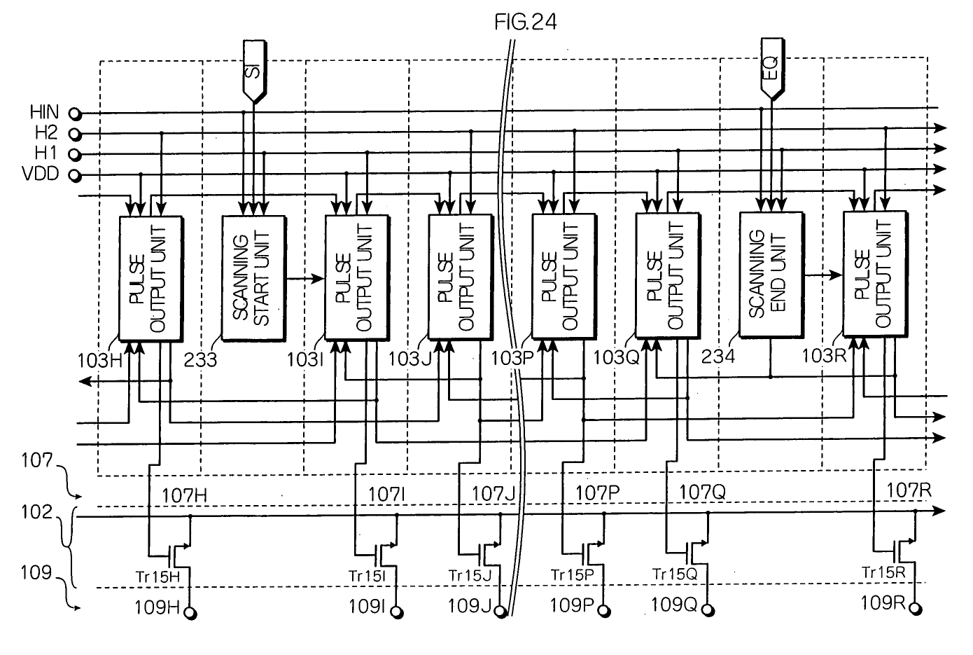

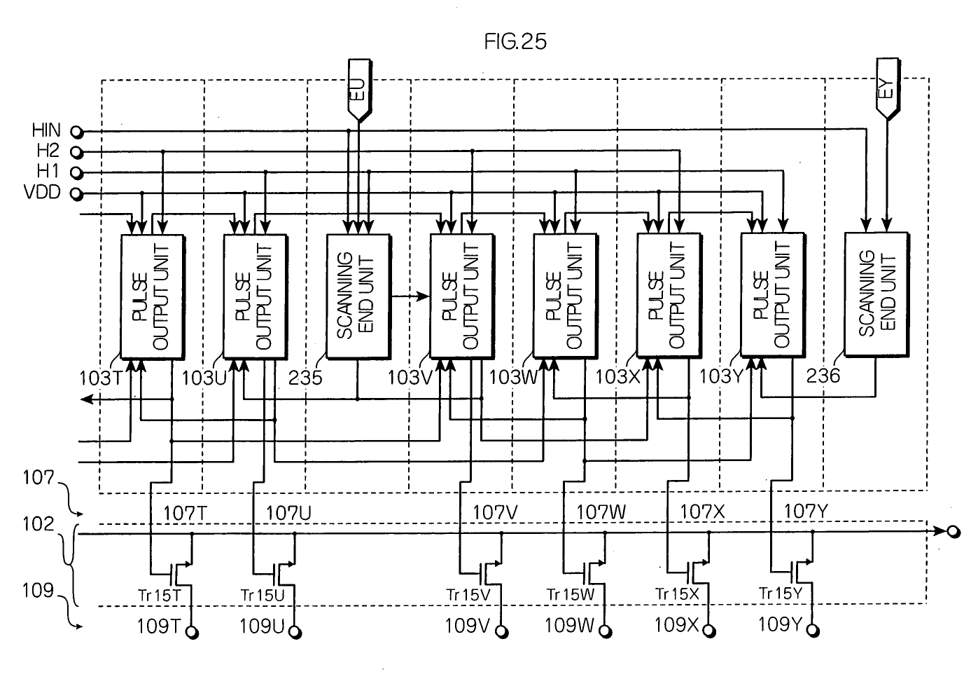

FIGS. 23 to 25 are functional block diagrams showing a configuration of the horizontal scanning shift register relating to the second embodiment.

As shown in FIGS. 23 to 25, the horizontal scanning shift register 203 includes a pulse output unit 203A, scanning start units 231 to 233, and scanning end units 234 to 236, instead of the pulse output unit 103A, the scanning start unit 131, the scanning start/end units 132 to 135, and the scanning end unit 136. The horizontal scanning shift register 203 differs from the horizontal scanning shift register 103 in the first embodiment in that the same voltage pulse (hereafter referred to as a “horizontal shift start pulse”) is applied to each of the terminals SA, SE, and SI, instead of a different voltage pulse being individually applied to each of the terminals SA, SE, SI, EQ, EU, and EY. Apart from the horizontal shift start pulse, the same voltage pulse (hereafter referred to as a “horizontal shift end pulse”) is applied from the pulse generating circuit 205 to each of the terminals EQ, EU, and EY. Further, a voltage pulse (hereafter referred to as a “horizontal scanning start/end pulse”) is applied from the pulse generating circuit 205 via the terminal HIN. Also, the horizontal scanning shift register 203 starts outputting a horizontal selective pulse from a different pulse output unit, depending on a combination of a first horizontal shift pulse, a second horizontal shift pulse, a horizontal shift start pulse, a horizontal shift end pulse, and a horizontal scanning start/end pulse.

For example, when a HIGH level horizontal shift start pulse is applied after a HIGH level horizontal scanning start/end pulse, a HIGH level second horizontal shift pulse, and a HIGH level first horizontal shift pulse are applied, the horizontal scanning shift register 203 starts outputting a horizontal selective pulse from the pulse output unit 203A. In the same manner, when a HIGH level first horizontal shift pulse is applied after a HIGH level horizontal scanning start/end pulse, a HIGH level horizontal shift start pulse, and a HIGH level second horizontal shift pulse are applied, the horizontal scanning shift register 203 starts outputting a horizontal selective pulse from the pulse output unit 103E. Also, when a HIGH level horizontal scanning start/end pulse, a HIGH level first horizontal shift pulse, and a HIGH level horizontal shift start pulse are applied, the horizontal scanning shift register 203 starts outputting a horizontal selective pulse from the pulse output unit 103I. After a horizontal selective pulse is output from one of the pulse output units 203A, 103E, and 103I, an active pulse output unit to output a horizontal selective pulse is sequentially shifted in the direction from where the scanning start unit 231 is positioned toward where the scanning end unit 236 is positioned.

Further, if a LOW level horizontal scanning start/end pulse, a HIGH level horizontal shift end pulse, and a HIGH level first horizontal shift pulse are applied when the pulse output unit 103Q outputs a horizontal selective pulse, a horizontal selective pulse is output from pulse output units preceding the pulse output unit 103Q and from the pulse output unit 103Q, but is not output from the pulse output unit 103R and the following pulse output units. In the same manner, if a LOW level horizontal scanning start/end pulse, a HIGH level horizontal shift end pulse, and a HIGH level first horizontal shift pulse are applied when the pulse output unit 103U outputs a horizontal shift pulse, a horizontal selective pulse is output from pulse output units preceding the pulse output unit 103U and from the pulse output unit 103U, but is not output from the pulse output unit 103V and the following pulse output units. In the other cases, a horizontal selective pulse is sequentially output from one pulse output unit after another, with the pulse output unit 103Y being the last unit to output a horizontal selective pulse.

It should be noted here that a HIGH level horizontal shift start pulse is not applied to the terminals SA, SE, and SI while the active pulse output unit to output a horizontal selective pulse is being shifted.

<Circuit Configuration of the Horizontal Scanning Shift Register 203>

The following describes a circuit configuration of the horizontal scanning shift register 203 having the above-described configuration.

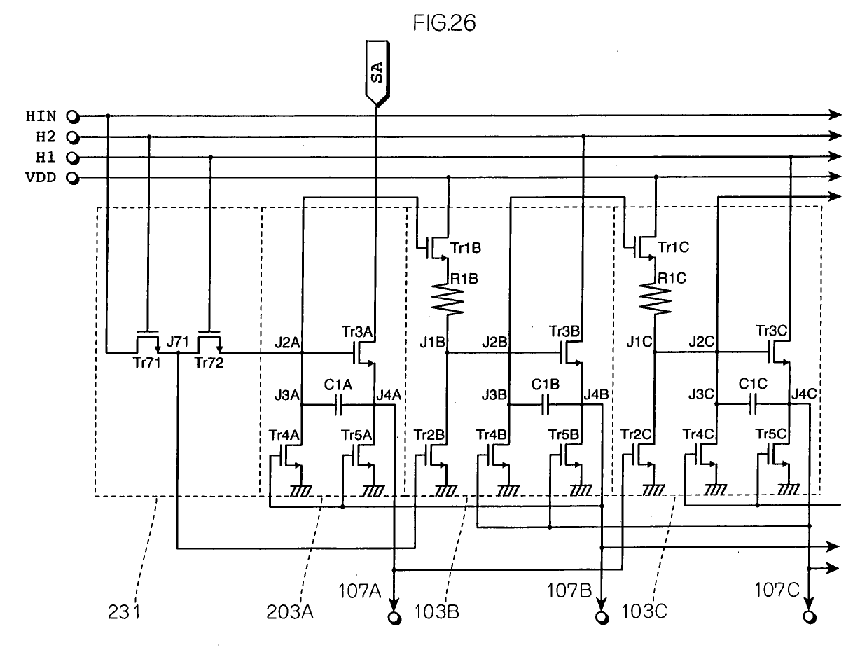

As one example, FIGS. 26 to 29 are circuit diagrams showing the configuration of the horizontal scanning shift register relating to the second embodiment.

The circuit configuration in FIG. 26 includes the pulse output unit 203A and the scanning start unit 231, instead of the pulse output unit 103A and the scanning start unit 131.

<Pulse Output Unit 203A>

The pulse output unit 203A differs from the pulse output unit 103A in that a horizontal shift start pulse is applied from the pulse generating circuit 205 to the drain of the Tr3A via the terminal SA, instead of a first horizontal shift pulse being applied via the terminal H1.

<Scanning Start Unit 231>

The scanning start unit 231 includes MOS transistors Tr71 and Tr72, and wiring lines that connect these components.

To the MOS transistor Tr71 (hereafter simply, “Tr71”), a horizontal scanning start/end pulse is applied to its drain via the terminal HIN. When a HIGH level second horizontal shift pulse is applied to its gate via the terminal H2, the Tr71 enters in the conducting state. A voltage pulse according to a voltage level of the horizontal scanning start/end pulse then appears at the source of the Tr71.

The MOS transistor Tr72 (hereafter simply, “Tr72”) has its drain connected to the source of the Tr71. When a HIGH level horizontal shift pulse is applied to its gate via the terminal H1, the Tr72 enters in the conducting state. A voltage pulse according to a voltage level of the voltage pulse appearing at the source of the Tr71 then appears at the source of the Tr72.

Here, when a HIGH level first horizontal shift pulse, a HIGH level second horizontal shift pulse, and a HIGH level horizontal scanning start/end pulse are applied, a HIGH level voltage pulse appears at the source of the Tr71, and also, a HIGH level voltage pulse appears at the source of the Tr72. The HIGH level voltage pulse appearing at the source of the Tr72 is output from the scanning start unit 231 to the pulse output unit 203A. Due to this, a voltage level becomes HIGH at the junctions J2A and J3A of the pulse output unit 203A. Further, the output HIGH level voltage pulse is applied to the gate of the Tr3A, so that the Tr3A enters in the conducting state.

Also, the HIGH level voltage pulse appearing at the source of the Tr71 is applied to the gate of the Tr2B via the junction J71, so that the Tr2B enters in the conducting state. Regardless of whether the Tr1B is in the conducting state or in the non-conducting state, a voltage level becomes LOW at the junctions J1B, J2B, and J3B, and the Tr3B enters in the non-conducting state (shifting starts).

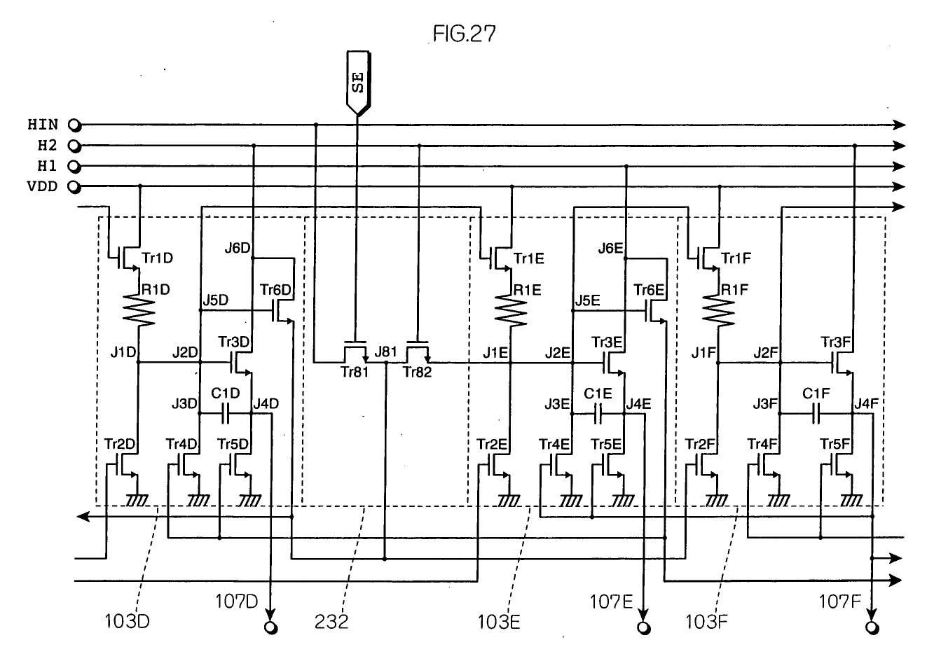

The circuit configuration in FIG. 27 includes the scanning start unit 232 instead of the scanning start unit 132.

<Scanning Start Unit 232>

The scanning start unit 232 includes MOS transistors Tr81 and Tr82, and wiring lines that connect these components.

To the MOS transistor Tr81 (hereafter simply, “Tr81”), a horizontal scanning start/end pulse is applied to its drain via the terminal HIN. When a HIGH level horizontal shift start pulse is applied to its gate via the terminal SE, the Tr81 enters in the conducting state. A voltage pulse according to a voltage level of the horizontal scanning start/end pulse then appears at the source of the Tr81.

The MOS transistor Tr82 (hereafter simply, “Tr82”) has its drain connected to the source of the Tr81. When a HIGH level second horizontal shift pulse is applied to its gate via the terminal H2, the Tr82 enters in the conducting state. A voltage pulse according to a voltage level of the voltage pulse appearing at the source of the Tr81 then appears at the source of the Tr82.

Here, when a HIGH level horizontal shift start pulse, a HIGH level second horizontal shift pulse, and a HIGH level horizontal scanning start/end pulse are applied, a HIGH level voltage pulse appears at the source of the Tr81, and also, a HIGH level voltage pulse appears at the source of the Tr82. The HIGH level voltage pulse appearing at the source of the Tr82 is output from the scanning start unit 232 to the pulse output unit 103E. Due to this, a voltage level becomes LOW at the junctions J1E, J2E, J3E, and J5E of the pulse output unit 103E. Further, the output HIGH level voltage pulse is applied to the gates of the Tr3E and Tr6E, so that the Tr3E and the Tr6E enter in the conducting state.

Also, the HIGH level voltage pulse appearing at the source of the Tr81 is applied to the gate of the Tr2F via the junction J81, so that the Tr2F enters in the conducting state. Regardless of whether the Tr1F is in the conducting state or in the non-conducting state, a voltage level becomes LOW at the junctions J1F, J2F, and J3F, and the Tr3F enters in the non-conducting state (shifting starts).

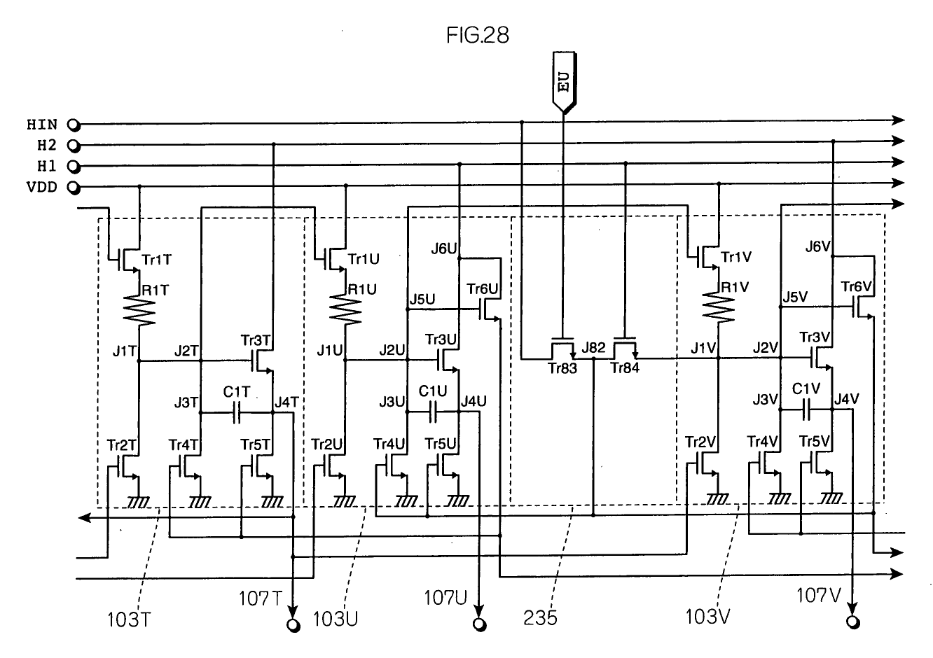

The circuit configuration in FIG. 28 includes the scanning end unit 235 instead of the scanning end unit 135.

<Scanning End Unit 235>

The scanning end unit 235 includes MOS transistors Tr83 and Tr84, and wiring lines that connect these components.

To the MOS transistor Tr83 (hereafter simply, “Tr83”), a horizontal scanning start/end pulse is applied to its drain via the terminal HIN. When a HIGH level horizontal shift end pulse is applied to its gate via the terminal EU, the Tr83 enters in the conducting state. A voltage pulse according to a voltage level of the horizontal scanning start/end pulse then appears at the source of the Tr83.

The MOS transistor Tr84 (hereafter simply, “Tr84”) has its drain connected to the source of the Tr83. When a HIGH level first horizontal shift pulse is applied to its gate via the terminal H1, the Tr84 enters in the conducting state. A voltage pulse according to a voltage level of the voltage pulse appearing at the source of the Tr83 then appears at the source of the Tr84.

Here, when a HIGH level horizontal shift end pulse, a HIGH level first horizontal shift pulse, and a LOW level horizontal scanning start/end pulse are applied, a LOW level voltage pulse appears at the source of the Tr83, and also, a LOW level voltage pulse appears at the source of the Tr84. The LOW level voltage pulse appearing at the source of the Tr84 is output from the scanning end unit 235 to the pulse output unit 103V. Due to this, a voltage level becomes LOW at the junctions J1V, J2V, J3V, and J5V, regardless of whether the Tr1V is in the conducting state or in the non-conducting state. Further, the output LOW level voltage pulse is applied to the gates of the Tr3V and Tr6V, so that the Tr3V and the Tr6V enter in the conducting state.

Also, when a LOW level first horizontal shift pulse, a HIGH level horizontal shift end pulse, and a HIGH level horizontal scanning start/end pulse are applied, the HIGH level voltage pulse appearing at the source of the Tr83 is applied to the gates of the Tr4U and the Tr5U constituting the pulse output unit 103U via the junction J82, so that the Tr4U and the Tr5U enter in the conducting state. A voltage level then becomes LOW at the junctions J3U and the J4U, so that both terminals of the C1U are grounded, and the C1U is discharged (shifting ends).

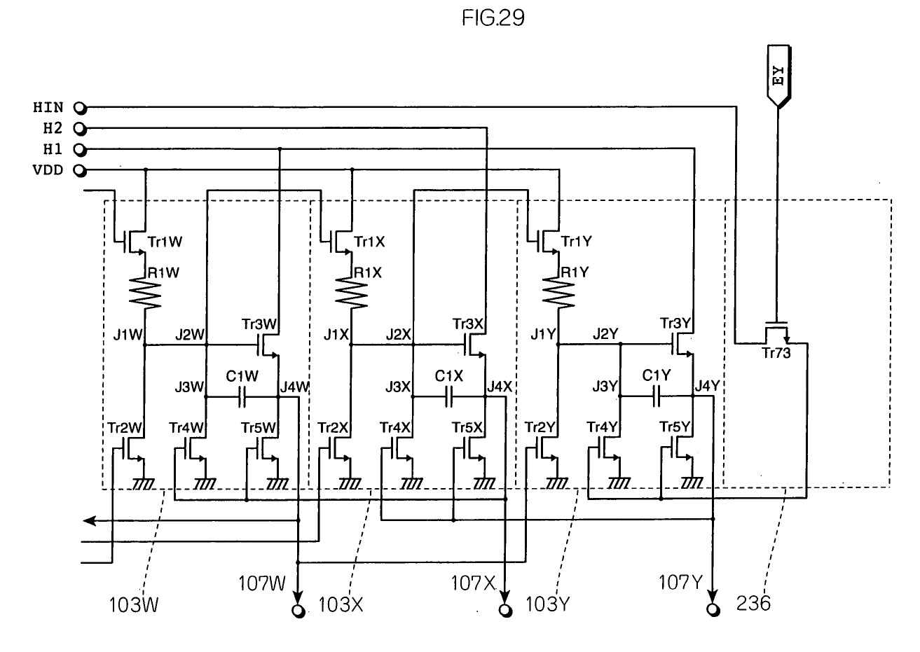

The circuit configuration in FIG. 29 includes the scanning end unit 236 instead of the scanning end unit 136.

<Scanning End Unit 236>

The scanning end unit 236 includes a MOS transistor Tr73.

To the MOS transistor Tr73 (hereafter simply, “Tr73”), a horizontal scanning start/end pulse is applied to its drain via the terminal HIN. When a HIGH level horizontal shift end pulse is applied to its gate via the terminal EY, the Tr73 enters in the conducting state. A voltage pulse according to a voltage level of the horizontal scanning start/end pulse then appears at the source of the Tr73.

Here, when a HIGH level horizontal shift end pulse and a HIGH level horizontal scanning start/end pulse are applied, a HIGH level voltage pulse appearing at the source of the Tr73 is applied to the gates of the Tr4Y and the Tr5Y constituting the pulse output unit 103Y, so that the Tr4Y and the Tr5Y enter in the conducting state. Then, a voltage level becomes LOW at the junctions J3Y and J4Y, so that both terminals of the C1Y are grounded, and the C1Y is discharged (shifting ends).

<Configuration of the Vertical Scanning Shift Register 204>

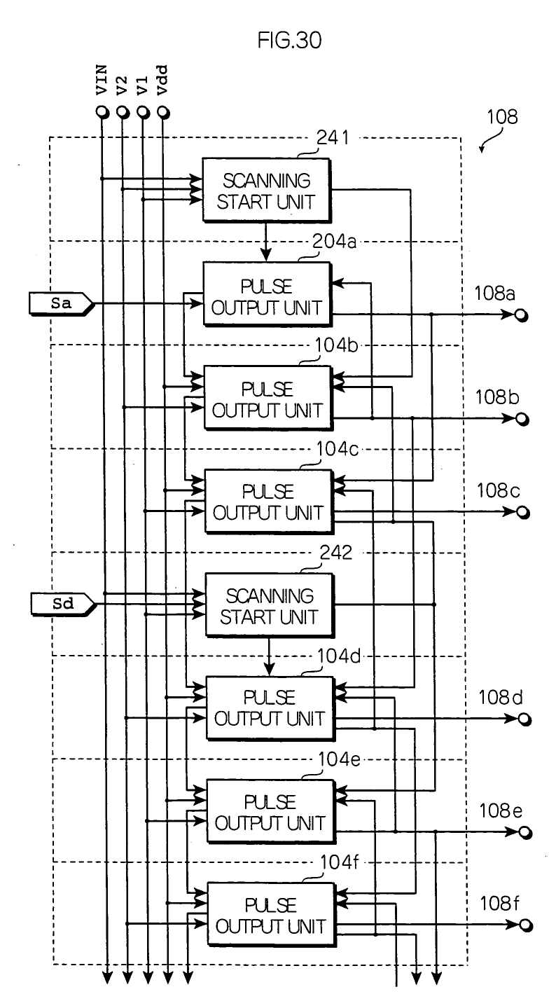

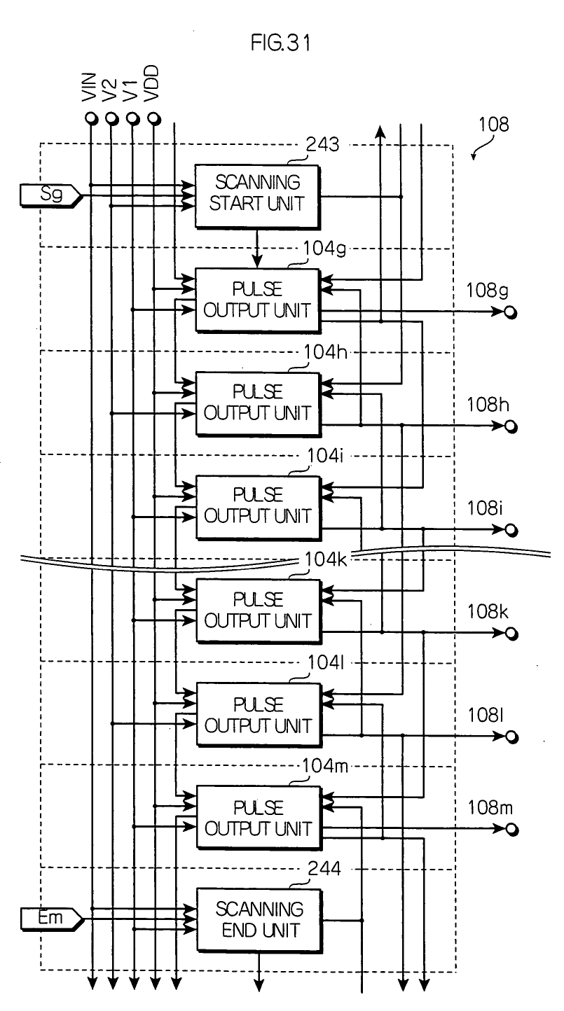

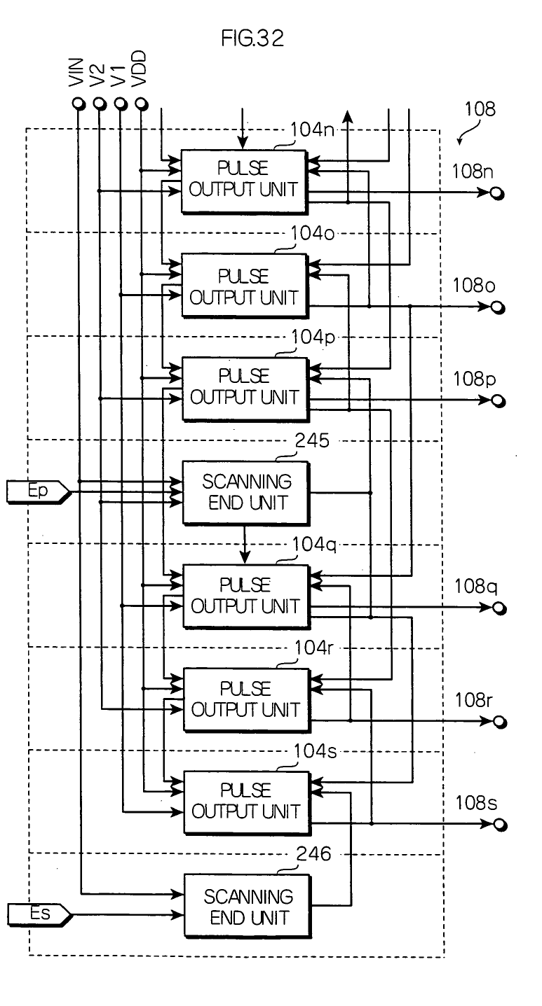

FIGS. 30 to 32 are functional block diagrams showing the configuration of the vertical scanning shift register relating to the second embodiment.

As shown in FIGS. 30 to 32, the vertical scanning shift register 204 includes scanning start units 241 to 243 and scanning end units 244 to 246, instead of the scanning start unit 141, the scanning start/end units 142 to 145, and the scanning end unit 146. The vertical scanning shift register 204 differs from the vertical scanning shift register 104 in the first embodiment in that the same voltage pulse (hereafter referred to as a “vertical shift start pulse”) is applied from the pulse generating circuit 205 to each of the terminals Sa, Sd, and Sg, instead of a different voltage pulse being individually applied to each of the terminals Sa, Sd, Sg, Em, Ep, and Es from the pulse generating circuit 105. Apart from the vertical shift start pulse, the same voltage pulse (hereafter referred to as a “vertical shift end pulse”) is applied from the pulse generating circuit 205 to each of the terminals Em, Ep, and Es. Further, a voltage pulse (hereafter referred to as a “vertical scanning start/end pulse”) is applied from the pulse generating circuit 205 to the vertical scanning shift register 204 via the terminal VIN.

Also, the vertical scanning shift register 204 starts outputting a vertical selective pulse from a different pulse output unit, depending on a combination of a first vertical shift pulse, a second vertical shift pulse, a vertical shift start pulse, a vertical shift end pulse, and a vertical scanning start/end pulse.

<Circuit Configuration of the Vertical Scanning Shift Register 204>

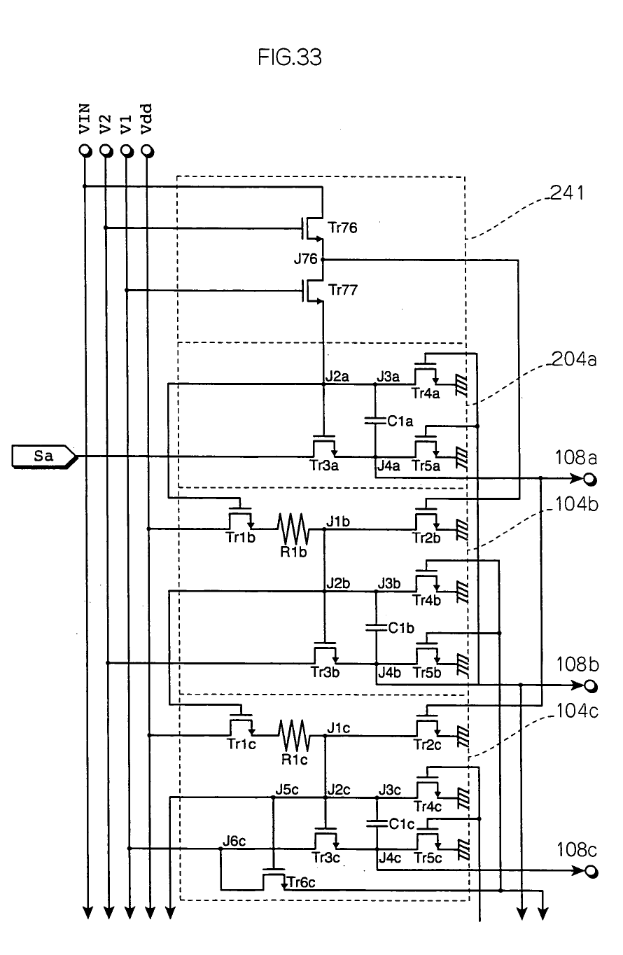

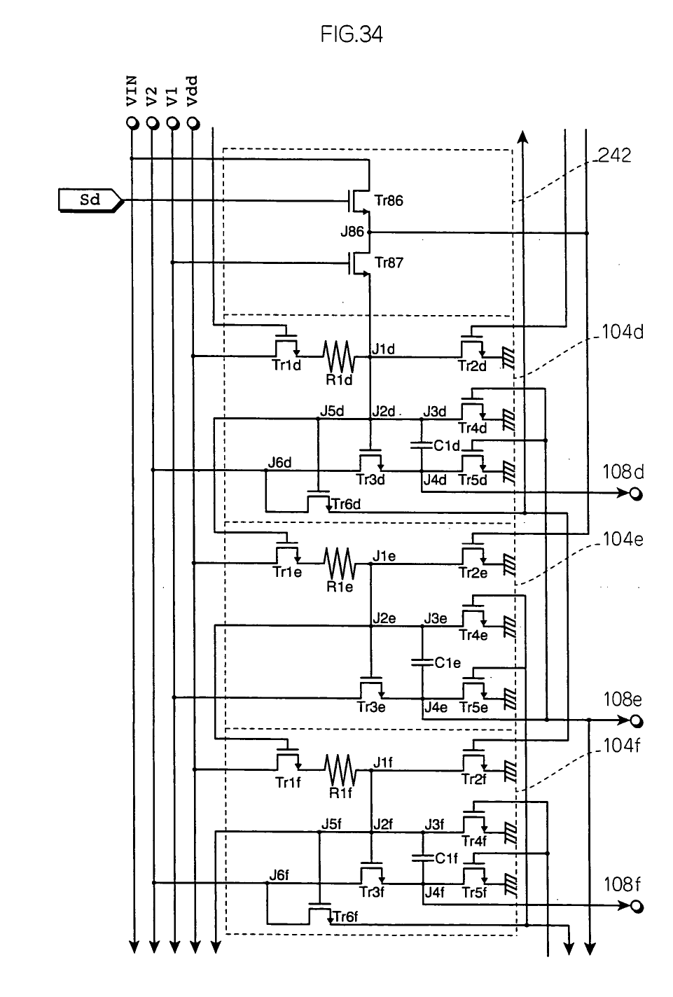

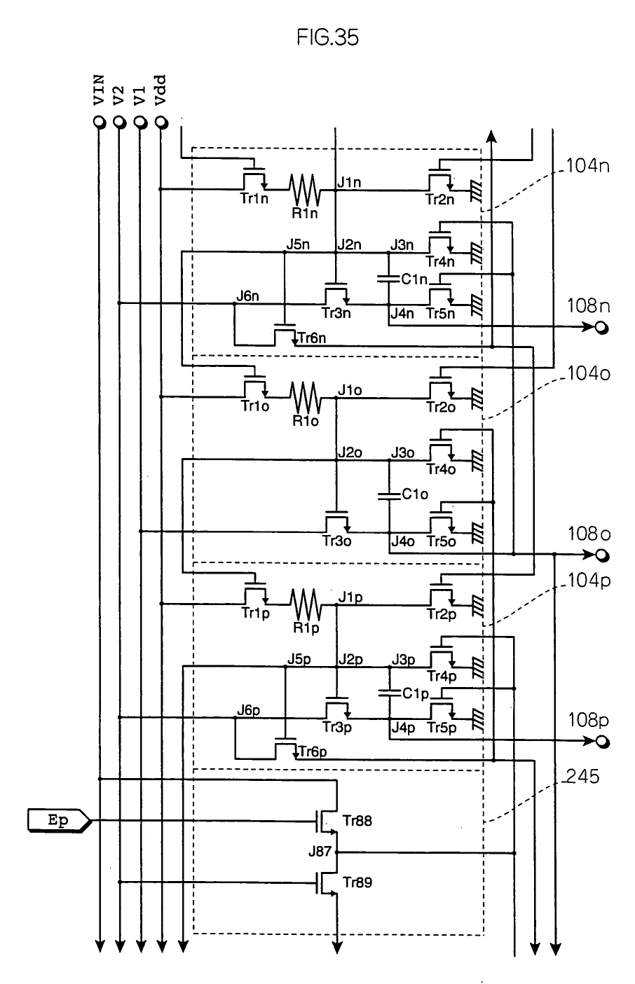

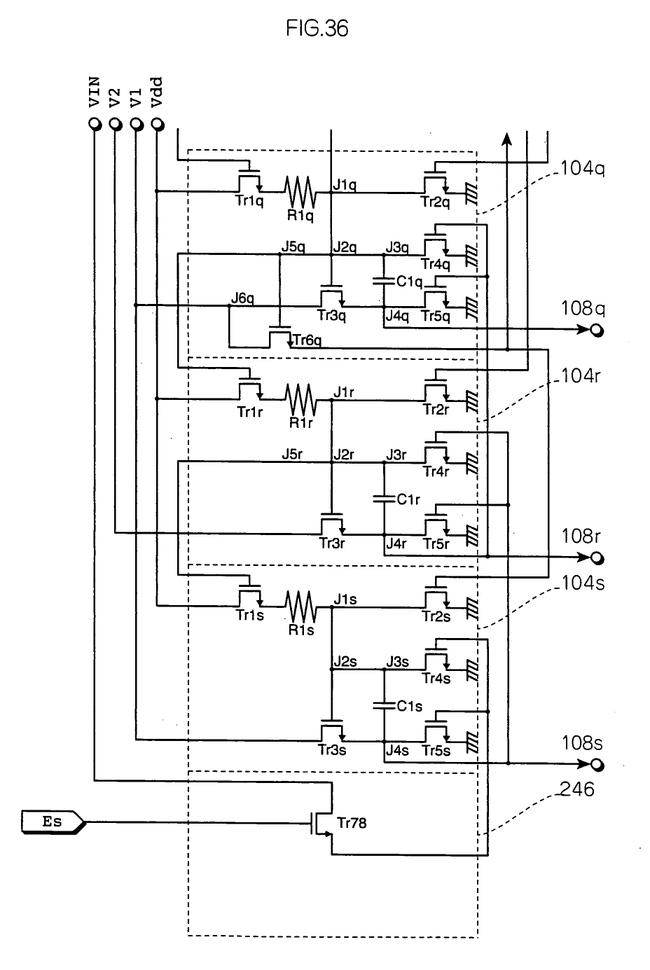

As one example, FIGS. 33 to 36 are circuit diagrams showing the configuration of the vertical scanning shift register relating to the second embodiment.

As shown in FIGS. 33 to 36, the vertical scanning shift register 204 includes the same components as the components of the horizontal scanning shift register 203, and therefore is not described here.

<Operation of the CCD 200>

The following describes the operation of the CCD 200 including the horizontal scanning shift register 203 and the vertical scanning shift register 204 having the above-described configurations. The following description exemplifies the case where one of scanning areas A, B., and C described in the first embodiment is selectively scanned, according to a voltage pulse applied from the pulse generating circuit 205 to the horizontal scanning shift register 203 and the vertical scanning shift register 204.

<Operation Example 1 in the Second Embodiment>

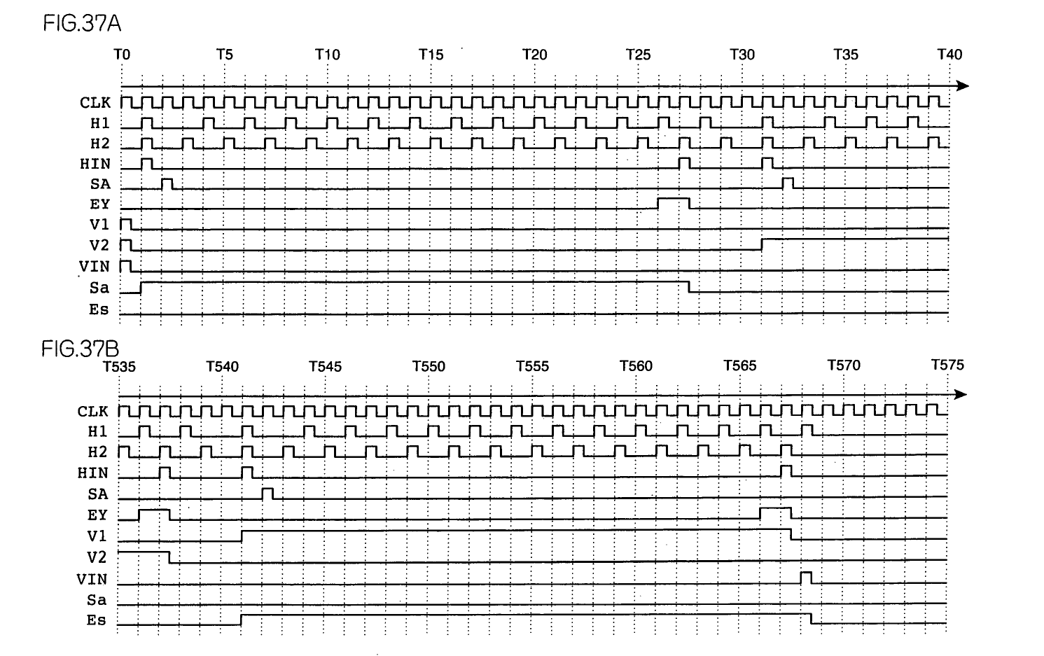

FIGS. 37A and 37B show timing charts for voltage pulses applied from the pulse generating circuit to the horizontal scanning shift register and the vertical scanning shift register when the scanning area A is scanned in the second embodiment. FIG. 37A shows a timing chart when the scanning starts, whereas FIG. 37B shows a timing chart when the scanning ends.

As shown in FIGS. 37A and 37B, voltage pulses are applied from the pulse generating circuit 205 to the components of the horizontal scanning shift register 203 and the vertical scanning shift register 204 via the clock, terminals H1, H2, HIN, SA, EY, V1, V2, VIN, Sa, and Es in the stated order shown from top down.

To be more specific, to the components of the horizontal scanning shift register 203, a HIGH level first horizontal shift pulse is applied via the terminal H1 for one clock from “T1”, “T4”, . . . , and “T28” with a 30-clock cycle, and a HIGH level second horizontal shift pulse is applied via the terminal H2 for one clock from “T1” with a two-clock cycle. Also, a HIGH level horizontal scanning start/end pulse is applied via the terminal HIN for one clock from “T1” and “T27” with a 30-clock cycle. Further, to the scanning start unit 231, a HIGH level horizontal shift start pulse is applied via the terminal SA for one clock from “T2” with a 30-clock cycle. To the scanning end unit 236, a HIGH level horizontal shift end pulse is applied via the terminal EY for two clocks from “T26” with a 30-clock cycle.

In the same manner, to the components of the vertical scanning shift register 204, a HIGH level first vertical shift pulse is applied via the terminal V1 for one clock from “T0”, and for 27 clocks from “T61” with a 60-clock cycle. A HIGH level second vertical shift pulse is applied via the terminal V2 for one clock from “T0” and for 27 clocks from “T31” with a 60-clock cycle. Also, a HIGH level vertical scanning start/end pulse is applied via the terminal VIN for one clock from “T0” and “T568”. Further, to the scanning start unit 241, a HIGH level vertical shift start pulse is applied via the terminal Sa for 27 clocks from “T1”. To the scanning end unit 246, a HIGH level vertical shift end pulse is applied via the terminal Es for 28 clocks from “T541”.

Here, the following describes one example case where one row is scanned in the horizontal direction during the time from “T0” to “T28”, based on the timing charts shown in FIGS. 37A and 37B.

Here, to the vertical scanning shift register 204, a HIGH level first vertical shift pulse, a HIGH level second vertical shift pulse, and a HIGH level vertical scanning start/end pulse are applied, from the pulse generating circuit 205, so that the pulse output unit 204a makes a state transition to the charging-state, and the pulse output unit 104b makes a state transition to the insulating state (“T0”). Further, a LOW level second vertical shift pulse is applied, a HIGH level first vertical shift start pulse is applied to the pulse output unit 204a via the terminal Sa, so that the pulse output unit 204a makes a state transition to the outputting-state, the pulse output unit 104b makes a state transition to the charging-state, and the pulse output unit 104c makes a state transition to the insulating-state (“T1”).

Hereafter, it is assumed that a vertical selective pulse is being output from the output unit 204a until “T28”, and a LOW level vertical shift end pulse is being applied to the scanning end unit 246 via the terminal Es until “T541”.

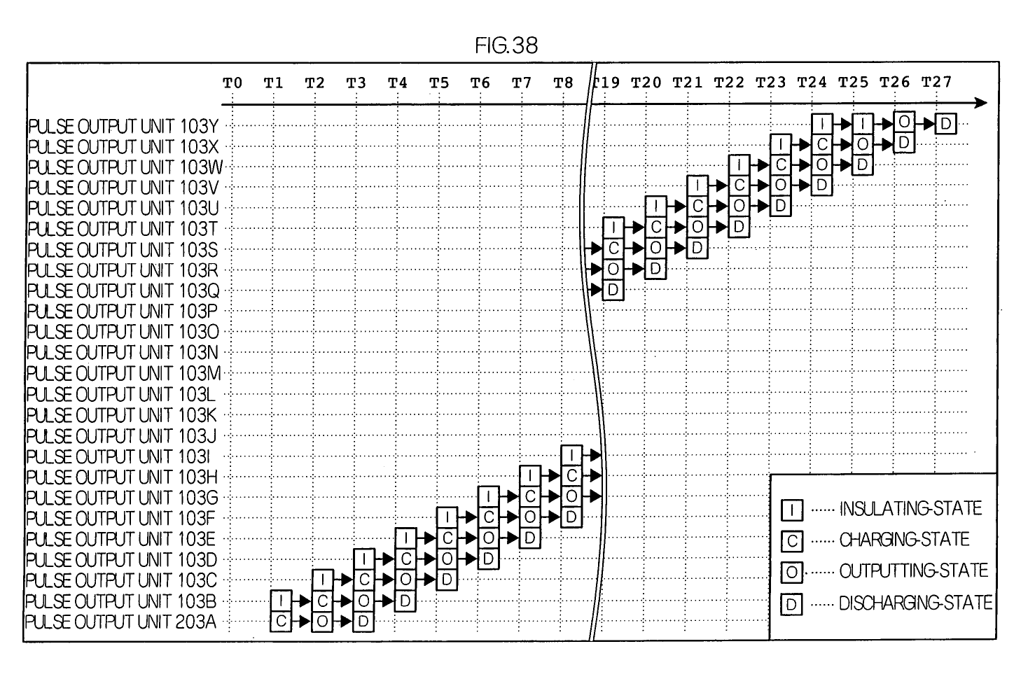

FIG. 38 shows the state transition of the horizontal scanning shift register relating to the second embodiment for the operation example 1. The state transition during the time from “T4” to “T24” is not described.

As shown in the figure, to the horizontal scanning shift register 203, a HIGH level first horizontal shift pulse, a HIGH level second horizontal shift pulse, and a HIGH level horizontal scanning start/end pulse are applied, from the pulse generating circuit 205, so that the pulse output unit 203A makes a state transition to the charging-state, and the pulse output unit 103B makes a state transition to the insulating-state (“T1”). Further, a LOW level first horizontal shift pulse, a LOW level second horizontal shift pulse, and a LOW level horizontal scanning start/end pulse are applied, and a HIGH level horizontal shift start pulse is to the scanning start unit 231 via the terminal SA, so that the pulse output unit 203A makes a state transition to the outputting-state, the pulse output unit 103B makes a state transition to the charging-state, and the pulse output unit 103C makes a state transition to the insulating-state (“T2”) Further, a LOW level first horizontal shift pulse, a LOW level horizontal scanning start/end pulse, and a HIGH level second horizontal shift pulse are applied, and a LOW level horizontal shift start pulse is applied to the scanning start unit 231 via the terminal SA, so that the pulse output unit 203A makes a state transition to the discharging-state, the pulse output unit 103B makes a state transition to the outputting-state, the pulse output unit 103C makes a state transition to the charging-state, and the pulse output unit 103D makes a state transition to the insulating-state (“T3”).

After that, to the horizontal scanning shift register 203, a LOW level first horizontal shift pulse and a HIGH level second horizontal shift pulse are applied, and a LOW level voltage pulse is applied to the scanning end unit 236 via the terminal EY, from the pulse generating circuit 205, so that the pulse output unit 103W makes a state transition to the discharging-state, the pulse output unit 103X makes a state transition to the outputting-state, and the pulse output unit 103Y makes a state transition to the charging-state (“T25”). Further, a HIGH level first horizontal shift pulse and a LOW level second horizontal shift pulse are applied, and a HIGH level horizontal shift end pulse is applied to the scanning end unit 236 via the terminal EY, so that the pulse output unit 103X makes a state transition to the discharging-state, and the pulse output unit 103Y makes a state transition to the outputting-state (“T26”). Then, a LOW level first horizontal shift pulse, a HIGH level second horizontal shift pulse, and a HIGH level horizontal scanning start/end pulse are applied, and a HIGH level horizontal shift end pulse is applied to the scanning end unit 236 via the terminal EY, so that the pulse output unit 103Y makes a state transition to the discharging-state (“T27”).

As described above, a horizontal selective pulse is output from each of the pulse output units 203A to 103Y, resulting in the pixel units 101Aa to 101Ya being scanned. In the same manner, to each of the active pulse output units 104b to 104s in the vertical scanning shift register 204, a horizontal selective pulse is output from each of the pulse output units 203A to 103Y, resulting in the scanning area A being scanned.

<Operation Example 2 in the Second Embodiment>

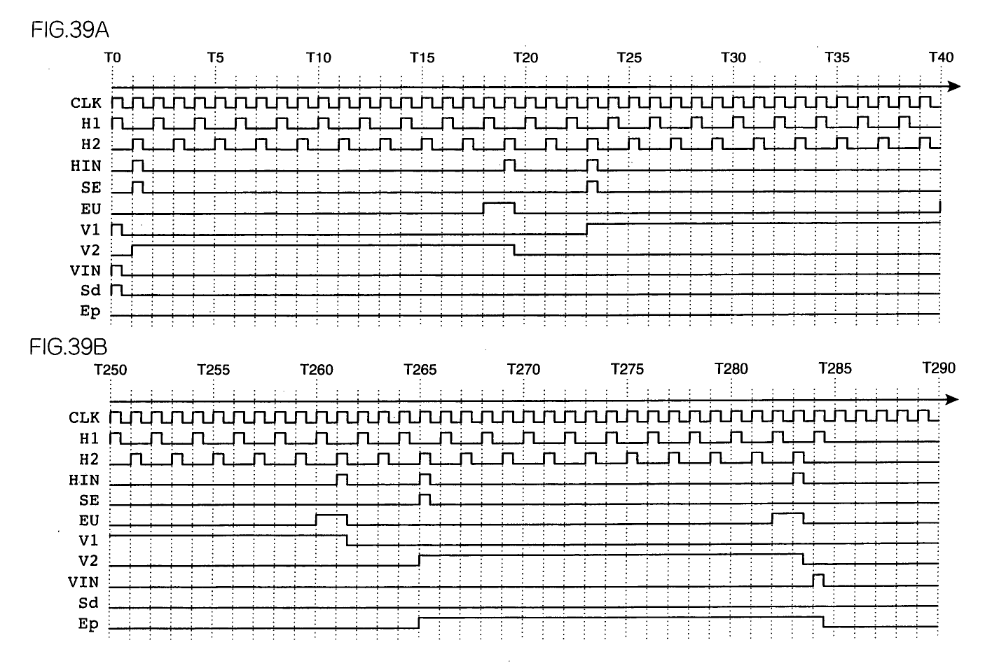

FIGS. 39A and 39B show timing charts for voltage pulses applied from the pulse generating circuit to the horizontal scanning shift register and the vertical scanning shift register when the scanning area B is scanned in the second embodiment. FIG. 39A shows a timing chart when the scanning starts, whereas FIG. 39B shows a timing chart when the scanning ends.

As shown in FIGS. 39A and 39B, voltage pulses are applied from the pulse generating circuit 205 to the components of the horizontal scanning shift register 203 and the vertical scanning shift register 204 via the clock, terminals H1, H2, HIN, SE, EU, V1, V2, VIN, Sd, and Ep in the stated order shown from top down.

To be more specific, to the components of the horizontal scanning shift register 203, a HIGH level first horizontal shift pulse is applied via the terminal H1 for one clock from “T0” with a two-clock cycle, and a HIGH level second horizontal shift pulse is applied via the terminal H2 for one clock from “T1” with a two-clock cycle. Also, a HIGH level horizontal scanning start/end pulse is applied via the terminal HIN for one clock from “T1” and “T19” with a 22-clock cycle. Further, to the scanning start unit 232, a HIGH level horizontal shift start pulse is applied via the terminal SE for one clock from “T1” with a 22-clock cycle. To the scanning end unit 235, a HIGH level horizontal shift end pulse is applied via the terminal EU for two clocks from “T18” with a 22-clock cycle.

In the same manner, to the components of the vertical scanning shift register 204, a HIGH level first vertical shift pulse is applied via the terminal V1 for one clock from “T0”, and for 19 clocks from “T23” with a 44-clock cycle. A HIGH level voltage pulse is applied via the terminal V2 for 19 clocks from “T1” with a 44-clock cycle. Also, a HIGH level vertical scanning start/end pulse is applied via the terminal VIN for one clock from “T0” and “T284”. Further, to the scanning start unit 242, a HIGH level vertical shift start pulse is applied via the terminal Sd for one clock from “T0”. To the scanning end unit 145, a HIGH level vertical shift end pulse is applied via the terminal Ep for 20 clocks from “T265”.

Here, the following describes one example case where one row is scanned in the horizontal direction during the time from “T0” to “T20”, based on the timing charts shown in FIGS. 39A and 39B.

Here, to the vertical scanning shift register 204, a HIGH level first vertical shift pulse, a HIGH level vertical scanning start/end pulse, and a LOW level second vertical shift pulse are applied, and a HIGH level horizontal shift start pulse is applied to the scanning start unit 242 via the terminal Sd, from the pulse generating circuit 205, so that the pulse output unit 104d makes a state transition to the charging-state, and the pulse output unit 104e makes a state transition to the insulating-state (“T0”). Further, a LOW level first vertical shift pulse, a LOW level vertical scanning start/end pulse, and a HIGH level second vertical shift pulse are applied, and a LOW level voltage pulse is applied to the scanning start unit 242 via the terminal Sd, so that the pulse output unit 104d makes a state transition to the outputting-state, the pulse output unit 104e makes a state transition to the charging-state, and the pulse output unit 104f makes a state transition to the insulating-state (“T1”).

Hereafter, it is assumed that a vertical selective pulse is being output from the output unit 104d until “T20”, and a LOW level vertical shift end pulse is being applied to the scanning end unit 245 via the terminal Ep until “T265”.

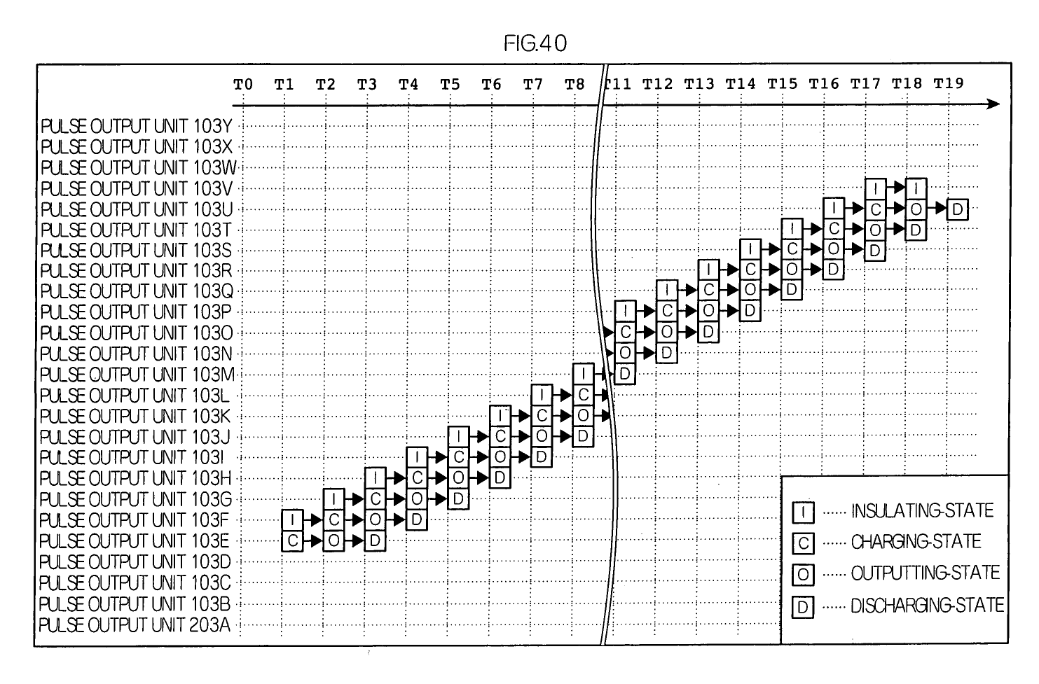

FIG. 40 shows the state transition of the horizontal scanning shift register relating to the second embodiment for the operation example 2. The state transition during the time from “T4” to “T16” is not described.

As shown in the figure, to the horizontal scanning shift register 203, a LOW level first horizontal shift pulse, a HIGH level second horizontal shift pulse, and a HIGH level horizontal scanning start/end pulse are applied, and a HIGH level horizontal shift start pulse is applied to the scanning start unit 232 via the terminal SE, from the pulse generating circuit 205, so that the pulse output unit 103E makes a state transition to the charging-state, and the pulse output unit 103F makes a state transition to the insulating-state (“T1”). Further, a HIGH level first horizontal shift pulse, a LOW level second horizontal shift pulse, a LOW level horizontal scanning start/end pulse, and a LOW level horizontal shift start pulse are applied, so that the pulse output unit 103E makes a state transition to the outputting-state, the pulse output unit 103F makes a state transition to the charging-state, and the pulse output unit 103G makes a state transition to the insulating-state (“T2”). Further, a LOW level first horizontal shift pulse and a HIGH level second horizontal shift pulse are applied, so that the pulse output unit 103E makes a state transition to the discharging-state, the pulse output unit 103F makes a state transition to the outputting-state, the pulse output unit 103G makes a state transition to the charging-state, and the pulse output unit 103H makes a state transition to the insulating-state (“T3”).

After that, to the horizontal scanning shift register 203, a LOW level first horizontal shift pulse and a HIGH level second horizontal shift pulse are applied from the pulse generating circuit 205, so that the pulse output unit 103S makes a state transition to the discharging-state, the pulse output unit 103T makes a state transition to the outputting-state, the pulse output unit 103U makes a state transition to the charging-state, and the pulse output unit 103V makes a state transition to the insulating-state (“T17”). Further, a HIGH level first horizontal shift pulse and a LOW level second horizontal shift pulse are applied, and a HIGH level horizontal shift end pulse is applied to the scanning end unit 235 via the terminal EU, so that the pulse output unit 103T makes a state transition to the discharging-state, the pulse output unit 103U makes a state transition to the outputting-state, and the pulse output unit 103V makes a state transition to the insulating-state (“T18”). Then, a LOW level first horizontal shift pulse, a HIGH level second horizontal shift pulse, and a HIGH level horizontal scanning start/end pulse are applied, so that the pulse output unit 103U makes a state transition to the discharging-state, and the pulse output unit 103V makes a state transition to the insulating-state (“T19”).

As described above, a horizontal selective pulse is output from each of the pulse output units 103E to 103U, resulting in the pixel units 101Ed to 101Ud being scanned. In the same manner, to each of the active pulse output units 104e to 104p in the vertical scanning shift register 204, a horizontal selective pulse is output from each of the pulse output units 103E to 103U, resulting in the scanning area. B being scanned.

<Operation Example 3 in the Second Embodiment>

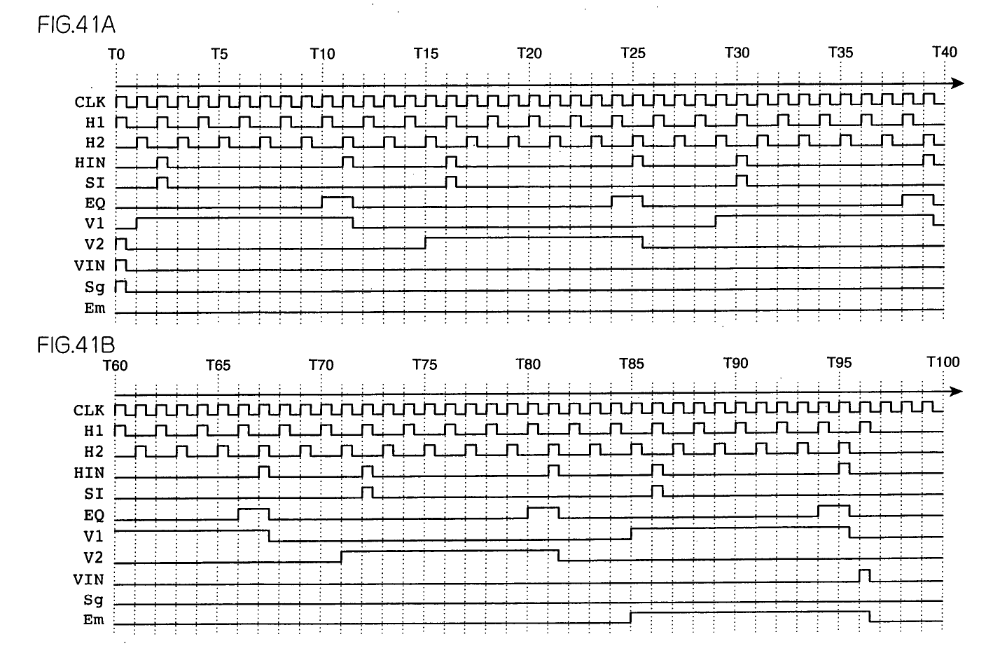

FIGS. 41A and 41B show timing charts for voltage pulses applied from the pulse generating circuit to the horizontal scanning shift register and the vertical scanning shift register when the scanning area C is scanned in the second embodiment. FIG. 41A shows a timing chart when the scanning starts, whereas FIG. 41B shows a timing chart when the scanning ends.

As shown in FIGS. 41A and 41B, voltage pulses are applied from the pulse generating circuit 205 to the components of the horizontal scanning shift register 203 and the vertical scanning shift register 204 via the clock, terminals H1, H2, HIN, SI, EQ, V1, V2, VIN, Sg, and Em, in the stated order shown from top down.

To be more specific, to the components of the horizontal scanning shift register 203, a HIGH level first horizontal shift pulse is applied via the terminal H1 for one clock from “T0” with a two-clock cycle, and a HIGH level second horizontal shift pulse is applied via the terminal H2 for one clock from “T1” with a two-clock cycle. Also, a HIGH level horizontal scanning start/end pulse is applied via the terminal HIN for one clock from “T2” and “T11” with a 14-clock cycle. Further, to the scanning start unit 233, a HIGH level horizontal shift start pulse is applied via the terminal SI for one clock from “T2” with a 14-clock cycle. To the scanning end unit 234, a HIGH level horizontal shift end pulse is applied via the terminal EQ for two clocks from “T10” with a 14-clock cycle.

In the same manner, to the components of the vertical scanning shift register 204, a HIGH level first vertical shift pulse is applied via the terminal V1 for 11 clocks from “T1” with a 28-clock cycle, and a HIGH level second vertical shift pulse is applied via the terminal V2 for one clock from “T0” and for 11 clocks from “T15” with a 28-clock cycle. Further, to the scanning start unit 243, a HIGH level vertical shift start pulse is applied via the terminal Sg for one clock from “T0”. To the scanning end unit 244, a HIGH level vertical shift end pulse is applied via the terminal Em for 12 clocks from “T85”.

Here, the following describes one example case where one row is scanned in the horizontal direction during the time from “T0” to “T12”, based on the timing charts shown in FIGS. 41A and 41B.

Here, to the vertical scanning shift register 204, a LOW level first vertical shift pulse, a HIGH level second vertical shift pulse, and a HIGH level vertical scanning start/end pulse are applied, and a HIGH level vertical shift start pulse is applied to the scanning start unit 243 via the terminal Sg, so that the pulse output unit 104g makes a state transition to the charging-state, and the pulse output unit 104h makes a state transition to the insulating-state (“T0”). Further, a HIGH level first vertical shift pulse, a LOW level second vertical shift pulse, and a LOW level vertical scanning start/end pulse are applied, and a LOW level vertical shift start pulse is applied to the scanning start unit 243 via the terminal Sg, so that the pulse output unit 104g makes a state transition to the outputting-state, the pulse output unit 104h makes a state transition to the charging-state, and the pulse output unit 104i makes a state transition to the insulating-state (“T1”).

Hereafter, it is assumed that a vertical selective pulse is being output from the output unit 104g until “T12”, and a LOW level vertical shift end pulse is being applied to the scanning end unit 244 via the terminal Em until “T84”.

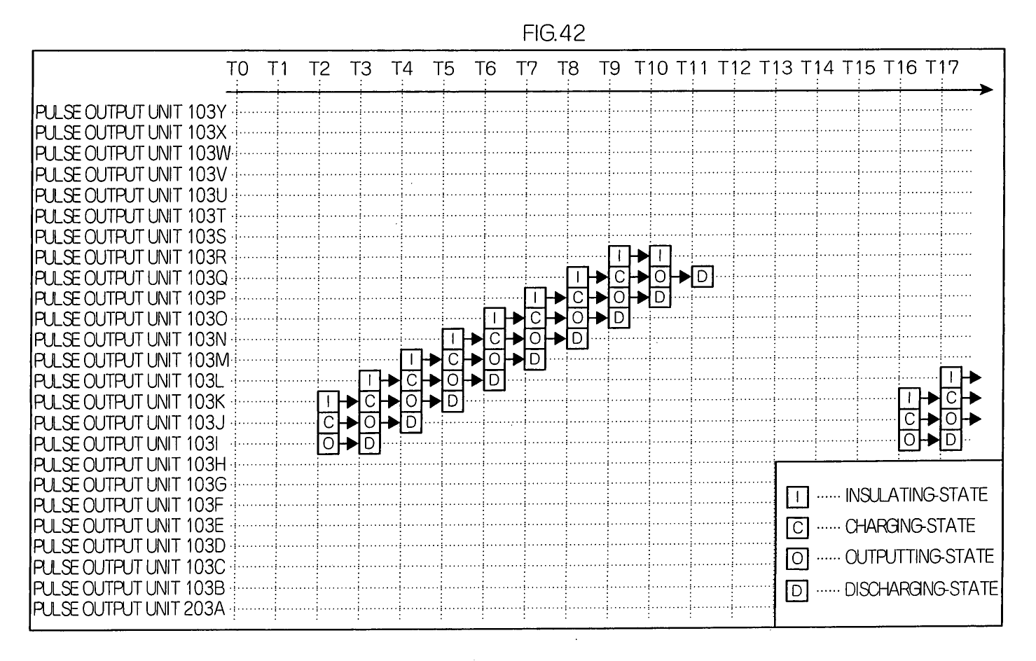

FIG. 42 shows the state transition of the horizontal scanning shift register relating to the second embodiment for the operation example 3. The state transition during the time from “T4” to “T8” is not described.

As shown in the figure, to the horizontal scanning shift register 203, a HIGH level first horizontal shift pulse, a HIGH level horizontal scanning start/end pulse, and a LOW level second horizontal shift pulse are applied, and a HIGH level horizontal shift start pulse is applied to the scanning start unit 233 via the terminal SI, from the pulse generating circuit 205, so that the pulse output unit 103I makes a state transition to the outputting-state, the pulse output unit 103J makes a state transition to the charging-state, and the pulse output unit 103K makes a state transition to the insulating-state (“T2”) Further, a LOW level first horizontal shift pulse, a LOW level horizontal scanning start/end pulse, and a HIGH level second horizontal shift pulse are applied, and a LOW level horizontal shift start pulse is applied to the scanning start unit 233 via the terminal SI, so that the pulse output unit 103I makes a state transition to the discharging-state, the pulse output unit 103J makes a state transition to the outputting-state, the pulse output unit 103K makes a state transition to the charging-state, and the pulse output unit 103L makes a state transition to the insulating-state (“T3”).

After that, to the horizontal scanning shift register 203, a LOW level first horizontal shift pulse and a HIGH level second horizontal shift pulse are applied from the pulse generating circuit 205, so that the pulse output unit 1030 makes a state transition to the discharging-state, the pulse output unit 103P makes a state transition to the outputting-state, the pulse output unit 103Q makes a state transition to the charging-state, and the pulse output unit 103R makes a state transition to the insulating-state (“T9”) Further, a HIGH level first horizontal shift pulse and a LOW level second horizontal shift pulse are applied, and a HIGH level vertical shift end pulse is applied to the scanning end unit 234 via the terminal EQ, so that the pulse output unit 103P makes a state transition to the discharging-state, the pulse output unit 103Q makes a state transition to the outputting-state, and the pulse output unit 103R makes a state transition to the insulating-state (“T10”). Then, a LOW level first horizontal shift pulse, a HIGH level second horizontal shift pulse, and a HIGH level horizontal scanning start/end pulse are applied, and a HIGH level horizontal shift end pulse is applied to the scanning end unit 234 via the terminal EQ, so that the pulse output unit 103Q makes a state transition to the discharging-state (“T11”).

As described above, a horizontal selective pulse is output from each of the pulse output units 103I to 103Q, resulting in the pixel units 101Ig to 101Qg being scanned. In the same manner, to each of the active pulse output units 104h to 104m in the vertical scanning shift register 204, a horizontal selective pulse is output from each of the pulse output units 103I to 103Q, resulting in the scanning area C being scanned.

<Summary of the Second Embodiment>

As described above, the horizontal scanning shift register 203 and the vertical scanning shift register 204 respectively output a horizontal selective pulse and a vertical selective pulse, and apply the horizontal selective pulse to the gates of the horizontal MOS transistors Tr15A to Tr15Y constituting the switch unit 102, and apply the vertical selective pulse to the gates of the vertical MOS transistors Tr11Aa to Tr11Ys constituting the light-receiving unit 101, to select one pixel unit after another for reading a signal charge from the selected pixel unit. In this way, a signal charge accumulated in a photodiode of the selected pixel unit is read and output to the switch unit 102 via the vertical signal lines 109A to 109Y.

Here, according to a voltage pulse applied from the pulse generating circuit 205, a horizontal MOS transistor to which a horizontal selective pulse is applied, and a vertical MOS transistor to which a vertical selective pulse is applied are controlled.

<Modifications>

Although the present invention is described based on the above embodiments, it should be clear that the present invention is not limited to specific examples shown in the above embodiment. The following modifications are also possible.

The scanning start/end unit 132 (or 135 etc.) and the pulse output unit 103E (or 103V etc.) in the first embodiment may be alternately combined to constitute a shift register.

In the second embodiment, six scanning start units may be provided to individually start scanning according to a combination of two out of four voltage pulses, and scanning of the light-receiving unit may be started from one of the six scanning start positions.

The shift register may be composed of a MOS transistor with one of n-channel and p-channel.

Only one of a horizontal scanning shift register and a vertical scanning shift register may be realized by the shift register (parallel-in/parallel out shift register) relating to the first embodiment (or second embodiment), and the other one of the horizontal scanning shift register and the vertical scanning shift register may be realized by a conventional shift register (serial-in/parallel-out shift register).

In the case where the light-receiving unit is one-dimensional, the one-dimensional light-receiving unit maybe scanned by the shift register (parallel-in/parallel-out shift register) relating to the first embodiment (or second embodiment).

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

What is claimed is:

1. A charge-coupled device of XY addressing type, comprising:
a light-receiving unit that includes an XY matrix of pixel units in each of which photoelectric transfer and charge accumulation are performed;
a pulse generating circuit operable to generate two or more types of voltage pulses; and
a shift register operable to
(a) start scanning from a first pixel unit that is included in the light-receiving unit, when the two or more types of voltage pulses applied thereto in parallel from the pulse generating circuit are in a first combination, and
(b) start scanning from a second pixel unit that is different from the first pixel unit and is included in the light-receiving unit, when the two or more types of the applied voltage pulses are in a second combination that is different from the first combination.

2. The charge-coupled device of claim 1, wherein
the pulse generating circuit generates a first voltage pulse, a second voltage pulse, and a third voltage pulse, each having a voltage level set at HIGH level or LOW level, and applies the first voltage pulse, the second voltage pulse, and the third voltage pulse to the shift register, and
the first combination is a combination of the first voltage pulse and the second voltage pulse both being set at HIGH level and the third voltage pulse being set at LOW level at a first time point that is before scanning is started, and the second combination is a combination of the second voltage pulse and the third voltage pulse both being set at HIGH level and the first voltage pulse being set at LOW level at the first time point.

3. The charge-coupled device of claim 2, wherein
the shift register includes:
a first pulse output unit operable to output a first selective pulse indicating to select the first pixel unit from the light-receiving unit;
a second pulse output unit operable to output a second selective pulse indicating to select the second pixel unit from the light-receiving unit;
a first scanning start unit operable to output, to the first pulse output unit, a first scanning start pulse indicating to start scanning from the first pixel unit, when the first voltage pulse and the second voltage pulse both being set at HIGH level are applied at the first time point; and
a second scanning start unit operable to output, to the second pulse output unit, a second scanning start pulse indicating to start scanning from the second pixel unit, when the second voltage pulse and the third voltage pulse both being set at HIGH level are applied at the first time point,
the first pulse output unit outputs the first selective pulse, when the first scanning start pulse is applied at the first time point and the third voltage pulse being set at HIGH level is applied at a second time point that follows the first time point, and
the second pulse output unit outputs the second selective pulse, when the second scanning start pulse is applied at the first time point and the first voltage pulse being set at HIGH level is applied at the second time point.

4. The charge-coupled device of claim 3, wherein
the pulse generating circuit generates a fourth voltage pulse having a voltage level set at HIGH level or LOW level, and applies the fourth voltage pulse to the shift register,
the first scanning start unit includes:
a first MOSFET, to a drain of which the fourth voltage pulse is applied and to a gate of which the second voltage pulse is applied, where MOSFET stands for Metal Oxide Semiconductor Field Effect Transistor; and
a second MOSFET, a drain of which is connected to a source of the first MOSFET and to a gate of which the first voltage pulse is applied, and
the first scanning start unit outputs, as the first scanning start pulse, a voltage pulse being set at HIGH level appearing at a source of the second MOSFET, when the fourth voltage pulse being set at HIGH level is applied at the first time point.

5. The charge-coupled device of claim 4, wherein the shift register includes MOSFETs with a single channel.

6. The charge-coupled device of claim 1, wherein
in the light-receiving unit, a pixel unit belonging to a first column is the first pixel unit, and a pixel unit belonging to a second column that is different from the first column is the second pixel unit, and
the shift register is a horizontal scanning shift register that is placed to extend in an X-axis direction of the light-receiving unit and that scans the light-receiving unit in the X-axis direction.

7. The charge-coupled device of claim 1, wherein
the pulse generating circuit generates a first voltage pulse and a second voltage pulse, each having a voltage level set at HIGH level or LOW level, and applies the first voltage pulse and the second voltage pulse to the shift register, and
the shift register starts scanning from the first pixel unit when the first voltage pulse being set at HIGH level and the second voltage pulse being set at LOW level are applied at a first time point that is before scanning is started, and starts scanning from the second pixel unit when the first voltage being set at LOW level and the second voltage pulse being set at HIGH level are applied at the first time point.

8. The charge-coupled device of claim 7, wherein
in the light-receiving unit, a pixel unit belonging to a first row is the first pixel unit, and a pixel unit belonging to a second row that is different from the first row is the second pixel unit, and
the shift register is a vertical scanning shift register that is placed to extend in a Y-axis direction of the light-receiving unit and that scans the light-receiving unit in the Y-axis direction.

9. The charge-coupled device of claim 3, wherein
the pulse generating circuit generates a fourth voltage pulse having a voltage level set at HIGH level or LOW level, and applies the fourth voltage pulse to the shift register, and
the shift register ends scanning at a last pixel unit that is positioned last in a scanning direction in the light-receiving unit, unless the first voltage pulse and the fourth voltage pulse both being set at HIGH level and the second voltage pulse being set at LOW level are applied at a third time point that is before scanning is ended, and ends scanning at a third pixel unit that is different from the last pixel unit, when the first voltage pulse and the fourth voltage pulse both being set at HIGH level and the second voltage pulse being set at LOW level are applied at the third time point.

10. The charge-coupled device of claim 9, wherein
the shift register includes:
a third pulse output unit operable to output a third selective pulse indicating to select the third pixel unit from the light-receiving unit;
a fourth pulse output unit operable to output a fourth selective pulse indicating to select a fourth pixel unit that is positioned next to the third pixel unit from the light-receiving unit; and
a first scanning end unit operable to output, to the fourth pulse output unit, a first scanning end pulse indicating to end scanning at the third pixel unit, when the first voltage pulse and the fourth voltage pulse both being set at HIGH level are applied at the third time point,
the third pulse output unit outputs the third selective pulse, when the first voltage pulse being set at HIGH level is applied at the third time point, and
the fourth pulse output unit outputs the fourth selective pulse when the first scanning end pulse is not applied at the third time point, and the second voltage pulse being set at HIGH level is applied at a fourth time point that follows the third time point, and does not output the fourth selective pulse when the first scanning end pulse is applied at the third time point even if the second voltage pulse being set at HIGH level is applied at the fourth time point.

11. The charge-coupled device of claim 10, wherein
the pulse generating circuit generates a fifth voltage pulse having a voltage level set at HIGH level or LOW level, and applies the fifth voltage pulse to the shift register,
the second scanning start unit includes:
a first MOSFET, to a drain of which the fifth voltage pulse is applied and to a gate of which the third voltage pulse is applied, where MOSFET stands for Metal Oxide Semiconductor Field Effect Transistor; and
a second MOSFET, a drain of which is connected to a source of the first MOSFET and to a gate of which the second voltage pulse is applied,
the second scanning start unit outputs, as the second scanning start pulse, a voltage pulse being set at HIGH level appearing at a source of the second MOSFET, when the fifth voltage pulse being set at HIGH level is applied at the first time point,
the first scanning end unit includes:
a third MOSFET, to a drain of which the fifth voltage pulse is applied and to a gate of which the fourth voltage pulse is applied; and
a fourth MOSFET, a drain of which is connected to a source of the third MOSFET and to a gate of which the first voltage pulse is applied, and
the first scanning end unit outputs, as the first scanning end pulse, a voltage pulse being set at LOW level appearing at a source of the fourth MOSFET, when the fifth voltage pulse being set at LOW level is applied at the third time point.

12. A charge-coupled device of XY addressing type, comprising:
a light-receiving unit that includes an XY matrix of pixel units in each of which photoelectric transfer and charge accumulation are performed;
a pulse generating circuit operable to generate two or more types of voltage pulses; and
a shift register operable to
(a) end scanning at a last pixel unit that is positioned last in a scanning direction in the light-receiving unit, when the two or more types of voltage pulses applied thereto in parallel from the pulse generating circuit are in a combination other than a first combination, and
(b) end scanning at a first pixel unit that is different from the last pixel unit and is included in the light-receiving unit, when the two or more types of the applied voltage pulses are in the first combination.

13. The charge-coupled device of claim 12, wherein
the pulse generating circuit generates a first voltage pulse, a second voltage pulse, and a third voltage pulse, each having a voltage level set at HIGH level or LOW level, and applies the first voltage pulse, the second voltage pulse, and the third voltage pulse to the shift register, and
the first combination is a combination of the first voltage pulse and the third voltage pulse both being set at HIGH level and the second voltage pulse being set at LOW level at a first time point that is before scanning is ended.

14. The charge-coupled device of claim 13, wherein
the shift register includes:
a first pulse output unit operable to output a first selective pulse indicating to select the first pixel unit from the light-receiving unit;
a second pulse output unit operable to output a second selective pulse indicating to select a second pixel unit that is positioned next to the first pixel unit from the light-receiving unit; and
a first scanning end unit operable to output, to the second pulse output unit, a first scanning end pulse indicating to end scanning at the first pixel unit, when the first voltage pulse and the third voltage pulse both being set at HIGH level are applied at the first time point,
the first pulse output unit outputs the first selective pulse when the first voltage pulse being set at HIGH level is applied at the first time point, and
the second pulse output unit outputs the second selective pulse when the first scanning end pulse is not applied at the first time point, and the second voltage pulse being set at HIGH level is applied at a second time point that follows the first time point, and does not output the second selective pulse when the first scanning end pulse is applied at the first time point even if the second voltage pulse being set at HIGH level is applied at the second time point.

15. The charge-coupled device of claim 14, wherein
the pulse generating circuit generates a fourth voltage pulse having a voltage level set at HIGH level or LOW level, and applies the fourth voltage pulse to the shift register,
the first scanning end unit includes:
a first MOSFET, to a drain of which the fourth voltage pulse is applied and to a gate of which the third voltage pulse is applied, where MOSFET stands for Metal Oxide Semiconductor Field Effect Transistor; and
a second MOSFET, a drain of which is connected to a source of the first MOSFET and to a gate of which the first voltage pulse is applied, and
the first scanning end unit outputs, as the first scanning end pulse, a voltage pulse being set at LOW level appearing at the source of the second MOSFET, when the fourth voltage pulse being set at LOW level is applied at the first time point.
